(19) United States
(12) Patent Application Publication
(10) Pub. No.: US 2021/0218923 A1
(43) Pub. Date: Jul. 15, 2021

(54) SOLID-STATE IMAGING DEVICE AND ELECTRONIC DEVICE

(71) Applicant: Sony Semiconductor Solutions Corporation, Kanagawa (JP)

(72) Inventor: Koji Yoda, Kanagawa (JP)

(21) Appl. No.: 17/267,954

(22) PCT Filed: Sep. 4, 2019
(86) PCT No.: PCT/JP2019/034717

§ 371 Date: Feb. 11, 2021

(30) Foreign Application Priority Data
Sep. 18, 2018 (JP) 2018-173554

(51) Int. Cl. H04N 5/3745; H04N 5/347; H01L 27/146

(52) U.S. Cl. CPC H04N 5/3745; H01L 27/14643; H01L 27/14609; H04N 5/347

(57) ABSTRACT

The present disclosure relates to a solid-state imaging device and an electronic device capable of further improving processing performance.

A solid-state imaging device is provided including an array unit in which a plurality of pixels each including a photoelectric conversion unit and an analog memory unit is arranged, in which the analog memory unit holds an electric charge photoelectrically converted by the photoelectric conversion unit by first exposure, and the electric charge held in the analog memory unit by the first exposure is adaptively and non-destructively read. A technology according to the present disclosure can be applied to, for example, a CMOS image sensor.

### TECHNICAL FIELD

The present disclosure relates to a solid-state imaging device and an electronic device, and more particularly to a solid-state imaging device and an electronic device enabled to further improve processing performance.

### BACKGROUND ART

In recent years, image sensors such as Complementary Metal Oxide Semiconductor (CMOS) image sensors have become widespread and are used in various fields. For example, as a technology related to an image sensor, a technology disclosed in Patent Document 1 is known.

### CITATION LIST

### Patent Document

Patent Document 1: Japanese Patent Application Laid-Open No. 2012-253422

### SUMMARY OF THE INVENTION

### Problems to be Solved by the Invention

By the way, in a solid-state imaging device such as an image sensor, a method is used of transferring an electric charge stored in a photodiode to an analog memory, and reading the electric charge held in the analog memory. In such a method, since the electric charge held in the analog memory is generally subjected to destructive reading, the electric charge can be read only once, and there is a possibility that flexibility of processing is impaired.

Furthermore, in the technology disclosed in Patent Document 1, the electric charge held in the analog memory is read, but it is not sufficient for securing the flexibility of processing, and there has been a need for devising a technology to improve processing performance by performing the processing more flexibly.

The present disclosure has been made in view of such a situation, and is intended to further improve the processing performance.

### Solutions to Problems

A solid-state imaging device of one aspect of the present disclosure is a solid-state imaging device including an array unit in which a plurality of pixels each including a photoelectric conversion unit and an analog memory unit is arranged, in which the analog memory unit holds an electric charge photoelectrically converted by the photoelectric conversion unit by first exposure, and the electric charge held in the analog memory unit by the first exposure is adaptively and non-destructively read.

An electronic device of one aspect of the present disclosure is an electronic device equipped with a solid-state imaging device including an array unit in which a plurality of pixels each including a photoelectric conversion unit and an analog memory unit is arranged, in which the analog memory unit holds an electric charge photoelectrically converted by the photoelectric conversion unit by first exposure, and the electric charge held in the analog memory unit by the first exposure is adaptively and non-destructively read.

In the solid-state imaging device and the electronic device of one aspect of the present disclosure, the array unit is provided in which the plurality of pixels each including the photoelectric conversion unit and the analog memory unit is arranged, and in the analog memory unit, the electric charge photoelectrically converted by the photoelectric conversion unit by the first exposure is held, and the electric charge held in the analog memory unit by the first exposure is adaptively and non-destructively read.

Note that, the solid-state imaging device or the electronic device of one aspect of the present disclosure may be an independent device or an internal block constituting one device.

### BRIEF DESCRIPTION OF DRAWINGS

FIG. 1 is a diagram illustrating a first example of a configuration of a solid-state imaging device of a first embodiment.

FIG. 2 is a circuit diagram illustrating an example of a configuration of a pixel of the solid-state imaging device of the first embodiment.

FIG. 3 is a diagram illustrating a data flow of the first example of the configuration of the solid-state imaging device of the first embodiment.

FIG. 4 is a diagram illustrating a second example of the configuration of the solid-state imaging device of the first embodiment.

FIG. 5 is a diagram illustrating a data flow of the second example of the configuration of the solid-state imaging device of the first embodiment.

FIG. 6 is a timing chart illustrating an example of a method of driving the pixel of the solid-state imaging device of the first embodiment.

FIG. 7 is a diagram illustrating an example of processing of a camera device equipped with the solid-state imaging device of the first embodiment.

FIG. 8 is a timing chart illustrating an example of operation of the camera device equipped with the solid-state imaging device of the first embodiment.

FIG. 9 is a diagram illustrating an outline of a pixel of a solid-state imaging device of a second embodiment.

FIG. 10 is a diagram illustrating an outline of the solid-state imaging device of the second embodiment.

FIG. 11 is a circuit diagram illustrating an example of a configuration of the pixel of the solid-state imaging device of the second embodiment.

FIG. 12 is a diagram illustrating a first example of a configuration of the solid-state imaging device of the second embodiment.

FIG. 13 is a diagram illustrating a data flow of the first example of the configuration of the solid-state imaging device of the second embodiment.

FIG. 14 is a diagram illustrating a second example of the configuration of the solid-state imaging device of the second embodiment.

FIG. 15 is a diagram illustrating a data flow of the second example of the configuration of the solid-state imaging device of the second embodiment.

FIG. 16 is a timing chart illustrating an example of a method of driving the pixel of the solid-state imaging device of the second embodiment.

FIG. 17 is a diagram illustrating an example of processing of a camera device equipped with the solid-state imaging device of the second embodiment.

FIG. 18 is a timing chart illustrating a first example of a method of driving a pixel of a solid-state imaging device of a third embodiment.

FIG. 19 is a diagram illustrating an outline of the solid-state imaging device of the third embodiment.

FIG. 20 is a diagram illustrating the outline of the solid-state imaging device of the third embodiment.

FIG. 21 is a circuit diagram illustrating a first example of a configuration of the pixel of the solid-state imaging device of the third embodiment.

FIG. 22 is a circuit diagram illustrating a second example of the configuration of the pixel of the solid-state imaging device of the third embodiment.

FIG. 23 is a diagram illustrating an example of a configuration of the solid-state imaging device of the third embodiment.

FIG. 24 is a timing chart illustrating a second example of a method of driving the pixel of the solid-state imaging device of the third embodiment.

FIG. 25 is a diagram illustrating a first example of reading of the pixel of the solid-state imaging device of the third embodiment.

FIG. 26 is a diagram illustrating a second example of reading of the pixel of the solid-state imaging device of the third embodiment.

FIG. 27 is a diagram illustrating an example of a configuration of a digital processing unit of the solid-state imaging device of the third embodiment.

FIG. 28 is a diagram illustrating an example of processing of the digital processing unit of the solid-state imaging device of the third embodiment.

FIG. 29 is a diagram illustrating a data flow of the example of the configuration of the solid-state imaging device of the third embodiment.

FIG. 30 is a diagram illustrating a data flow of the example of the configuration of the solid-state imaging device of the third embodiment.

FIG. 31 is a diagram illustrating a data flow of the example of the configuration of the solid-state imaging device of the third embodiment.

FIG. 32 is a timing chart illustrating a first example of operation of the solid-state imaging device of the third embodiment.

FIG. 33 is a timing chart illustrating a second example of the operation of the solid-state imaging device of the third embodiment.

FIG. 34 is a diagram illustrating an example of re-exposure control of the solid-state imaging device of the third embodiment.

FIG. 35 is a diagram illustrating an example of the re-exposure control of the solid-state imaging device of the third embodiment.

FIG. 36 is a diagram illustrating an example of processing of a camera device equipped with the solid-state imaging device of the third embodiment.

FIG. 37 is a diagram illustrating an example of a configuration of an electronic device equipped with the solid-state imaging device.

FIG. 38 is a diagram illustrating a first example of a structure of the solid-state imaging device.

FIG. 39 is a diagram illustrating a second example of the structure of the solid-state imaging device.

FIG. 40 is a diagram illustrating a third example of the structure of the solid-state imaging device.

FIG. 41 is a diagram illustrating a first example of a configuration of the solid-state imaging device mounted on the electronic device.

FIG. 42 is a diagram illustrating a second example of the configuration of the solid-state imaging device mounted on the electronic device.

FIG. 43 is a diagram illustrating an example of a planar layout of pixels arranged two-dimensionally in a pixel array unit.

FIG. 44 is a diagram illustrating an example of a configuration of a column ADC unit.

FIG. 45 is a diagram illustrating an example of the planar layout of the pixels during all-pixel reading.

FIG. 46 is a timing chart illustrating an example of operation of the column ADC unit during the all-pixel reading.

FIG. 47 is a diagram illustrating an example of the planar layout of the pixels during thinning out reading.

FIG. 48 is a timing chart illustrating an example of operation of the column ADC unit during the thinning out reading.

FIG. 49 is a diagram illustrating an example of the planar layout of the pixels during pixel addition reading.

FIG. 50 is a diagram illustrating an outline of the pixel addition reading.

FIG. 51 is a timing chart illustrating an example of operation of the column ADC unit during the pixel addition reading.

FIG. 52 is a diagram illustrating usage examples of the solid-state imaging device.

FIG. 53 is a block diagram illustrating an example of a schematic configuration of a vehicle control system.

FIG. 54 is an explanatory diagram illustrating an example of installation positions of a vehicle exterior information detecting unit and an imaging unit.

### MODE FOR CARRYING OUT THE INVENTION

Hereinafter, embodiments of a technology (the present technology) according to the present disclosure will be described with reference to the drawings. Note that, the description will be given in the following order.

1. First Embodiment

2. Second Embodiment

3. Third Embodiment

4. Fourth Embodiment

5. Modifications

6. Usage examples of solid-state imaging device

7. Application example to mobile body

### 1. First Embodiment

(First Example of Configuration of Solid-State Imaging Device)

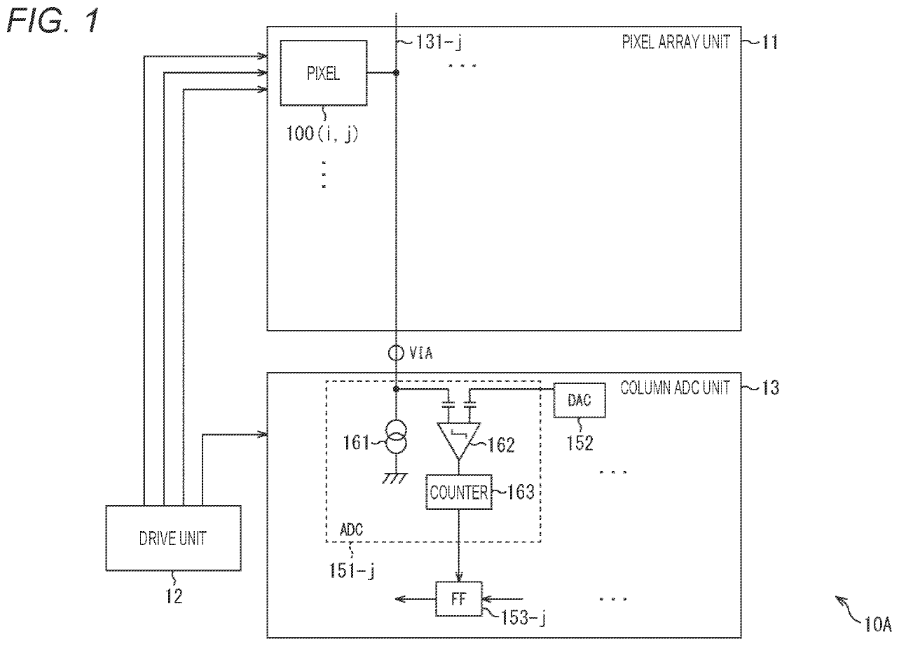

FIG. 1 is a diagram illustrating a first example of a configuration of a solid-state imaging device to which the technology according to the present disclosure is applied.

A solid-state imaging device 10A in FIG. 1 is configured as, for example, an image sensor using a Complementary Metal Oxide Semiconductor (CMOS) (CMOS image sensor). A solid-state imaging device 10 takes in incident light (image light) from a subject via an optical lens system (not illustrated), converts an amount of incident light formed as an image on an imaging surface into an electric signal on a pixel basis, and outputs the electric signal as a pixel signal.

In FIG. 1, the solid-state imaging device 10A includes a pixel array unit 11, a drive unit 12, and a column ADC unit 13.

In the pixel array unit 11, a plurality of pixels 100 is arranged two-dimensionally (in a matrix form). The pixels 100 each include a photodiode as a photoelectric conversion element (photoelectric conversion unit), and a plurality of pixel transistors. For example, the pixel transistors include a transfer transistor (TRG), a reset transistor (RST), an amplification transistor (AMP), and a selection transistor (SEL).

Note that, in the following description, a pixel in a row i and a column j of the pixels 100 arranged two-dimensionally in the pixel array unit 11 is also referred to as a pixel 100(i, j).

The drive unit 12 includes, for example, a shift register or the like, selects a predetermined pixel drive line, applies a drive signal (pulse signal) to the selected pixel drive line, to drive the pixels 100 on a row basis. That is, the drive unit 12 selectively scans the pixels 100 arranged in the pixel array unit 11 in the vertical direction sequentially on a row basis, and supplies the pixel signal corresponding to a signal charge (electric charge) generated depending on an amount of light received in the photodiode of each of the pixels 100 to the column ADC unit 13 through a vertical signal line 131.

The column ADC unit 13 is provided with an Analog to Digital Converter (ADC) 151-j for each column of pixels 100(i, j) arranged two-dimensionally in the pixel array unit 11. The ADC 151-j includes a constant current circuit 161, a comparator 162, and a counter 163.

The constant current circuit 161 is connected to one end of a vertical signal line 131-j connected to the pixels 100(i, j). The comparator 162 compares a signal voltage (Vx) from the vertical signal line 131-j input to the comparator 162 with a reference voltage (Vref) of a ramp wave (Ramp) from a Digital to Analog Converter (DAC) 152, and outputs an output signal of a level depending on the comparison result to the counter 163.

The counter 163 performs counting on the basis of the output signal from the comparator 162, and outputs the count value to an FF circuit 153-j. The count value held in the FF circuit 153-j is transferred (shifting a digital value) to a horizontal output line sequentially, and obtained as an imaging signal. For example, here, a reset component and a signal component of the pixel 100(i, j) are read in order, and each is counted and subtracted, whereby operation of Correlated Double Sampling (CDS) is performed.

Note that, in the solid-state imaging device 10A, a laminated structure (two-layer structure) can be adopted in which the pixel array unit 11 and the column ADC unit 13 are laminated and a signal line is connected via a through-via (VIA). Furthermore, the solid-state imaging device 10A can be, for example, a backside illumination type image sensor.

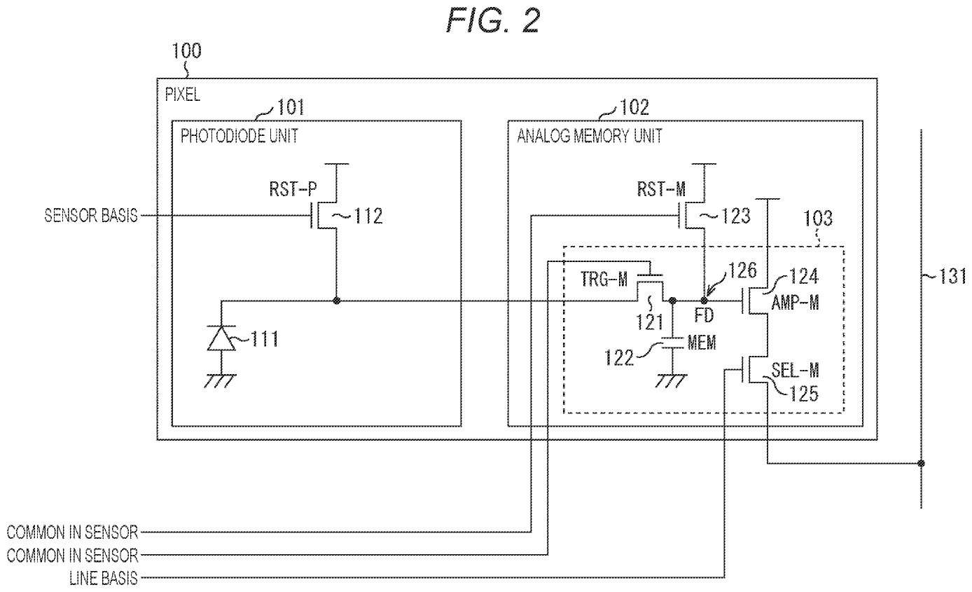

FIG. 2 illustrates an example of a configuration of the pixel 100 arranged two-dimensionally in the pixel array unit 11 of FIG. 1.

In FIG. 2, the pixel 100 includes a photodiode unit 101 and an analog memory unit 102. The photodiode unit 101 is a photoelectric conversion unit including a photodiode (PD) 111 and a reset transistor (RST-P) 112. The analog memory unit 102 includes a transfer transistor 121 (TRG-M), an analog memory (MEM) 122, a reset transistor (RST-M) 123, an amplification transistor (AMP-M) 124, and a selection transistor (SEL-M) 125.

The photodiode 111 has a photoelectric conversion region of a pn junction, for example, and generates and stores a signal charge (electric charge) depending on the amount of light received. The photodiode 111 is grounded at one end that is the anode electrode, and is connected to the source of the transfer transistor 121 at the other end that is the cathode electrode.

The reset transistor 112 is connected between the photodiode 111 and a power supply unit. A drive signal RST-P from the drive unit 12 (FIG. 1) is applied to the gate of the reset transistor 112. When the drive signal RST-P is in an active state, a reset gate of the reset transistor 112 is in a conductive state, and the photodiode 111 is reset.

In the analog memory unit 102, the drain of the transfer transistor 121 is connected to the source of the reset transistor 123 and the gate of the amplification transistor 124, and this connection point forms a floating diffusion (FD) 126 as a floating diffusion region.

The transfer transistor 121 is connected between the photodiode 111 and the floating diffusion 126. A drive signal TRG-M from the drive unit 12 (FIG. 1) is applied to the gate of the transfer transistor 121. When the drive signal TRG-M is in an active state, a transfer gate of the transfer transistor 121 is in a conductive state, and the electric charge stored in the photodiode 111 is transferred from the photodiode unit 101 side to the analog memory unit 102 side.

The analog memory 122 includes, for example, a capacitor, and its one pole plate is grounded, and the other pole plate is connected between the drain of the transfer transistor 121 and the floating diffusion 126. The analog memory 122 holds the electric charge transferred by the transfer transistor 121, that is, the electric charge from the photodiode 111.

The floating diffusion 126 performs charge-voltage conversion of the electric charge held in the analog memory 122, that is, the electric charge transferred by the transfer transistor 121 into a voltage signal, and outputs the voltage signal to (the gate of) the amplification transistor 124.

The reset transistor 123 is connected between the floating diffusion 126 and the power supply unit. A drive signal RST-M from the drive unit 12 (FIG. 1) is applied to the gate of the reset transistor 123. When the drive signal RST-M is in an active state, a reset gate of the reset transistor 123 is in a conductive state, and the floating diffusion 126 is reset.

The amplification transistor 124, in which the gate is connected to the floating diffusion 126 and the drain is connected to the power supply unit, serves as an input unit of a reading circuit for the voltage signal held by the floating diffusion 126, that is, a so-called source follower circuit. That is, in the amplification transistor 124, the source is connected to the vertical signal line 131 via the selection transistor 125, whereby a source follower circuit is formed by the amplification transistor 124 and the constant current circuit 161 (FIG. 1) connected to one end of the vertical signal line 131.

The selection transistor 125 is connected between the source of the amplification transistor 124 and the vertical signal line 131. A drive signal SEL-M from the drive unit 12 (FIG. 1) is applied to the gate of the selection transistor 125. When the drive signal SEL-M is in an active state, the selection transistor 125 is in a conductive state, and the pixel 100 is in a selected state. As a result, a read signal (pixel signal) output from the amplification transistor 124 is output to the vertical signal line 131 via the selection transistor 125.

In the pixel 100 configured as described above, the drive signals RST-P, TRG-M, and RST-M respectively applied to the gates of the reset transistor 112, the transfer transistor 121, and the reset transistor 123 are controlled commonly in the sensor (on a sensor basis), whereas the drive signal SEL-M applied to the gate of the selection transistor 125 is controlled on a line basis (on a row basis), whereby the electric charge stored in the photodiode 111 by exposure with a global shutter method is transferred and held in the analog memory 122, and (the pixel signal corresponding to) the electric charge held in the analog memory 122 is non-destructively read.

Note that, the reset transistor 123 may be shared for each any plurality of pixels 100 arranged in the pixel array unit 11, and in such pixels 100 sharing the reset transistor 123, the analog memory unit 102 includes elements in an area 103 excluding the reset transistor 123.

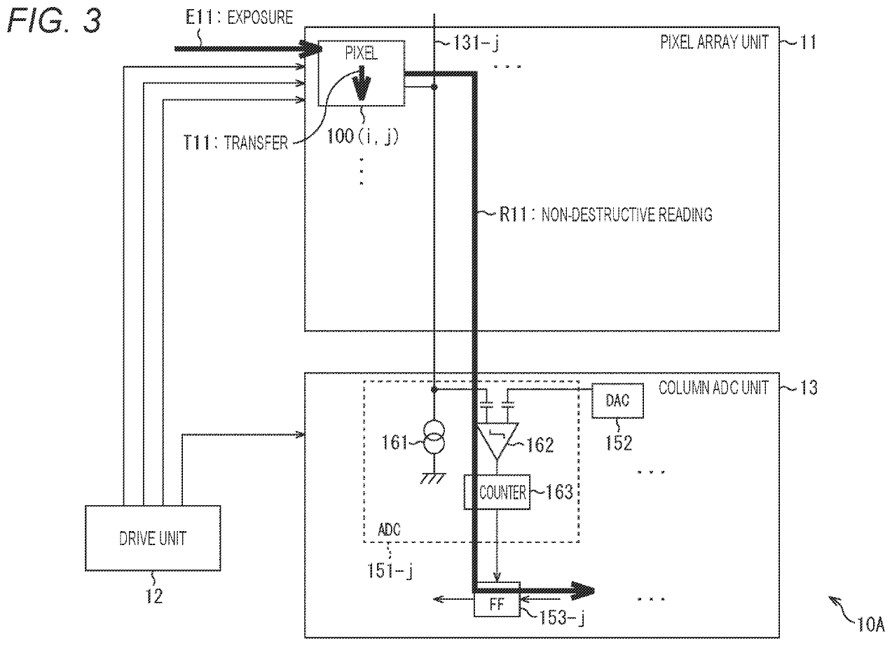

FIG. 3 illustrates a data flow of the solid-state imaging device 10A of FIG. 1.

In the pixels 100(i, j) arranged two-dimensionally in the pixel array unit 11 in the solid-state imaging device 10A, the electric charge stored in the photodiode 111 by exposure (Eli) with the global shutter method is transferred (T11) from the photodiode unit 101 to the analog memory unit 102, and held in the analog memory 122.

Then, the electric charge held in the analog memory 122 of the pixel 100(i, j) is non-destructively read (R11) in accordance with the drive signal from the drive unit 12, and input to the column ADC unit 13 via the vertical signal line 131-j.

In the ADC 151-j arranged for each column in the column ADC unit 13, the signal voltage (Vx) non-destructively read from the analog memory 122 of the pixel 100(i, j) and the reference voltage (Vref) of the ramp wave from the DAC 152 are compared with each other, and counting is performed depending on the comparison result, whereby an analog signal is converted into a digital signal and output to the outside.

As described above, in the solid-state imaging device 10A, non-destructive reading is performed during reading of the electric charge held in the analog memory 122 of the pixel 100, so that the electric charge stored in the photodiode 111 by one exposure and transferred to and held in the analog memory 122 can be read repeatedly any number of times.

(Second Example of Configuration of Solid-State Imaging Device)

By the way, the structure of the pixel 100 is not limited to the structure in which the photodiode unit 101 and the analog memory unit 102 are included in the same layer, but a structure (intra-pixel separation structure) may be adopted in which the photodiode unit 101 and the analog memory unit 102 are laminated to be respectively included in different layers and a signal line is connected via a through-via (VIA). Thus, next, such an intra-pixel separation structure will be described.

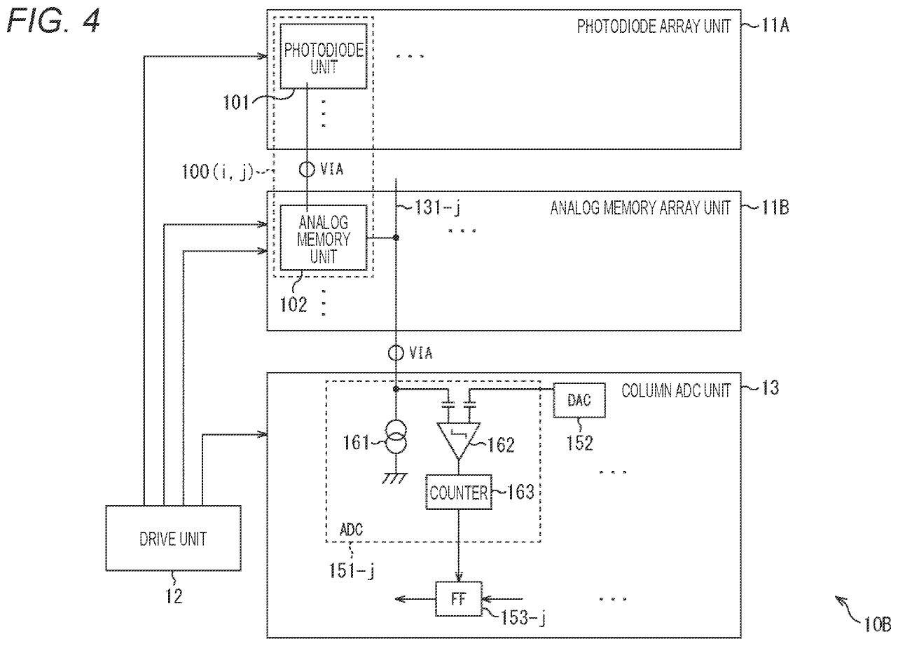

FIG. 4 is a diagram illustrating a second example of the configuration of the solid-state imaging device to which the technology according to the present disclosure is applied.

In FIG. 4, a solid-state imaging device 10B includes a photodiode array unit 11A, an analog memory array unit 11B, the drive unit 12, and the column ADC unit 13. That is, the solid-state imaging device 10B (FIG. 4) includes the photodiode array unit 11A and the analog memory array unit 11B laminated together instead of the pixel array unit 11 as compared with the solid-state imaging device 10A (FIG. 1).

In the photodiode array unit 11A, a plurality of the photodiode units 101 is arranged two-dimensionally (in a matrix form). In the analog memory array unit 11B, a plurality of the analog memory units 102 is arranged two-dimensionally (in a matrix form). Here, the plurality of photodiode units 101 arranged in the photodiode array unit 11A and the plurality of analog memory units 102 arranged in the analog memory array unit 11B are respectively formed at corresponding positions of the laminated layers, and connected together by the signal line via the through-via (VIA).

That is, (the cathode electrode of) the photodiode 111 of the photodiode unit 101 in the photodiode array unit 11A formed in a first layer and (the source of) the transfer transistor 121 of the analog memory unit 102 in the analog memory array unit 11B formed in a second layer are connected together by the signal line via the through-via (VIA). In this way, the photodiode unit 101 and the analog memory unit 102 are laminated to form the pixel 100(i, j).

Note that, in FIG. 4, the configurations of the photodiode unit 101 and the analog memory unit 102 are similar to those illustrated in FIG. 2, and thus detailed description thereof will be omitted here. Furthermore, in FIG. 4, the configuration of the column ADC unit 13 is similar to the configuration illustrated in FIG. 1, and a laminated structure (three-layer structure) can be made in which the column ADC unit 13 is further laminated with the analog memory array unit 11B laminated with the photodiode array unit 11A and signal lines are connected via through-vias (VIAs). Furthermore, the solid-state imaging device 10B can be, for example, a backside illumination type image sensor.

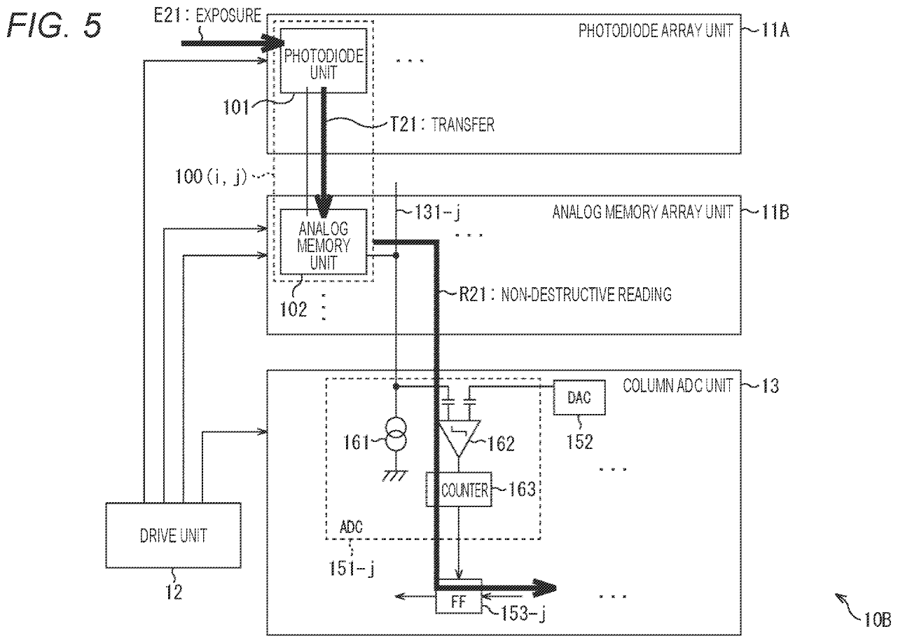

FIG. 5 illustrates a data flow of the solid-state imaging device 10B of FIG. 4.

In the photodiode unit 101 arranged two-dimensionally in the photodiode array unit 11A in the solid-state imaging device 10B, the electric charge stored in the photodiode 111 by exposure (E21) with the global shutter method is transferred (T21) to the analog memory unit 102 arranged in the analog memory array unit 11B, and held in the analog memory 122.

Then, the electric charge held in the analog memory 122 of the analog memory unit 102 of the pixel 100(i, j) is non-destructively read (R21) in accordance with the drive signal from the drive unit 12, and input to the column ADC unit 13 via the vertical signal line 131-j, and AD conversion is performed.

As described above, the solid-state imaging device 10B includes the photodiode array unit 11A and the analog memory array unit 11B laminated together, and non-destructive reading is performed during reading of the electric charge held in the analog memory 122 of the analog memory unit 102, so that the electric charge stored in the photodiode 111 by one exposure and transferred to and held in the analog memory 122 can be read repeatedly any number of times.

(Example of Driving Method)

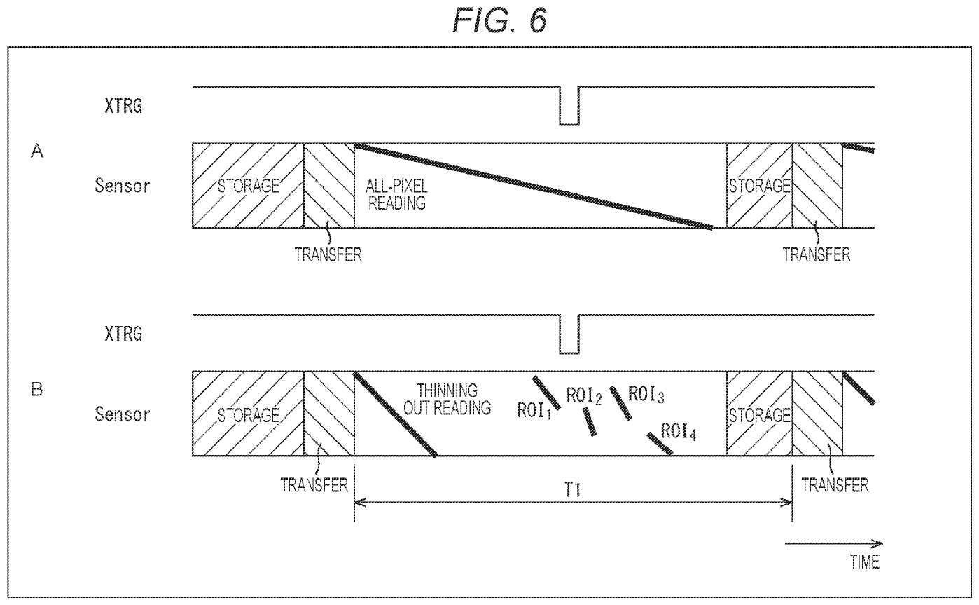

Next, with reference to a timing chart of FIG. 6, a description will be given of an example of a method of driving the pixel 100 of the solid-state imaging device 10 (10A, 10B) according to a first embodiment. Note that, in FIG. 6, for comparison, A of FIG. 6 illustrates a conventional driving method, and B of FIG. 6 illustrates a driving method of the first embodiment. Furthermore, in FIG. 6, the direction of time is a direction from the left side to the right side in the figure.

That is, in the case of the conventional driving method, an electric charge stored in a photodiode is transferred by the first exposure, electric charges of all pixels arranged in a pixel array unit are read, and similarly, also by the second and subsequent exposures, reading of all the pixels after the storage and transfer is repeated (A of FIG. 6).

On the other hand, in the case of the driving method of the first embodiment, during a period T1 that is after the electric charge stored in the photodiode 111 by the first exposure is transferred to the analog memory 122 and before the electric charge stored in the photodiode 111 by the second exposure is transferred to the analog memory 122, the electric charge held in the analog memory 122 by the first exposure can be read (non-destructively read) repeatedly any number of times (B of FIG. 6).

For example, in the solid-state imaging device 10, during the period T1, it is possible to read any pixels 100 by thinning out, among the pixels 100 (all pixels) arranged in the pixel array unit 11, or read pixels 100 corresponding to a target area (Region of Interest (ROI)) in an image frame. In the example of FIG. 6, electric charges held in the analog memories 122 of the pixels 100 corresponding to four different ROI areas (ROI₁, ROI₂, ROI₃, ROI₄) are respectively read at arbitrary timings within the period T1.

### Application Example

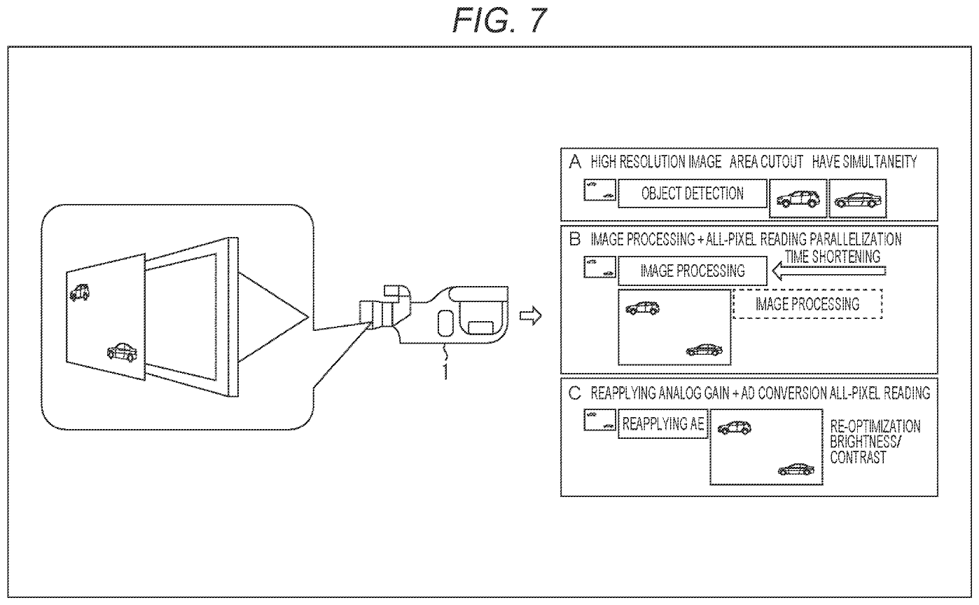

FIG. 7 illustrates an example of processing of a camera device equipped with the solid-state imaging device to which the technology according to the present disclosure is applied.

In FIG. 7, a camera device 1 equipped with the solid-state imaging device 10 (10A, 10B) has a function of outputting, prior to main processing, an image (reduced image) based on an electric charge (electric charge non-destructively read from the analog memory 122) obtained by thinning out any pixels 100 among the pixels 100 (all pixels) arranged in the pixel array unit 11, and then performing the main processing by using the reduced image. Here, three types of processing are exemplified as the main processing that can be executed by the camera device 1.

First, the camera device 1 can perform processing of detecting an object included in the reduced image and extracting an image (ROI image) of an arbitrary area (ROI area) including the detected object (A of FIG. 7).

For example, in this processing, ROI images (enlarged images of two cars) can be generated by non-destructively reading the electric charge held in the analog memory 122 for each of the plurality of pixels 100 and obtained by the same exposure as when the reduced image (image of a wide area including two cars) is generated. That is, the reduced image obtained by thinning out reading and the ROI image obtained by ROI reading have simultaneity, so that, for example, even in a case where the electric charge is read again by changing a cutout area and a reduction ratio on the basis of a result of object detection using the reduced image, it is possible to accurately inherit a position, size, shape, and the like on the image, and improve visibility (processing performance can be further improved).

Second, the camera device 1 can perform parallelized processing of non-destructively reading the electric charge held in the analog memory 122 while executing image processing with the reduced image (B of FIG. 7).

For example, here, it is possible to execute processing of reading the electric charges held in the analog memories 122 of all the pixels 100 (all pixels) arranged in the pixel array unit 11 to generate a high-resolution captured image (high-resolution image including two cars) in parallel with image processing using the reduced image (low-resolution image including two cars). That is, since the image processing using the reduced image and the processing of all-pixel reading can be parallelized and the processing time can be shortened, it is possible to improve, for example, throughput and response (processing performance can be further improved).

Third, the camera device 1 can execute again signal processing before and after the AD conversion depending on an imaging state of the reduced image (C of FIG. 7).

For example, here, it is possible to generate a re-optimized image (second optimized image) by non-destructively performing the all-pixel reading of the electric charge held in the analog memory 122 of the pixel 100 and obtained by the same exposure as when the reduced image (first optimized image) is generated, and reapplying the signal processing (for example, gain, clamp, or the like) before and after the AD conversion depending on the imaging state (for example, brightness, contrast, or the like) for each predetermined area in the reduced image. That is, depending on the imaging state of the reduced image, it is possible to perform the all-pixel reading and also perform re-optimization such as reapplying an analog gain and performing AD conversion, so that it is possible to improve, for example, visibility and recognition performance (processing performance can be further improved).

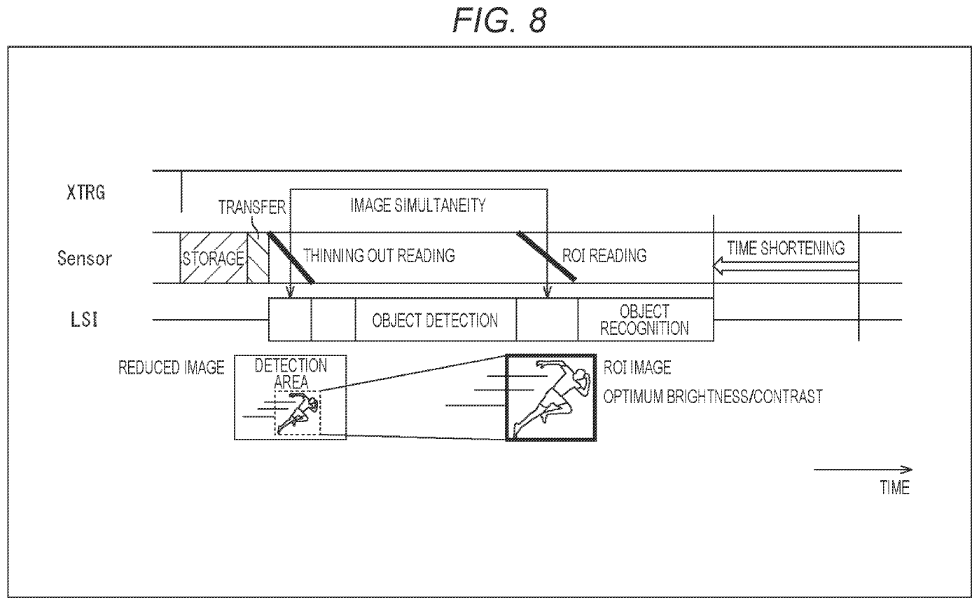

Note that, a timing chart of FIG. 8 illustrates an example of processing timing in a case where object detection and image recognition are performed by using a reduced image. In FIG. 8, in the camera device 1 equipped with the solid-state imaging device 10, an object is detected from the reduced image by object detection processing using the reduced image obtained by the thinning out reading, ROI reading is performed of an ROI area depending on a result of the object detection, and an ROI image is generated optimized (re-optimized) to the optimum brightness and contrast. Then, since the camera device 1 can perform object recognition processing using the optimized ROI image, object recognition performance (for example, recognition performance for a human face, a car model, or the like) can be improved.

Furthermore, in the description of FIGS. 6 to 8, for convenience of explanation, as the solid-state imaging device 10A (FIG. 1), a case has been mainly described where the pixel array unit 11 is provided, but similar processing can be performed even with the solid-state imaging device 10B (FIG. 4) provided with the photodiode array unit 11A and the analog memory array unit 11B instead of the pixel array unit 11.

In the above, the first embodiment has been described. In the solid-state imaging device 10 (10A, 10B) of the first embodiment, when exposure is performed at a constant period or at a predetermined timing, simultaneous exposure of all the pixels is performed with the global shutter method, and the electric charge stored in the photodiode 111 for each of the pixels 100 is transferred and held in the analog memory 122. As a result, when the electric charge held in the analog memory 122 for each pixel 100 is read, the electric charge can be non-destructively read as it is, and the electric charge can be read and processed any number of times repeatedly.

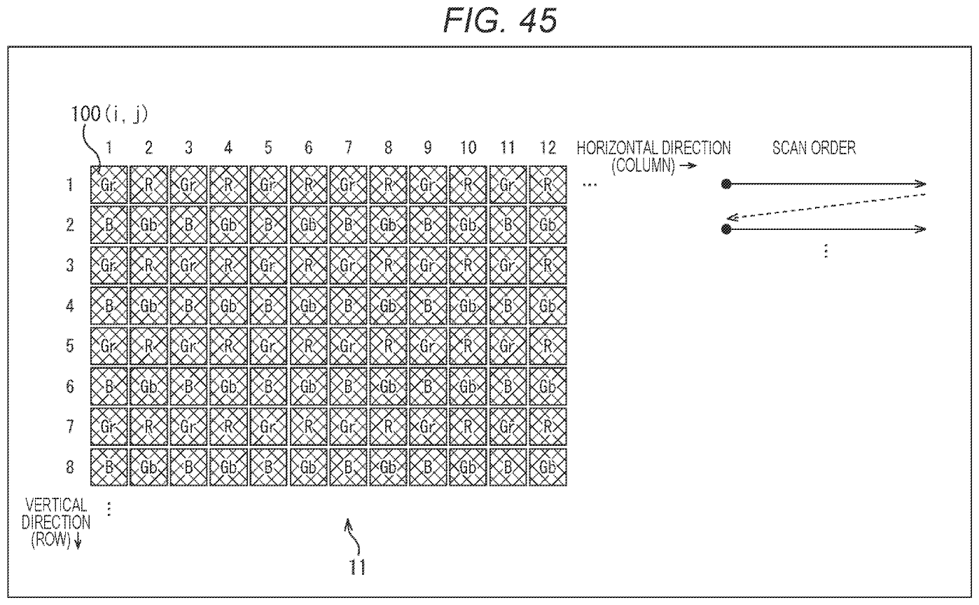

Furthermore, in the solid-state imaging device 10 (10A, 10B), during non-destructive reading of the electric charge held in the analog memory 122 for each of the plurality of pixels 100 arranged two-dimensionally, the electric charge can be adaptively read. For example, the electric charge held in the analog memory 122 for each of the plurality of pixels 100 can be read depending on an arbitrary area in the image frame, or a drive mode. Here, the arbitrary area includes, for example, an entire area, an ROI area, or the like. Furthermore, the drive mode includes, for example, all-pixel drive, thinning out drive, pixel addition reading drive, or the like. Note that, the details of reading by the all-pixel drive, thinning out drive, and the pixel addition reading drive will be described later with reference to FIGS. 45 to 46, 47 to 48, and 49 to 51, respectively.

Furthermore, for example, the exposure timing can be a predetermined timing such as a constant period depending on a frame rate, or notification of a trigger signal, and the electric charge held in the analog memory 122 for each of the plurality of pixels 100 may be non-destructively read depending on the predetermined timing.

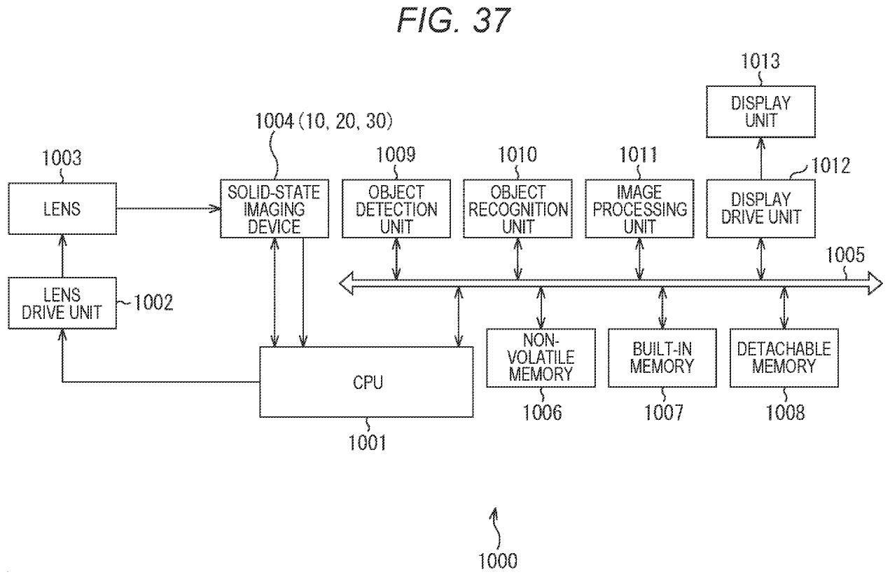

Moreover, for example, the solid-state imaging device 10 (10A, 10B) stores setting information in a register by serial communication with a control unit (for example, a CPU 1001 in FIG. 37 described later) of the camera device 1, and on the basis of the setting information, the drive unit 12 may cause the electric charge held in the analog memory 122 for each of the plurality of pixels 100 to be non-destructively read. Furthermore, for example, the electric charge held in the analog memory 122 for each of the plurality of pixels 100 may be non-destructively read depending on the signal processing (for example, gain, clamp, or the like) before and after the AD conversion by the column ADC unit 13.

Note that, the camera device 1 equipped with the solid-state imaging device 10 (10A, 10B) can output a reduced image at high speed by, for example, non-destructively reading an arbitrary area in the image frame by the thinning out reading or the pixel addition reading, and thereafter, can non-destructively read an image (for example, a high-resolution image or ROI image) of the arbitrary area captured at the same time as the previous reduced image by the all-pixel reading (or the thinning out reading or the pixel addition reading) and output the image.

Furthermore, in a case where the electric charge held in the analog memory 122 for each of the plurality of pixels 100 is non-destructively read, the resolution can be further increased but the sensitivity is lowered when the all-pixel reading is performed, whereas the resolution is decreased but the sensitivity can be further increased when the pixel addition reading is performed. Moreover, when the thinning out reading is performed, the resolution is lower than that of the all-pixel reading, and the sensitivity is lower than that of the pixel addition reading. As described above, the balance between the resolution and the sensitivity differs depending on the reading method, but in the solid-state imaging device 10 (10A, 10B), the electric charge held in the analog memory 122 for each of the plurality of pixels 100 can be read any number of times repeatedly, so that the optimum balance can be found.

### 2. Second Embodiment

By the way, since the configuration of the solid-state imaging device 10 of the first embodiment described above is a configuration in which the electric charge is held in the analog memory 122 of the pixel 100 and non-destructive reading is performed, it is not possible to read the electric charge stored in the photodiode 111 by new exposure in a state in which the electric charge is held in the analog memory 122.

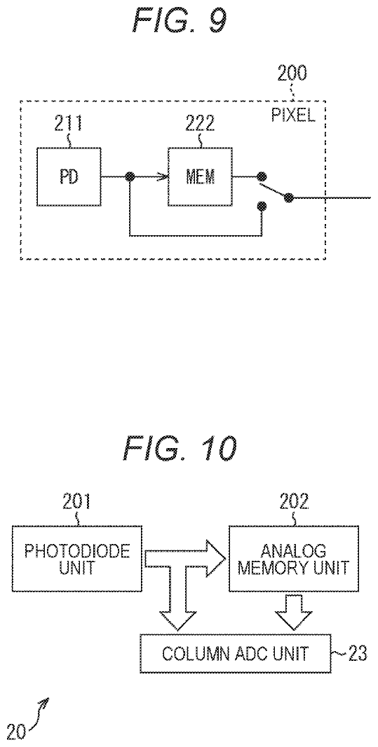

Thus, in a solid-state imaging device 20 of a second embodiment, as illustrated in a schematic diagram of FIG. 9, a configuration is adopted in which an electric charge stored in a photodiode (PD) 211 and an electric charge held in an analog memory (MEM) 222 can be switched, as an electric charge read in a pixel 200.

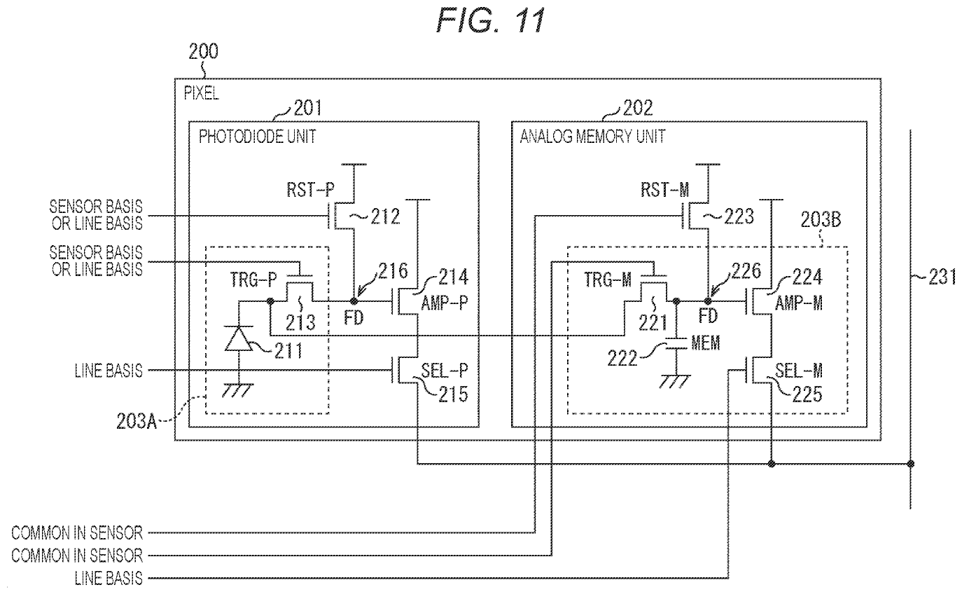

By adopting such a configuration, in the solid-state imaging device 20 of the second embodiment, it becomes possible to read the electric charge stored in the photodiode 211 by new exposure while the electric charge stored in the photodiode 211 of a photodiode unit 201 is transferred to an analog memory unit 202 and held in the analog memory 222 (FIG. 10).

FIG. 11 illustrates an example of a configuration of the pixel 200 of the second embodiment.

In FIG. 11, the pixel 200 includes the photodiode unit 201 and the analog memory unit 202. The photodiode unit 201 includes the photodiode 211, a reset transistor 212, a transfer transistor 213, an amplification transistor 214, and a selection transistor 215. The analog memory unit 202 includes a transfer transistor 221, the analog memory 222, a reset transistor 223, an amplification transistor 224, and a selection transistor 225.

In the photodiode unit 201, the photodiode 211 is grounded at one end that is the anode electrode, and is connected to the source of the transfer transistor 213 at the other end that is the cathode electrode. Furthermore, in the photodiode unit 201, the drain of the transfer transistor 213 is connected to the source of the reset transistor 212 and the gate of the amplification transistor 214, and this connection point forms a floating diffusion 216 as a floating diffusion region.

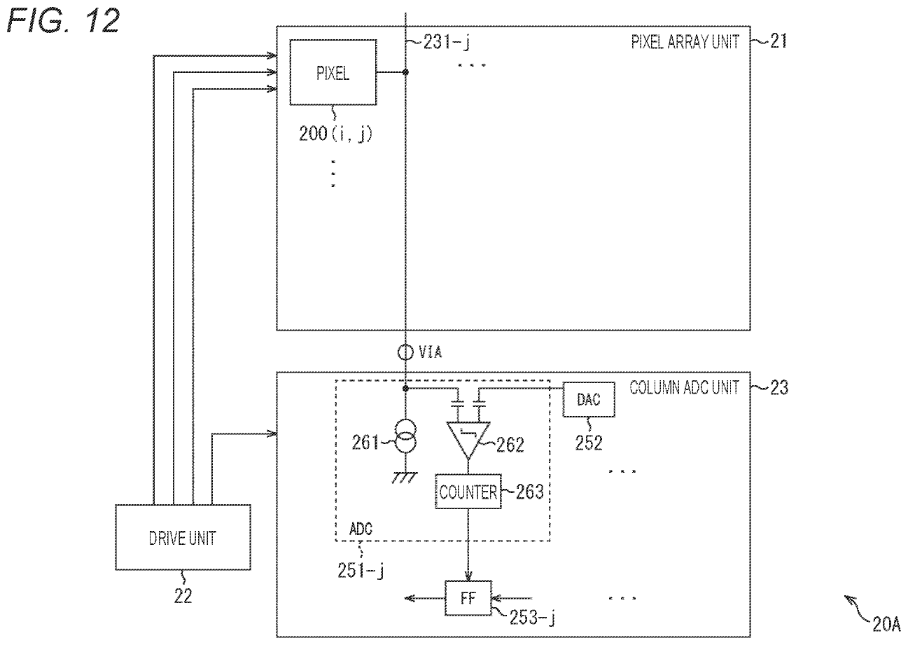

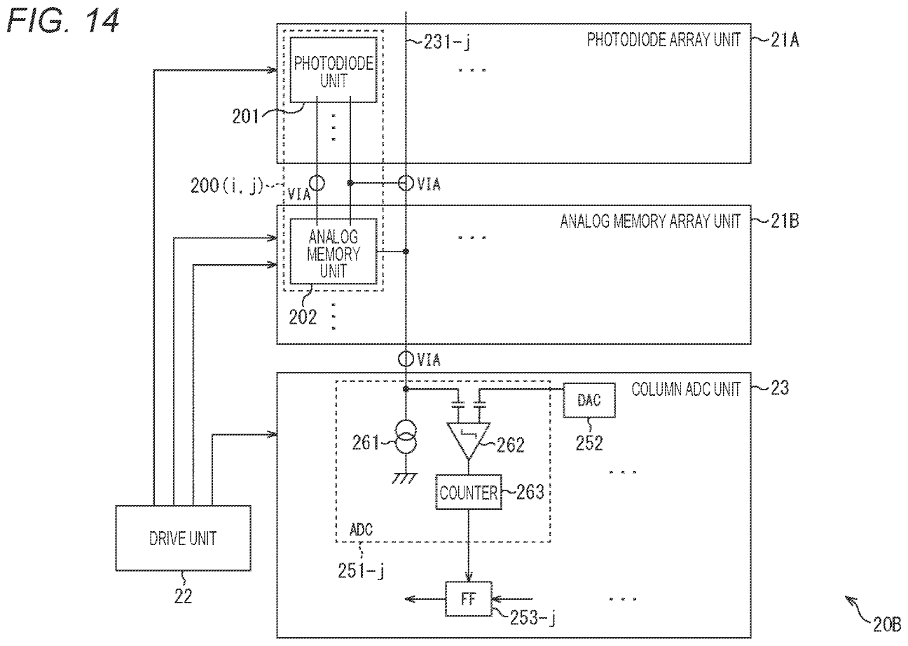

The transfer transistor 213 is connected between the photodiode 211 and the floating diffusion 216. A drive signal TRG-P from a drive unit 22 (FIG. 12 or 14, or the like) is applied to the gate of the transfer transistor 213. When the drive signal TRG-P is in an active state, the transfer gate of the transfer transistor 213 is in a conductive state, and the electric charge stored in the photodiode 211 is transferred to the floating diffusion 216.

The floating diffusion 216 performs charge-voltage conversion of the electric charge transferred by the transfer transistor 213 into a voltage signal, and outputs the voltage signal to (the gate of) the amplification transistor 214.

The reset transistor 212 is connected between the floating diffusion 216 and a power supply unit. A drive signal RST-P from the drive unit 22 (FIG. 12 or 14, or the like) is applied to the gate of the reset transistor 212. When the drive signal RST-P is in an active state, the reset gate of the reset transistor 212 is in a conductive state, and the floating diffusion 216 is reset.

The amplification transistor 214, in which the gate is connected to the floating diffusion 216 and the drain is connected to the power supply unit, serves as an input unit of a reading circuit for the voltage signal held by the floating diffusion 216, that is, a so-called source follower circuit. That is, in the amplification transistor 214, the source is connected to a vertical signal line 231 via the selection transistor 215, whereby a source follower circuit is formed by the amplification transistor 214 and a constant current circuit 261 (FIG. 12 or 14, or the like.) connected to one end of the vertical signal line 231.

The selection transistor 215 is connected between the source of the amplification transistor 214 and the vertical signal line 231. A drive signal SEL-P from the drive unit 22 (FIG. 12 or 14, or the like) is applied to the gate of the selection transistor 215. When the drive signal SEL-P is in an active state, the selection transistor 215 is in a conductive state, and the pixel 200 is in a selected state. As a result, a read signal (pixel signal) output from the amplification transistor 214 is output to the vertical signal line 231 via the selection transistor 215.

In the pixel 200, the analog memory unit 202 is configured similarly to the analog memory unit 102 in FIG. 2. That is, the transfer transistor 221 transfers the electric charge stored in the photodiode 211 from the photodiode unit 201 side to the analog memory unit 202 side. The electric charge transferred by the transfer transistor 221 is held in the analog memory 222.

Then, the electric charge held in the analog memory 222 is read at a predetermined timing, converted into a voltage signal by a floating diffusion 226, and output to (the gate of) the amplification transistor 224. The amplification transistor 224 functions as a reading circuit for the voltage signal held by the floating diffusion 226, and its read signal (pixel signal) is output to the vertical signal line 231 via the selection transistor 225.

In the pixel 200 configured as described above, on the analog memory unit 202 side, the drive signals TRG-M and RST-M respectively applied to the gates of the transfer transistor 221 and the reset transistor 223 are controlled commonly in the sensor, whereas the drive signal SEL-M applied to the gate of the selection transistor 225 is controlled on a line basis (on a row basis), whereby the electric charge stored in the photodiode 211 of the photodiode unit 201 is transferred and held in the analog memory 222, and (the pixel signal corresponding to) the electric charge held in the analog memory 222 is non-destructively read.

Furthermore, in the pixel 200, on the photodiode unit 201 side, the drive signal SEL-P applied to the gate of the selection transistor 215 is controlled on a line basis (on a row basis), but for the reset transistor 212 and the transfer transistor 213, the drive signals RST-P and TRG-P applied to the gates are controlled depending on the shutter method, whereby (the pixel signal corresponding to) the electric charge stored in the photodiode 211 is read. That is, the reset transistor 212 and the transfer transistor 213 are driven on a sensor basis in a case where the shutter method is the global shutter method, and driven on a line basis in a case where the shutter method is the rolling shutter method. Here, control (exclusive control) is performed so that the drive signal SEL-P applied to the selection transistor 215 on the photodiode unit 201 side and the drive signal SEL-M applied to the selection transistor 225 on the analog memory unit 202 side are not in active states at the same time, and the electric charge stored in the photodiode 211 and the electric charge held in the analog memory 222 are not read at the same time.

Note that, the reset transistor 212, the amplification transistor 214, and the selection transistor 215 on the photodiode unit 201 side may be shared for each any plurality of pixels 200, and in such pixels 200 sharing the transistors, the photodiode unit 201 includes elements in an area 203A including the photodiode 211 and the transfer transistor 213. Furthermore, the reset transistor 223 on the analog memory unit 202 side may be shared for each any plurality of pixels 200, and in such pixels 200 sharing the reset transistor 223, the analog memory unit 202 includes elements in an area 203B excluding the reset transistor 223.

(First Example of Configuration of Solid-State Imaging Device)

By the way, similarly to the solid-state imaging device 10 of the first embodiment, the solid-state imaging device 20 of the second embodiment may adopt either of a configuration in which the photodiode unit 201 and the analog memory unit 202 of the pixels 200 are arranged in a pixel array unit 21, or a configuration in which a photodiode array unit 21A and an analog memory array unit 21B are separately arranged. Thus, these configurations will be described in order below.

FIG. 12 is a diagram illustrating a first example of the solid-state imaging device to which the technology according to the present disclosure is applied.

In FIG. 12, a solid-state imaging device 20A includes the pixel array unit 21, the drive unit 22, and a column ADC unit 23, similarly to the solid-state imaging device 10A (FIG. 1). A plurality of pixels 200(i, j) is arranged two-dimensionally in the pixel array unit 21. The plurality of pixels 200(i, j) arranged in the pixel array unit 21 is driven in accordance with the drive signal from the drive unit 22, and the electric charge held in the analog memory 222 or the electric charge stored in the photodiode 211 is read and input to the column ADC unit 23 via a vertical signal line 231-j.

The column ADC unit 23 is provided with an ADC 251-j for each column of the pixels 200(i, j) arranged two-dimensionally in the pixel array unit 21. In the ADC 251-j, a comparator 262 compares a signal voltage (Vx) from the vertical signal line 231-j with a reference voltage (Vref) of a ramp wave (Ramp) from a DAC 252, an output signal of a level depending on of the comparison result is counted by a counter 263, and the count value is output to an FF circuit 253-j. Then, the count value held in the FF circuit 253-j is transferred to the horizontal output line sequentially.

Note that, in the solid-state imaging device 20A, a laminated structure (two-layer structure) can be adopted in which the pixel array unit 21 and the column ADC unit 23 are laminated, similarly to the solid-state imaging device 10A (FIG. 1).

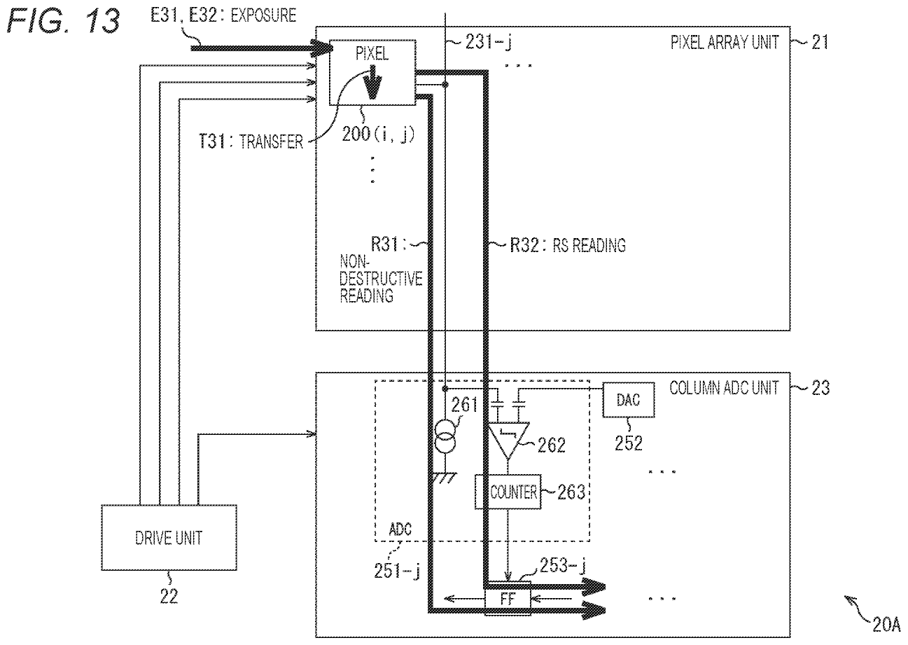

FIG. 13 illustrates a data flow of the solid-state imaging device 20A of FIG. 12.

In the solid-state imaging device 20A, in the pixels 200(i, j) arranged in the pixel array unit 21, the electric charge stored in the photodiode 211 by exposure (E31) with the global shutter method is transferred (T31) from the photodiode unit 201 to the analog memory unit 202, and held in the analog memory 222.

Then, the electric charge held in the analog memory 222 of the pixel 200(i, j) is non-destructively read (R31) in accordance with the drive signal from the drive unit 22, and input to the column ADC unit 23 via the vertical signal line 231-j.

In the column ADC unit 23, in the ADC 251-j arranged for each column, the signal voltage (Vx) non-destructively read from the analog memory 222 of the pixel 200(i, j) and the reference voltage (Vref) of the ramp wave from the DAC 252 are compared with each other, and counting is performed depending on the comparison result, whereby an analog signal is converted into a digital signal and output to the outside.

At this time, in the pixel 200(i, j), in a case where the electric charge is read by new exposure in a state in which the electric charge is held in the analog memory 222, exposure (E32) with the rolling shutter method is performed, and the electric charge stored in the photodiode 211 by the new exposure is read (R32) from the photodiode unit 201 side without being transferred to the analog memory 222. The electric charge read from the photodiode unit 201 side is input to (the ADC 251-j of) the column ADC unit 23 via the vertical signal line 231-j, and is converted from an analog signal to a digital signal.

As described above, in the solid-state imaging device 20A, non-destructive reading is performed during reading of the electric charge held in the analog memory 222 for each pixel 200, so that the electric charge stored in the photodiode 211 by one exposure and transferred to and held in the analog memory 222 can be read repeatedly any number of times. Furthermore, in the solid-state imaging device 20A, it is possible to read the electric charge stored in the photodiode 211 by the new exposure with the rolling shutter method while holding the electric charge in the analog memory 222 for each pixel 200.

(Second Example of Configuration of Solid-State Imaging Device)

FIG. 14 is a diagram illustrating a second example of the configuration of the solid-state imaging device to which the technology according to the present disclosure is applied.

In FIG. 14, a solid-state imaging device 20B includes the photodiode array unit 21A, the analog memory array unit 21B, the drive unit 22, and the column ADC unit 23, similarly to the solid-state imaging device 10B (FIG. 4).

That is, the solid-state imaging device 20B (FIG. 14) includes the photodiode array unit 21A in which a plurality of the photodiode units 201 is arranged two-dimensionally and the analog memory array unit 21B in which a plurality of the analog memory units 202 is arranged two-dimensionally that are laminated together, instead of the pixel array unit 21, as compared with the solid-state imaging device 20A (FIG. 12).

Here, (the cathode electrode of) the photodiode 211 of the photodiode unit 201 in the photodiode array unit 21A formed in a first layer and (the source of) the transfer transistor 221 of the analog memory unit 202 in the analog memory array unit 21B formed in a second layer are connected together by a signal line via a through-via (VIA).

Furthermore, (the source of) the selection transistor 215 of the photodiode unit 201 in the photodiode array unit 21A is connected to the vertical signal line 231-j via a through-via (VIA). In this way, the photodiode unit 201 and the analog memory unit 202 are laminated to form the pixel 200(i, j).

Note that, in FIG. 14, the configuration of the column ADC unit 23 is similar to the configuration illustrated in FIG. 12. Furthermore, in the solid-state imaging device 20B, similarly to the solid-state imaging device 10B (FIG. 4), a laminated structure (three-layer structure) can be adopted in which the photodiode array unit 21A, the analog memory array unit 21B, and the column ADC unit 23 are laminated.

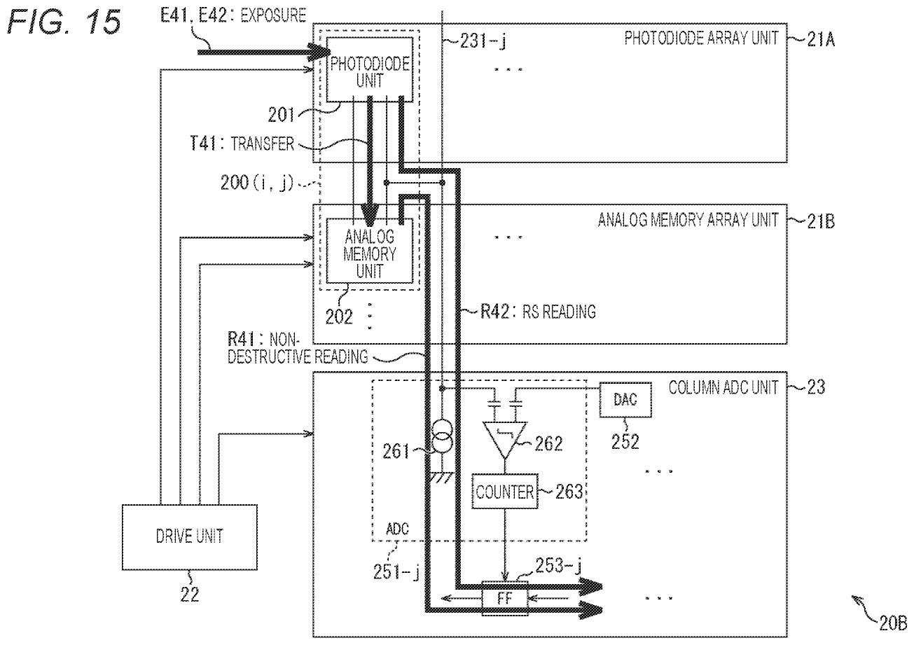

FIG. 15 illustrates a data flow of the solid-state imaging device 20B of FIG. 14.

In the solid-state imaging device 20B, in the photodiode unit 201 arranged in the photodiode array unit 21A, the electric charge stored in the photodiode 211 by exposure (E41) with the global shutter method is transferred (T41) to the analog memory unit 202 arranged in the analog memory array unit 21B, and held in the analog memory 222.

Then, the electric charge held in the analog memory 222 of the analog memory unit 202 of the pixel 200(i, j) is non-destructively read (R41) in accordance with the drive signal from the drive unit 22, and input to the column ADC unit 23 via the vertical signal line 231-j, and AD conversion is performed.

At this time, in the pixel 200(i, j), in a case where the electric charge is read by new exposure in a state in which the electric charge is held in the analog memory 222, exposure (E42) with the rolling shutter method is performed. Then, the electric charge stored in the photodiode 211 by the new exposure is read (R42) from the photodiode unit 201 side in accordance with the drive signal from the drive unit 22, and input to the column ADC unit 23 via the vertical signal line 231-j, and AD conversion is performed.

As described above, in the solid-state imaging device 20B, non-destructive reading is performed during reading of the electric charge held in the analog memory 222 for each pixel 200, so that the electric charge stored in the photodiode 211 by one exposure and transferred to and held in the analog memory 222 can be read repeatedly any number of times. Furthermore, in the solid-state imaging device 20B, it is possible to read the electric charge stored in the photodiode 211 by the new exposure with the rolling shutter method while holding the electric charge in the analog memory 222 for each pixel 200.

(Example of Driving Method)

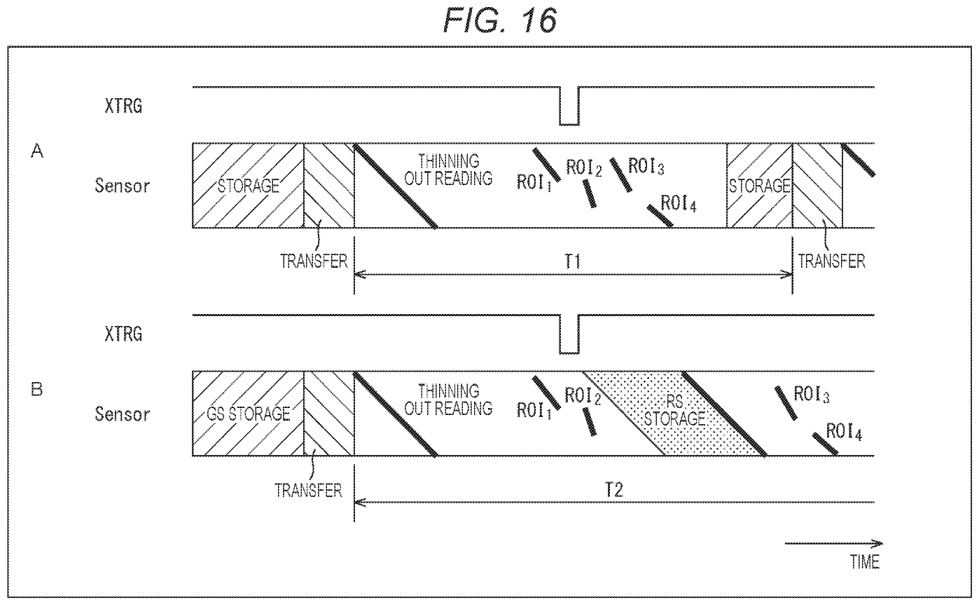

Next, with reference to the timing chart of FIG. 16, a description will be given of an example of a method of driving the pixel 200 of the solid-state imaging device 20 (20A, 20B) of the second embodiment. Note that, in FIG. 16, for comparison, A of FIG. 16 illustrates the driving method of the first embodiment, and B of FIG. 16 illustrates a driving method of the second embodiment.

That is, in the case of the driving method of the first embodiment, during a period T1 that is after the electric charge stored in the photodiode 111 by the first exposure is transferred and before the electric charge stored in the photodiode 111 by the second exposure is transferred, the electric charge held in the analog memory 122 by the first exposure can be read any number of times (A of FIG. 16). However, during this period T1, although new exposure is possible, the electric charge stored in the photodiode 111 cannot be read.

On the other hand, in the case of the driving method of the second embodiment, even during a period T2 that is after the electric charge stored in the photodiode 211 by the first exposure is transferred to the analog memory 222, the electric charge stored (RS storage) in the photodiode 211 by new exposure (exposure with the rolling shutter method) can be read in a state in which the electric charge is held in the analog memory 222 by first exposure (B of FIG. 16).

For example, in the solid-state imaging device 20, during the period T2, it is possible to read any pixels 200 by thinning out, among the plurality of pixels 200 (all pixels) arranged in the pixel array unit 21, or read pixels 200 corresponding to a target area (ROI area) in an image frame (B of FIG. 16). Moreover, in the solid-state imaging device 20, during the period T2, the electric charge stored (RS storage) in the photodiode 211 by the exposure with the rolling shutter method can be read in a state in which the electric charge is held in the analog memory 222 of the pixel 200.

### Application Example

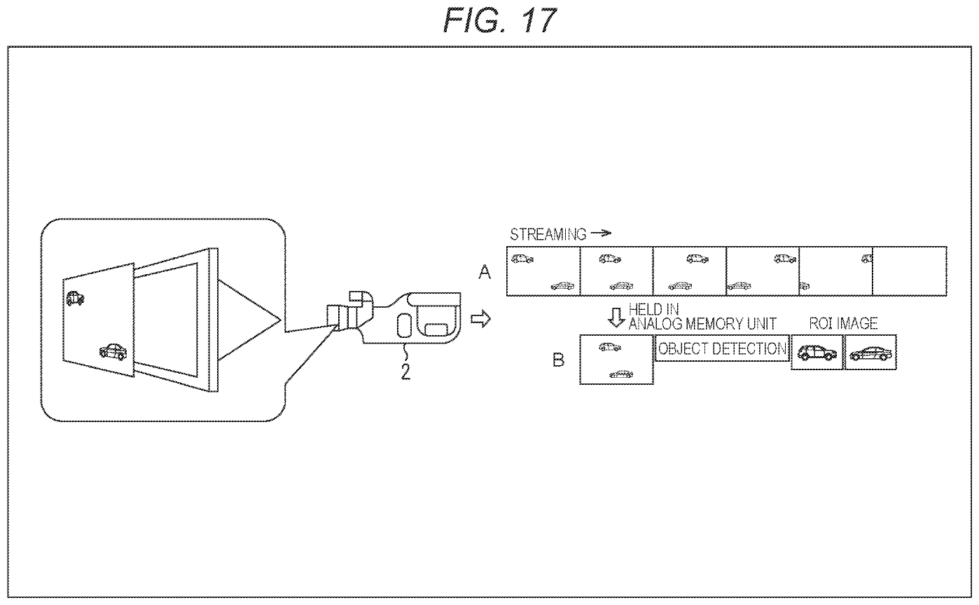

FIG. 17 illustrates an example of processing of a camera device equipped with the solid-state imaging device to which the technology according to the present disclosure is applied.

In FIG. 17, a camera device 2 equipped with the solid-state imaging device 20 (20A, 20B) can perform processing on an arbitrary image frame during streaming playback of a moving image based on a captured image (image frame).

For example, in this processing, the image frame is generated by reading the electric charge stored in the photodiode 211 of the pixel 200 by exposure with the rolling shutter method, and streaming playback of the moving image (video of two cars running in left and right opposite directions) is performed (A of FIG. 17). Here, at the time of imaging of the second image frame (A of FIG. 17), the electric charge stored in the photodiode 211 is transferred to the analog memory 222 of the pixel 200 and held (B of FIG. 17). As a result, the electric charge held in the analog memory 222 for each pixel 200 and corresponding to the second image frame (A of FIG. 17) can be non-destructively read (B of FIG. 17).

Then, in this processing, the electric charge held in the analog memory 222 for each pixel 200 is non-destructively read, whereby the captured image (image of two cars running in left and right opposite directions) corresponding to the second image frame (A of FIG. 17) is generated, objects (two cars) included in the generated captured image are detected, and ROI images (enlarged images of two cars) of arbitrary areas including the detected objects are generated (B of FIG. 17).

Note that, in the description of FIGS. 16 to 17, for convenience of explanation, as the solid-state imaging device 20A (FIG. 12), a case has been mainly described where the pixel array unit 21 is provided, but the same applies to the solid-state imaging device 20B (FIG. 14) provided with the photodiode array unit 21A and the analog memory array unit 21B instead of the pixel array unit 21.

In the above, the second embodiment has been described. In the solid-state imaging device 20 (20A, 20B) of the second embodiment, the pixel 200 is provided capable of switching between reading the electric charge stored in the photodiode 211 and reading the electric charge held in the analog memory 222. As a result, while the electric charge stored in the photodiode 211 by the first exposure is transferred to and held in the analog memory 222, the electric charge stored in the photodiode 211 by the second exposure can be read, so that it is possible not only to non-destructively read the electric charge held in the analog memory 222 any number of times repeatedly, but also to read the electric charge obtained by new exposure.

That is, if the device only has a function of non-destructively reading the electric charge held in the analog memory 222, a period during which the electric charge by the same exposure can be read is limited to a constant period in a case where imaging is performed at the constant period depending on the frame rate, for example, and it takes time to perform, for example, object detection processing, and there is a possibility that a situation of a subject during that time cannot be grasped and convenience becomes poor in a case where the electric charge by the same exposure is further read depending on the detection result. On the other hand, by adding a function of reading the electric charge obtained by the new exposure, it becomes possible to arbitrarily select, for example, whether or not to hold the electric charge in the analog memory 222, so that the convenience can be improved.

Here, in the first exposure, the exposure is performed, for example, with the global shutter method or the rolling shutter method. On the other hand, in the second exposure, the exposure is performed, for example, with the rolling shutter method. Here, by performing both the first exposure and the second exposure with the rolling shutter method, it is possible to improve the simultaneity between a captured image obtained by reading the electric charge held in the analog memory 222 by the first exposure and a captured image obtained by reading the electric charge stored in the photodiode 211 by the second exposure, also from a viewpoint of rolling shutter distortion.

Furthermore, in the solid-state imaging device 20 (20A, 20B), similarly to the solid-state imaging device 10, during non-destructive reading of the electric charge held in the analog memory 222 for each of the plurality of pixels 200 arranged two-dimensionally, the electric charge can be read adaptively. For example, the electric charge held in the analog memory 222 for each of the plurality of pixels 200 can be read depending on an arbitrary area (for example, entire area or ROI area) in the image frame, or a drive mode (for example, all-pixel drive, thinning out drive, pixel addition reading drive, or the like).

Furthermore, for example, the exposure timing can be a predetermined timing such as a constant period depending on a frame rate, or notification of a trigger signal, and the electric charge held in the analog memory 122 for each of the plurality of pixels 200 may be non-destructively read depending on the predetermined timing. Furthermore, for example, the electric charge held in the analog memory 222 for each of the plurality of pixels 200 may be non-destructively read depending on the signal processing (for example, gain, clamp, or the like) before and after the AD conversion by the column ADC unit 23.

Note that, in the above description, a case has been described where the electric charge held in the analog memory 222 by the first exposure and the electric charge stored in the photodiode 211 by the second exposure are read separately; however, the electric charge held in the analog memory 222 and the electric charge stored in the photodiode 211 may be added together and read. Furthermore, in a case where this addition reading (PD+MEM addition reading) is performed, the first exposure and the second exposure may be the same exposure.

Furthermore, in a case where the electric charge held in the analog memory 222 for each pixel 200 or the electric charge stored in the photodiode 211 of the pixel 200 is read, the resolution can be further increased but the sensitivity is lowered when the all-pixel reading is performed, whereas the resolution is decreased but the sensitivity can be further increased when the pixel addition reading is performed. Moreover, when the thinning out reading is performed, the resolution is lower than that of the all-pixel reading, and the sensitivity is lower than that of the pixel addition reading.

As described above, the balance between the resolution, the sensitivity, and the exposure time (number of times) differs depending on the reading method, but in the solid-state imaging device 20 (20A, 20B), the electric charge held in the analog memory 222 for each of the plurality of pixels 200 can be read any number of times repeatedly, and also the electric charge obtained by new exposure can be read, so that the optimum balance can be found.

### 3. Third Embodiment

By the way, in a conventional camera device, various imaging modes are prepared, for example, an SN priority mode (high sensitivity and low noise priority mode), a motion priority mode, and the like, but the exposure of the mounted solid-state imaging device and the signal processing before and after the AD conversion are performed only once. For that reason, depending on a subject, there has been a case where overexposure or underexposure occurs on the captured image.

Furthermore, some conventional camera devices have improved visibility by combining the results of multiple exposures for a short time and a long time, such as a Wide Dynamic Range (WDR) mode, but the amount of electric charge that has already been exposed cannot be changed even if there is a change in the subject during the multiple exposures, so there has been a case where false color or blur occurs on the captured image, for example, and improvement in visibility has been required.

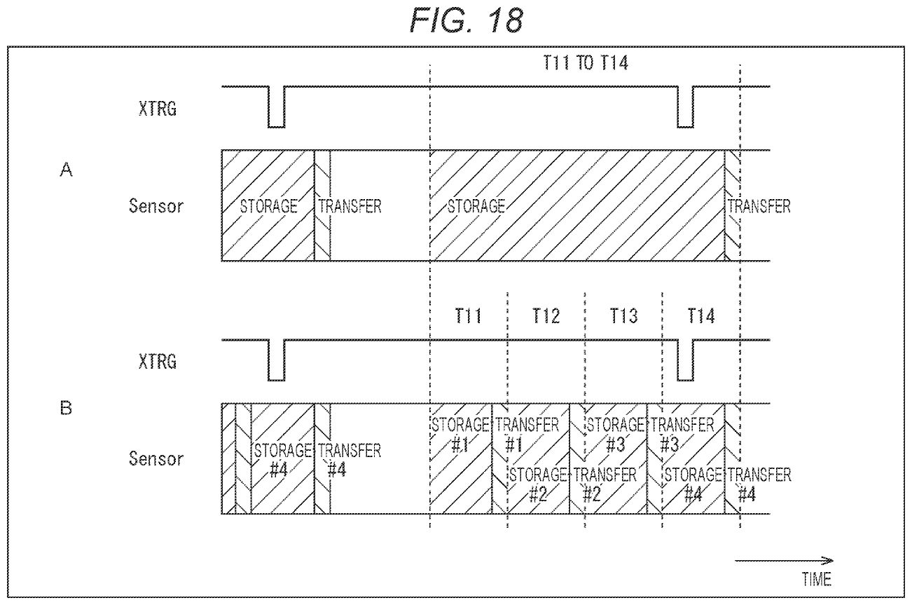

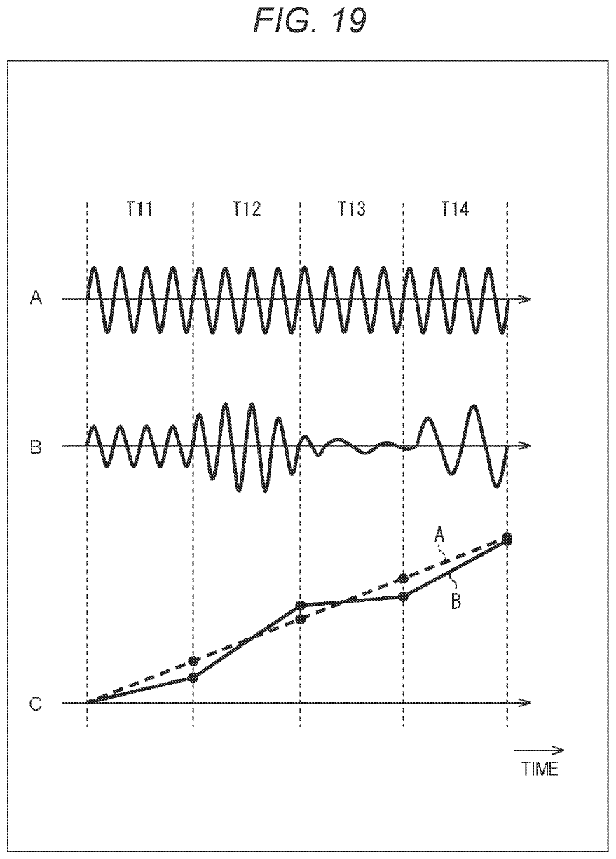

Thus, in a solid-state imaging device 30 of a third embodiment, a plurality of analog memories 332 is provided in a pixel 300, and an electric charge stored in a photodiode 311 obtained by time-division of one exposure is transferred as an electric charge held in each of the analog memories 332, and electric charges held in the analog memories 322 are selectively added together and output (FIGS. 18 to 20).

More specifically, as illustrated in a timing chart of FIG. 18, in the case of a conventional driving method, an electric charge stored in a photodiode by the first exposure is transferred as it is (A of FIG. 18). On the other hand, in the case of a driving method of the pixel 300 of the solid-state imaging device 30, one exposure is subjected to time-division (for example, divided into four of T11, T12, T13, and T14), and electric charges stored (for example, storage #1, storage #2, storage #3, storage #4) in the photodiode 311 are sequentially transferred (for example, transfer #1, transfer #2, transfer #3, transfer #4) to analog memories 322-1 to 322-4 (B of FIG. 18). The electric charges respectively held in the analog memories 322-1 to 322-4 in this way can be selectively and non-destructively read.

Here, FIG. 19 illustrates, as a temporal change of the amount of exposure, a wave of light in a case where there is no movement of the subject (A of FIG. 19) and a wave of light in a case where there is movement of the subject (B of FIG. 19). Furthermore, results of integrating pixel values corresponding to those waves of the light are illustrated in C of FIG. 19, for example. In C of FIG. 19, a dotted line A represents the result of integrating the pixel values corresponding to the wave of light of A of FIG. 19, and a solid line B is the result of integrating the pixel values corresponding to the wave of light of B of FIG. 19. That is, the result of integrating the pixel values is linear in a case where there is no change, and is irregular in a case where there is a change, and the solid-state imaging device 30 detects this.

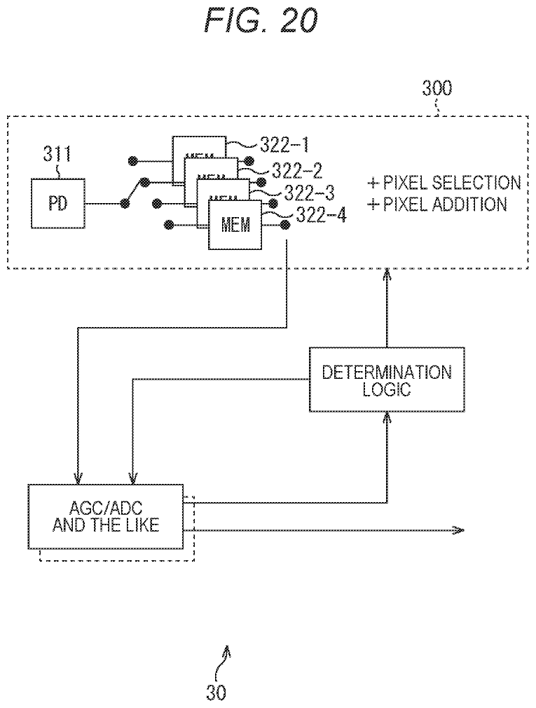

That is, in the solid-state imaging device 30, since one exposure is subjected to time-division (for example, divided into four of T11, T12, T13, and T14), it becomes possible to detect a change in the amount of electric charge and the timing of saturation within one exposure (FIG. 20). For that reason, in the solid-state imaging device 30, in a case where the electric charges held in the analog memories 322-1 to 322-4 of the pixel 300 are read again, it is possible to perform signal processing (for example, Auto Gain Control (AGC) or the like) before and after the AD conversion after reading only appropriate electric charges selectively and performing addition appropriately (FIG. 20). As a result, a processing unit in the subsequent stage can generate a captured image in which, for example, overexposure, motion blur, and underexposure are eliminated.

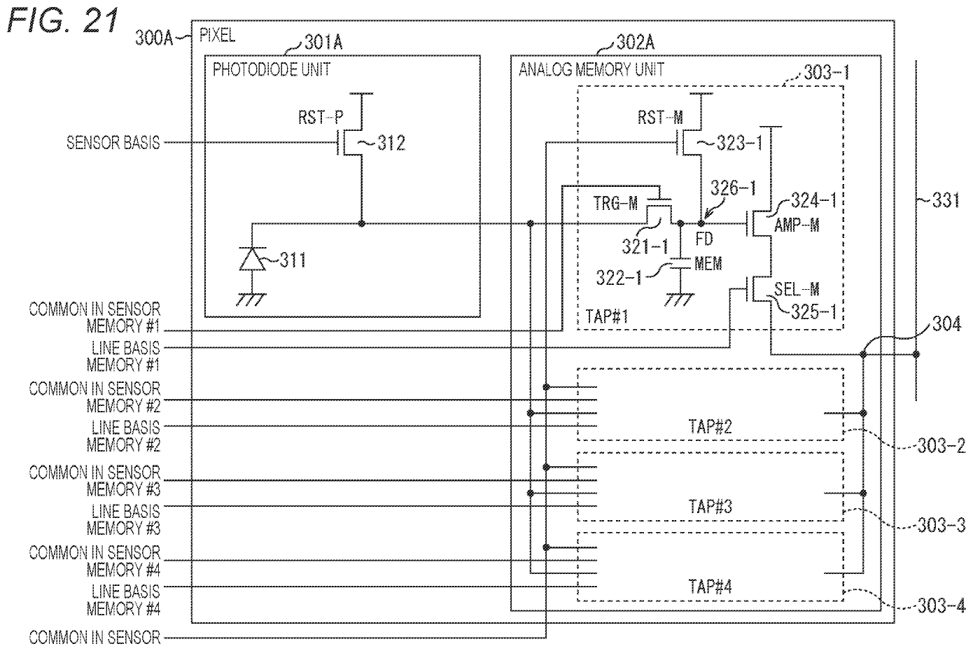

FIG. 21 illustrates a first example of a configuration of the pixel 300 of the third embodiment.

In FIG. 21, a pixel 300A includes a photodiode unit 301A and an analog memory unit 302A.

The photodiode unit 301A includes the photodiode 311 and a reset transistor 312. That is, the photodiode unit 301 is configured similarly to the photodiode unit 101 of FIG. 2, and transfers the electric charge stored in the photodiode 311 from the photodiode unit 301A side to the analog memory unit 302A side.

The analog memory unit 302A includes taps 303-1 to 303-4. In the analog memory unit 302A, the tap 303-1 is configured similarly to the analog memory unit 102 of FIG. 2, and includes a transfer transistor 321-1, the analog memory 322-1, a reset transistor 323-1, an amplification transistor 324-1, and a selection transistor 325-1.

Furthermore, although not illustrated, the taps 303-2 to 303-4 are configured similarly to the tap 303-1, and each include the transfer transistor 321-n, the analog memory 322-n, the reset transistor 323-n, the amplification transistor 324-n, and the selection transistor 325-n. Here, n is a value corresponding to the tap 303-n (n=2, 3, 4).

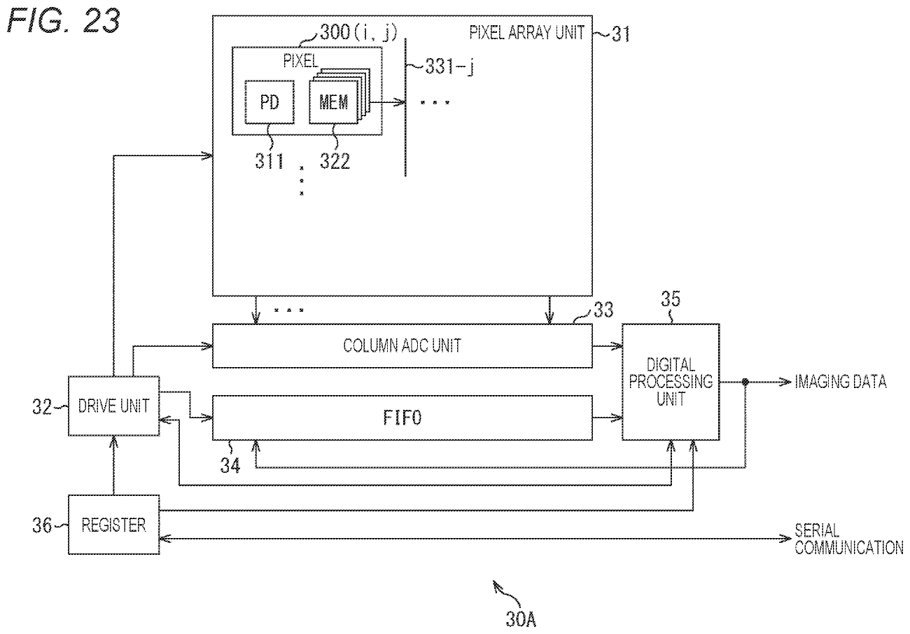

In the analog memory unit 302A, the pixel transistors provided in each of the taps 303-1 to 303-4 are driven in accordance with drive signals from a drive unit 32 (FIG. 23), whereby one exposure is divided by an arbitrary number (maximum four divisions) and the electric charge stored in the photodiode 311 is transferred to the analog memory 322 of any tap 303 among the taps 303-1 to 303-4 of four stages. As described above, since the analog memory unit 302A is provided with the taps 303-1 to 303-4 of four stages, the electric charges obtained by time-division of one exposure can be sequentially held in any of the analog memories 322-1 to 322-4.

Furthermore, in the analog memory unit 302A, the pixel transistors provided in each of the taps 303-1 to 303-4 are driven in accordance with drive signals from the drive unit 32 (FIG. 23), whereby the electric charges held in the analog memories 322-1 to 322-4 of the taps 303-1 to 303-4 of four stages are selectively read. Then, (pixel signals corresponding to) the electric charges selectively read from the analog memories 322-1 to 322-4 are added together (analog addition) at a pixel addition point 304 as necessary, and output to a vertical signal line 331.

Note that, in the pixel 300A, the drive signals RST-P, TRG-M, and RST-M applied to the gates of the reset transistor 312, the transfer transistors 321-1 to 321-4, and the reset transistors 323-1 to 323-4 are controlled commonly in the sensor (on a sensor basis), whereas the drive signal SEL-M applied to the gates of the selection transistors 325-1 to 325-4 is controlled on a line basis (on a row basis). Furthermore, the reset transistor 323 of the analog memory unit 302A may be shared for each any plurality of pixels 300.

Furthermore, in the pixel 300A, a configuration has been described of the analog memory unit 302A including the taps 303-1 to 303-4 of four stages, but the number of stages of the tap 303 is arbitrary, and the pixel 300A may include the tap 303 of, for example, six stages, eight stages, or the like. That is, the number of analog memories 322 and each capacity (amount of electric charge stored) in the pixel 300A are arbitrary. For example, in the pixel 300A, all the analog memories 322 may have the same capacity, or the capacities may be different for each analog memory 322.

Moreover, similarly to the solid-state imaging device 10, the solid-state imaging device 30 may adopt either of a configuration in which the photodiode unit 301A and the analog memory unit 302A of the pixel 300A are arranged in a pixel array unit 31 (11), or a configuration in which a photodiode array unit 31A (11A) and an analog memory array unit 31B (11B) are separately arranged. That is, in the case of the former configuration, a solid-state imaging device 30A has the configuration illustrated in FIG. 1, and transfer and reading are performed in accordance with the data flow illustrated in FIG. 3. Furthermore, in the case of the latter configuration, a solid-state imaging device 30B has the configuration illustrated in FIG. 4, and transfer and reading are performed in accordance with the data flow illustrated in FIG. 5.

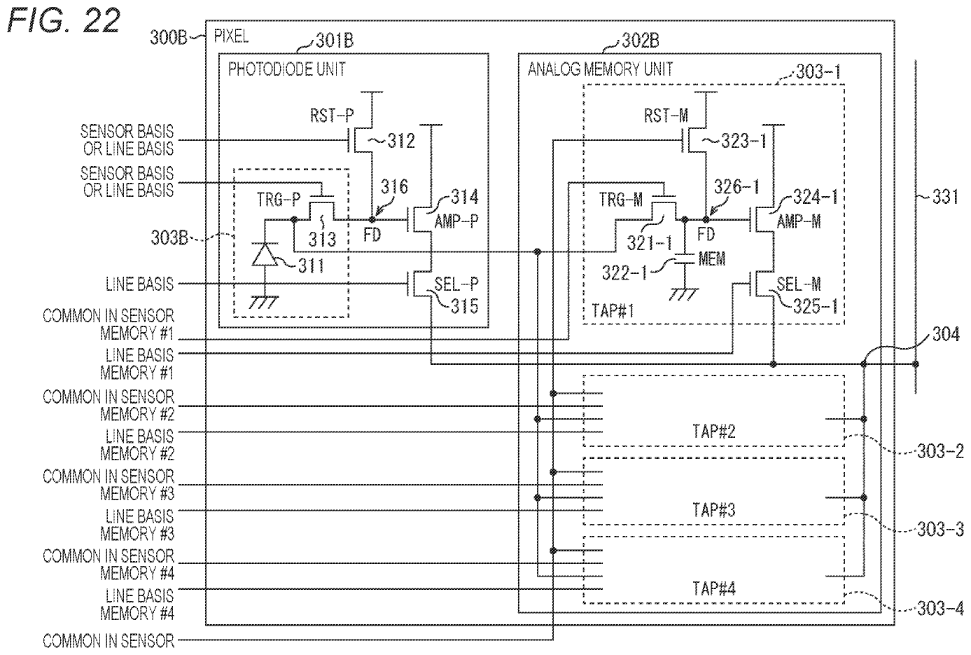

FIG. 22 illustrates a second example of the configuration of the pixel 300 of the third embodiment.

In FIG. 22, a pixel 300B includes a photodiode unit 301B and an analog memory unit 302B.

The photodiode unit 301B includes the photodiode 311, the reset transistor 312, a transfer transistor 313, an amplification transistor 314, and a selection transistor 315. That is, the photodiode unit 301B is configured similarly to the photodiode unit 201 in FIG. 11, and the electric charge stored in the photodiode 311 is not only transferred from the photodiode unit 301B side to the analog memory unit 302B side, but also can be output directly to the vertical signal line 331 from the photodiode unit 301B side.

The analog memory unit 302B includes the taps 303-1 to 303-4, similarly to the analog memory unit 302A in FIG. 21. That is, in the analog memory unit 302B, the tap 303-1 is configured similarly to the analog memory unit 202 of FIG. 11, and includes the transfer transistor 321-1, the analog memory 322-1, the reset transistor 323-1, the amplification transistor 324-1, and the selection transistor 325-1. Furthermore, although not illustrated, the taps 303-2 to 303-4 are configured similarly to the tap 303-1.

In the analog memory unit 302B, the pixel transistors provided in each of the taps 303-1 to 303-4 are driven in accordance with drive signals from the drive unit 32 (FIG. 23), and the electric charge obtained by dividing one exposure by an arbitrary number (maximum four divisions) is transferred to and held in the analog memory 322 of any tap 303. Then, in the analog memory unit 302B, the electric charges held in the analog memories 322-1 to 322-4 are selectively read in accordance with drive signals from the drive unit 32 (FIG. 23), and added together (analog addition) at the pixel addition point 304 and output as necessary.

Note that, in the pixel 300B, on the photodiode unit 301B side, the drive signal SEL-P applied to the gate of the selection transistor 315 is controlled on a line basis (on a row basis), but for the reset transistor 312 and the transfer transistor 313, the drive signals RST-P and TRG-P applied to the gates are controlled depending on the shutter method, whereby (the pixel signal corresponding to) the electric charge stored in the photodiode 211 is read. That is, the reset transistor 312 and the transfer transistor 313 are driven on a sensor basis in the case of the global shutter method, and are driven on a line basis in the case of the rolling shutter method. Furthermore, on the photodiode unit 301B side, the reset transistor 312, the transfer transistor 313, and the selection transistor 315 may be shared for each any plurality of pixels 300 (area 303B).

Furthermore, in the analog memory unit 302B of the pixel 300B, the tap 303 of an arbitrary number of stages can be provided similarly to the analog memory unit 302A of the pixel 300A. That is, the number of analog memories 322 and each capacity (amount of electric charge stored) in the pixel 300B are arbitrary.

Moreover, similarly to the solid-state imaging device 20, the solid-state imaging device 30 may adopt either of a configuration in which the photodiode unit 301B and the analog memory unit 302B of the pixel 300B are arranged in the pixel array unit 31 (21), or a configuration in which the photodiode array unit 31A (21A) and the analog memory array unit 31B (21B) are separately arranged. That is, in the case of the former configuration, the solid-state imaging device 30A has the configuration illustrated in FIG. 12, and transfer and reading are performed in accordance with the data flow illustrated in FIG. 13. Furthermore, in the case of the latter configuration, the solid-state imaging device 30B has the configuration illustrated in FIG. 14, and transfer and reading are performed in accordance with the data flow illustrated in FIG. 15.

(Example of Configuration of Solid-State Imaging Device)

FIG. 23 is a diagram illustrating an example of the solid-state imaging device to which the technology according to the present disclosure is applied.

In FIG. 23, the solid-state imaging device 30A includes the pixel array unit 31, the drive unit 32, a column ADC unit 33, a FIFO 34, a digital processing unit 35, and a register 36. A plurality of the pixels 300 (the pixel 300A in FIG. 21 or the pixel 300B in FIG. 22) is arranged two-dimensionally in the pixel array unit 31.

Here, in a pixel 300(i, j), by dividing one exposure by an arbitrary number, the electric charge stored in the photodiode 311 can be transferred to the analog memory 322 (at least one or more analog memories 322) of any tap 303 among the taps 303-1 to 303-4 of four stages in the analog memory unit 302. Here, the maximum number of divisions is set to four divisions, and a divided exposure time (for example, in steps of 1 H) and information for identifying a transfer destination analog memory 322 (for example, tap number) are set.

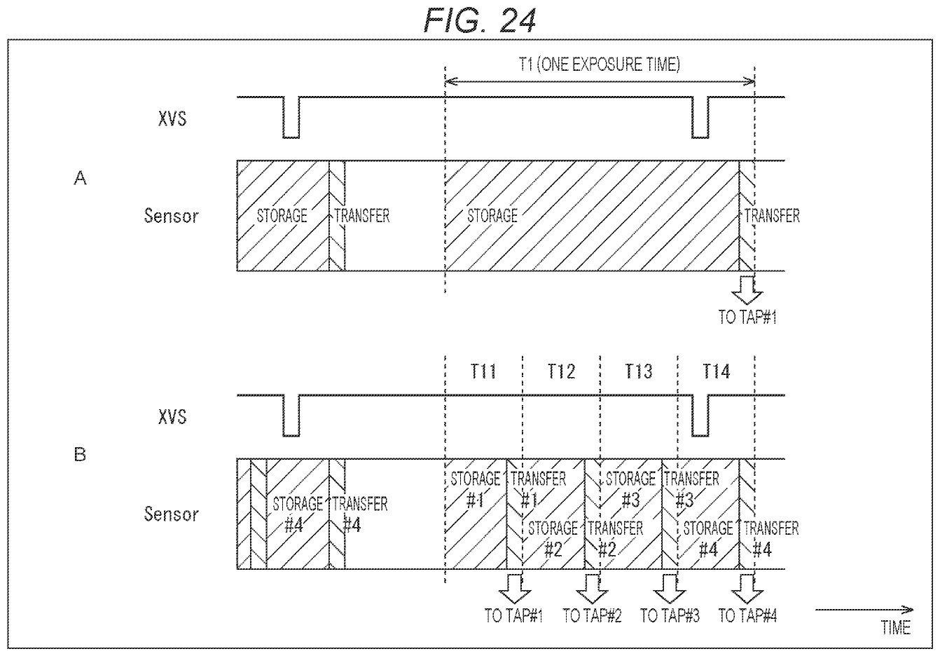

For example, in a case where one exposure is divided into one (in a case where the exposure is not divided), one exposure time T1 is set as the exposure time, and the analog memory 322-1 (TAP #1) of the tap 303-1 is set as the transfer destination of the electric charge by the exposure. By making such a setting, the electric charge stored in the photodiode 311 by one exposure can be transferred to the analog memory 322-1 (TAP #1) in the exposure time T1 (A of FIG. 24).

Furthermore, for example, in a case where one exposure is divided into four, each divided exposure period (T11, T12, T13, T14) is set, and the analog memories 322-1 to 322-4 (TAP #1, TAP #2, TAP #3, TAP #4) of the taps 303-1 to 303-4 are set as transfer destinations for those exposures. By making such a setting, one exposure is divided into four, and the electric charge stored in the photodiode 311 in the exposure time T11 can be transferred to the analog memory 322-1 (TAP #1) (“storage #1” and “transfer #1” in B of FIG. 24).

Similarly, in the exposure time T12, the electric charge stored in the photodiode 311 is transferred to the analog memory 322-2 (TAP #2) (“storage #2” and “transfer #2” in B of FIG. 24), in the exposure time T13, the electric charge stored in the photodiode 311 is transferred to the analog memory 322-3 (TAP #3) (“storage #3” and “transfer #3” in B of FIG. 24), and in the exposure time T14, the electric charge stored in the photodiode 311 is transferred to the analog memory 322-4 (TAP #4) (“storage #4” and “transfer #4” in B of FIG. 24).

As described above, in the solid-state imaging device 30A, the electric charge stored in the photodiode 311 can be sequentially transferred to the analog memory 322 of any tap 303 by time-division exposure in which one exposure is subjected to time-division. Then, the electric charges held in the analog memory 322 of any tap 303 are selectively read (non-destructively read) and added together as necessary.

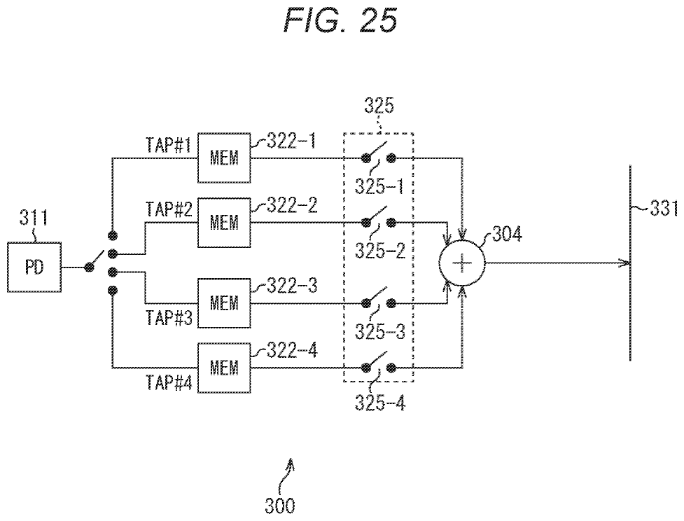

For example, as illustrated in FIG. 25, in a case where one exposure is divided into four, the electric charges transferred from the photodiode 311 are held in the analog memories 322-1 to 322-4 of the tap 303 of four stages, respectively. At this time, during reading of the electric charges held in the analog memories 322-1 to 322-4, any analog memory 322 can be selected. Furthermore, in a case where a plurality of the analog memories 322 is selected, the electric charges selectively read from the plurality of analog memories 322 can be subjected to analog-addition (pixel addition).

Furthermore, here, setting is performed of the number of times of reading the electric charge held in the analog memory 322 and performing AD conversion (for example, maximum four times), the number of analog memories 322 read simultaneously (for example, the number of memories that is four), and information for identifying the analog memories 322 read simultaneously (for example, tap numbers). Note that, in a case where a number greater than or equal to two is set as the number of memories to be read simultaneously, the read electric charges are subjected to analog-addition (pixel addition). Furthermore, in the case of this example, since the tap 303 of four stages is provided, the maximum number of memories that can be read simultaneously is three. Furthermore, these pieces of setting information are set by the amount for the number of times.

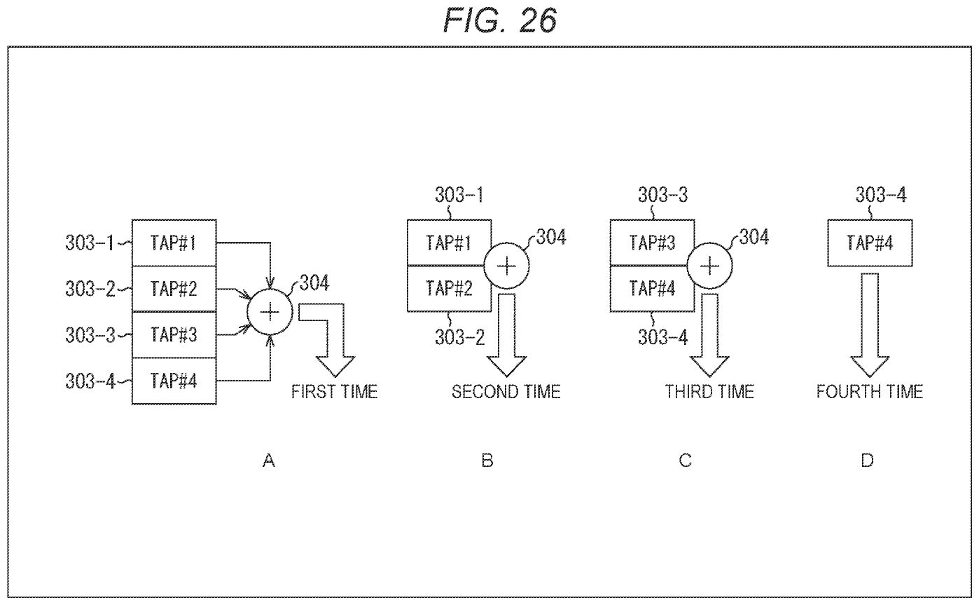

More specifically, as illustrated in FIG. 26, the number of times of reading is set to four, and in a case where the number of memories to be read simultaneously at the first reading is four, and TAP #1, TAP #2, TAP #3, and TAP #4 are set as the memories to be read simultaneously, the electric charges are read from the analog memories 322-1 to 322-4 of the taps 303-1 to 303-4, respectively, and subjected to analog addition (A of FIG. 26).

Furthermore, in the second reading, in a case where the number of memories to be read simultaneously is two, and TAP #1 and TAP #2 are set as the memories to be read simultaneously, the electric charges are read from the analog memories 322-1 and 322-2, respectively, and subjected to analog addition (B of FIG. 26). Moreover, in the third reading, in a case where the number of memories to be read simultaneously is two, and TAP #3 and TAP #4 are set as the memories to be read simultaneously, the electric charges are read from the analog memories 322-3 and 322-4, respectively, and subjected to analog addition (C of FIG. 26). Furthermore, in the fourth reading, in a case where the number of memories to be read simultaneously is set to one (TAP #4), the electric charge is read from the analog memory 322-4 (D of FIG. 26).

Furthermore, in the solid-state imaging device 30A, when the digital signal after AD conversion by the column ADC unit 33 is processed by the digital processing unit 35, digital signals after the AD conversion of the electric charge non-destructively read at different timings from the same pixel 300 can be subjected to digital addition.

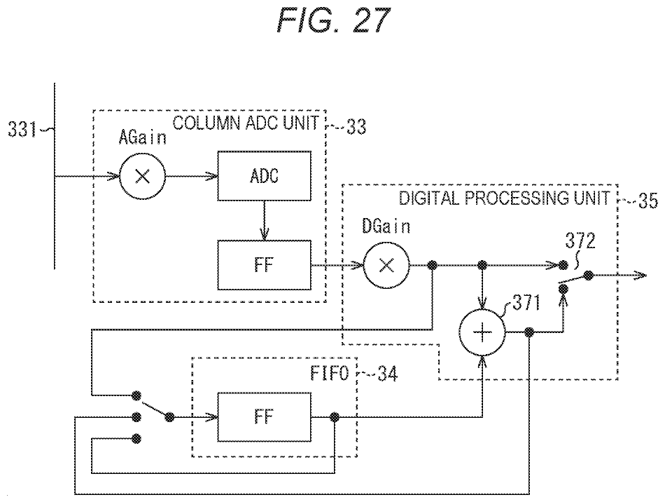

In the digital processing unit 35, a digital signal (current digital signal of pixel 300) input from the column ADC unit 33 and a digital signal (past digital signal of the same pixel 300) input from the FIFO 34 are subjected to digital addition by an addition unit 371 (FIG. 27). However, in the digital processing unit 35, by switching by a switch 372, it is possible to select whether to output the digital signal from the column ADC unit 33 by adding to the digital signal from the FIFO 34, or to output the digital signal from the column ADC unit 33 as it is without performing the addition (FIG. 27).

Furthermore, here, in addition to the number of times of performing digital addition of the digital signals after the AD conversion, various addition conditions can be set. Note that, in a case where the number of times of digital addition is set to zero, the digital addition is not performed.

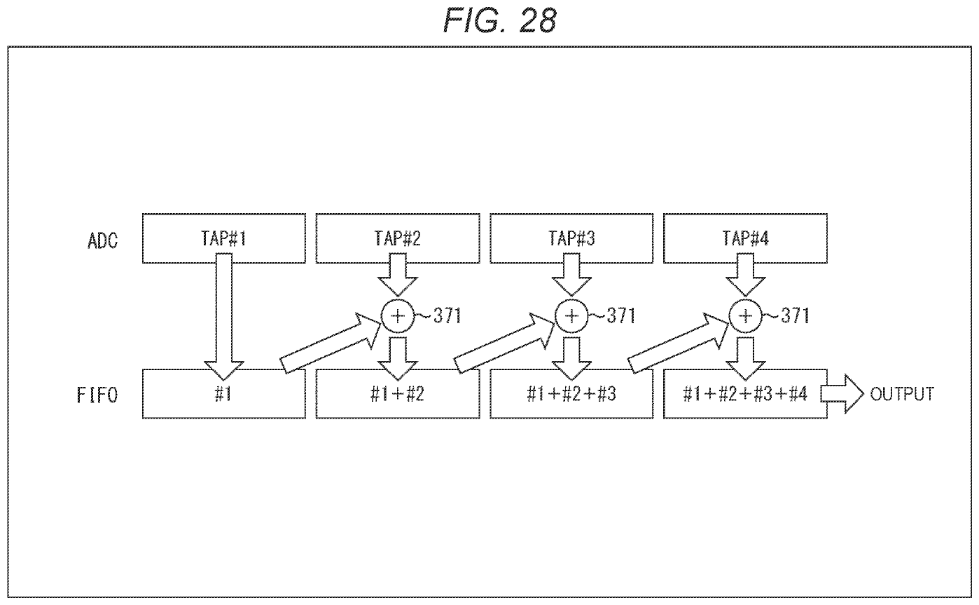

More specifically, for example, in a case where one exposure is divided into four, a case is assumed where the number of times of digital addition is set to three in a case where the electric charges transferred from the photodiode 311 are held in the analog memories 322-1 to 322-4 of the taps 303-1 to 303-4 (TAP #1, TAP #2, TAP #3, TAP #4), respectively. In this case, as illustrated in FIG. 28, the electric charge non-destructively read from the analog memory 322-1 (TAP #1) is subjected to AD conversion by the column ADC unit 33, output to the digital processing unit 35, and held in the FIFO 34.

Subsequently, the electric charge non-destructively read from the analog memory 322-2 (TAP #2) is subjected to AD conversion, and output to the digital processing unit 35. At this time, in the digital processing unit 35, a digital signal (TAP #2) after the AD conversion and a digital signal (TAP #1) held in the FIFO 34 are subjected to digital addition by the addition unit 371. A digital addition signal (#1+#2) obtained here is held in the FIFO 34.

Next, the electric charge non-destructively read from the analog memory 322-3 (TAP #3) is subjected to AD conversion, and output to the digital processing unit 35. At this time, in the digital processing unit 35, a digital signal (TAP #3) after the AD conversion and the digital addition signal (#1+#2) held in the FIFO 34 are subjected to digital addition by the addition unit 371. A digital addition signal (#1+#2+#3) obtained here is held in the FIFO 34.

Next, the electric charge non-destructively read from the analog memory 322-4 (TAP #4) is subjected to AD conversion, and output to the digital processing unit 35. At this time, in the digital processing unit 35, a digital signal (TAP #4) after the AD conversion and the digital addition signal (#1+#2+#3) held in the FIFO 34 are subjected to digital addition by the digital addition unit 371. A digital addition signal (#1+#2+#3+#4) obtained here is held in the FIFO 34, and output as imaging data to the subsequent stage.

The solid-state imaging device 30A is configured as described above. Note that, in the solid-state imaging device 30A, various data (for example, setting information or the like) can be stored in the register 36 by serial communication with an external control unit (a CPU 1001 in FIG. 37 described later). The drive unit 32 and the digital processing unit 35 can appropriately read the various data stored in the register 36 and perform processing.

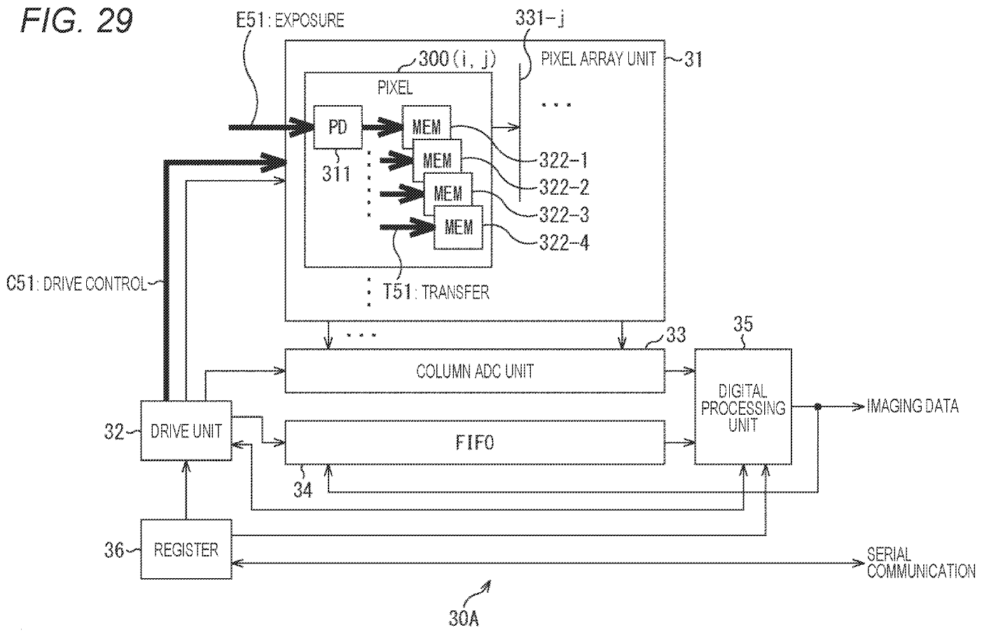

Next, a data flow of the solid-state imaging device 30A of FIG. 23 will be described with reference to FIGS. 29 to 31.

In the solid-state imaging device 30A (FIG. 29), in the pixel 300(i, j) arranged in the pixel array unit 31, the electric charge stored in the photodiode 311 by exposure (E51) with the global shutter method is transferred (T51) from the photodiode unit 301A to the analog memory unit 302A, and held in each of the analog memories 322-1 to 322-4.

Here, during the exposure, a transfer circuit (including the pixel transistors such as the transfer transistor 321) in each pixel 300 is controlled (C51) by the drive unit 32.

For example, in a frame rate mode, the exposure (E51) is started before a preset time for the fall of an XVS signal, and after a preset time period has elapsed from the start of the exposure, the electric charge obtained by the exposure is transferred (T51) to the preset analog memory 322.

Note that, in a case where time-division exposure is performed, this processing is repeated for a preset number of divisions (for example, 4 divisions). Furthermore, for example, in the case of a trigger mode, the exposure (E51) is started by the fall of an XTRG signal, and the electric charge obtained by the exposure is transferred (T51) to the preset analog memory 322 by the rise of the XTRG signal.

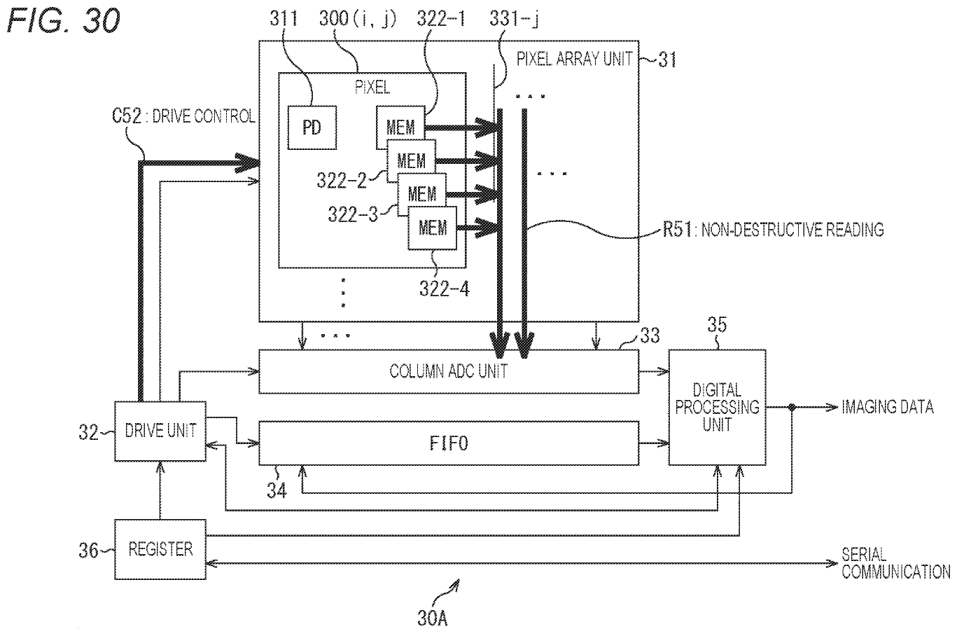

Next, in the solid-state imaging device 30A (FIG. 30), the electric charges held in the analog memories 322-1 to 322-4 of the pixel 300(i, j) are non-destructively read (R51), and input to the column ADC unit 33 via the vertical signal line 331-j.

Here, during the non-destructive reading, each row of the pixels 300 arranged in the pixel array unit 31 and a reading circuit (including the pixel transistors such as the selection transistor 325) in each pixel 300 are controlled (C52) by the drive unit 32.

For example, each row of the pixels 300 is selected to perform raster scan on the pixel array unit 31 in accordance with a preset pixel reading mode, and the analog memory 322 of any preset tap 303 in each pixel 300 is selected, and the electric charge held in the target analog memory 322 is non-destructively read (R51).

Note that, in a case where a plurality of memories is set to be read simultaneously, the electric charges read from the plurality of analog memories 322 are subjected to analog addition. Furthermore, in a case where a plurality of times is set as the number of times to read, this processing is repeated as many times as the set number of times, and the control target is shifted to the next line.

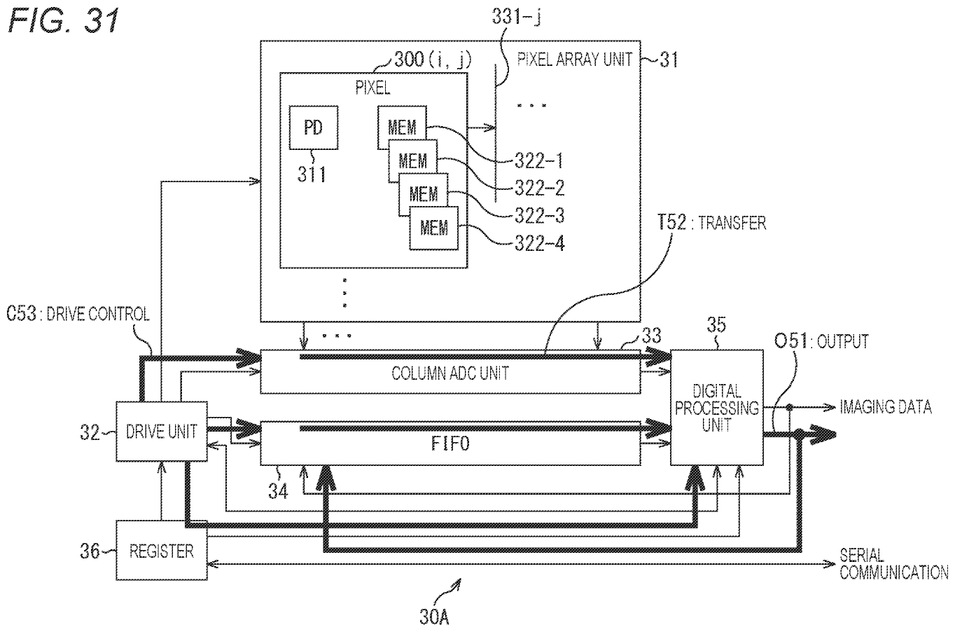

Next, in the solid-state imaging device 30A (FIG. 31), the digital signal subjected to the AD conversion by the column ADC unit 33 is input to the digital processing unit 35, and digital signal processing is performed. Here, during the AD conversion and the digital signal processing, the column ADC unit 33, the FIFO 34, and the digital processing unit 35 are controlled (C53) by the drive unit 32.

For example, in the column ADC unit 33, the analog signal transferred for each row via the vertical signal line 331-j from the pixel array unit 31 is converted into a digital signal including an analog gain in accordance with a preset set value, and the digital signal is horizontally transferred (T52) to the digital processing unit 35, sequentially. Then, in the digital processing unit 35, for the horizontally transferred digital signal, processing is sequentially performed, for example, multiplication of a digital gain, input selection and transfer to the FIFO 34, output selection, and the like, in accordance with a preset set value and a digital addition mode, and the processed signal is output (O51) to the subsequent stage.

(Specific Operation)

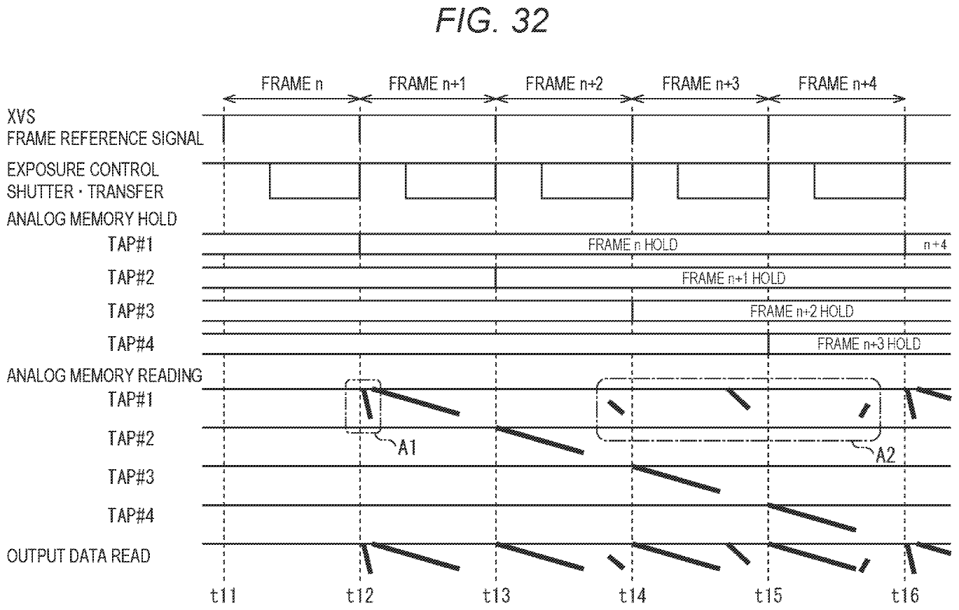

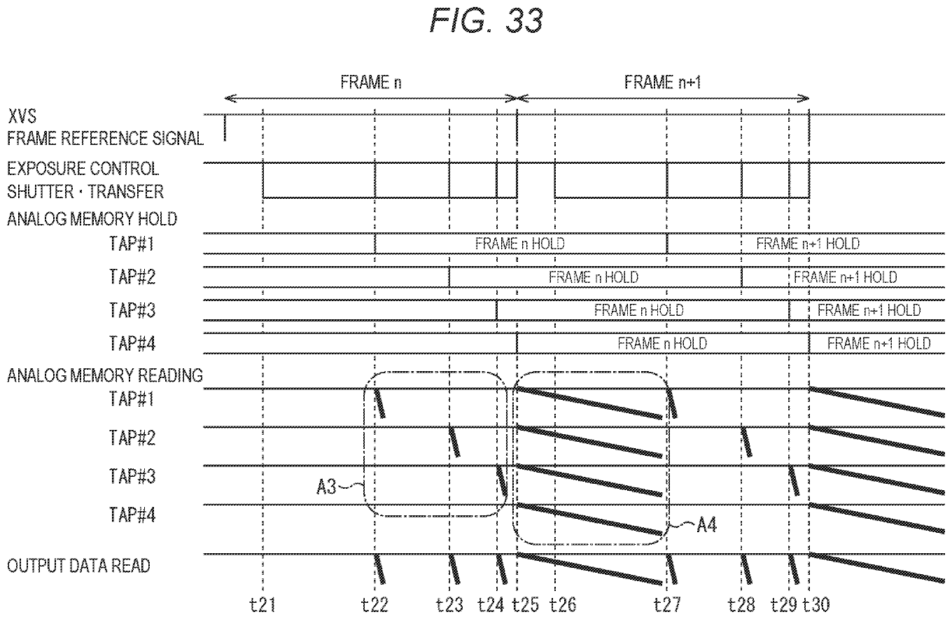

Next, a more specific operation of the solid-state imaging device 30A will be described with reference to timing charts of FIGS. 32 and 33.

In FIG. 32, the solid-state imaging device 30A operates in the frame rate mode, and exposure is performed on a frame rate basis. That is, the exposure is started from a predetermined time depending on a frame reference signal (XVS), and after a predetermined time period has elapsed from the start of the exposure, the electric charge obtained by the exposure is transferred to the preset analog memory 322.

In the example of FIG. 32, the analog memories 322-1 to 322-4 (TAP #1, TAP #2, TAP #3, TAP #4) are set as transfer destinations for the exposure. Here, when a frame n is exposed in a period from time t11 to t12, (the electric charge of) the frame n is held in the analog memory 322-1 (TAP #1) in a period from time t12 to time t16.

Similarly, when a frame n+1 is exposed in a period from the time t12 to t13, from the time t13 immediately after that, the analog memory 322-2 (TAP #2) starts to hold (the electric charge of) the frame n+1. Subsequently, when a frame n+2 is exposed in a period from the time t13 to t14, from the time t14 immediately after that, the analog memory 322-3 (TAP #3) starts to hold (the electric charge of) the frame n+2. Subsequently, when a frame n+3 is exposed in a period from the time t14 to t15, from the time t15 immediately after that, the analog memory 322-4 (TAP #4) starts to hold (the electric charge of) the frame n+3.

In this way, in the analog memories 322-1 to 322-4, the electric charges sequentially transferred from the photodiode 311 on a frame basis are held for each frame. Then, the electric charges respectively held in the analog memories 322-1 to 322-4 are selectively and non-destructively read.

In the example of FIG. 32, a thick line marked in a reading area of the analog memory 322 represents reading of the electric charge, and in the analog memories 322-1 to 322-4 (TAP #1, TAP #2, TAP #3, TAP #4), the electric charge is read at the timing when (the electric charge of) the frame is held. On the other hand, in the analog memory 322-1 (TAP #1), in addition to normal reading, thinning out reading (thick line in area A1) and late reading of an arbitrary area (thick line in area A2) for (the electric charge of) the held frame n are performed.

On the other hand, in FIG. 33, the solid-state imaging device 30A operates in the frame rate mode, but time-division exposure is performed and one exposure is divided into four. That is, the exposure is started from a predetermined time depending on the frame reference signal (XVS), and the electric charge obtained by the exposure is transferred to the preset analog memory 322 for each exposure time divided into four.

Also in the example of FIG. 33, the analog memories 322-1 to 322-4 (TAP #1, TAP #2, TAP #3, TAP #4) are set as transfer destinations for the exposure. Here, when time-division exposure of the frame n is performed in a period from time t21 to t22, from the time t22 immediately after that, the analog memory 322-1 (TAP #1) holds (the electric charge of) the frame n.

Similarly, when time-division exposure of the frame n is performed in a period from the time t22 to t23, from the time t23 immediately after that, the analog memory 322-2 (TAP #2) starts to hold (the electric charge of) the frame n. Subsequently, when time-division exposure of the frame n is performed in a period from the time t23 to t24, from the time t24 immediately after that, the analog memory 322-3 (TAP #3) starts to hold (the electric charge of) the frame n. Subsequently, when time-division exposure of the frame n is performed in a period from the time t24 to t25, from the time t25 immediately after that, the analog memory 322-4 (TAP #4) starts to hold (the electric charge of) the frame n.

In this way, in the analog memories 322-1 to 322-4, the electric charges sequentially transferred from the photodiode 311 by the time-division exposure are held for each frame. Then, the electric charges respectively held in the analog memories 322-1 to 322-1 are selectively and non-destructively read.

In the example of FIG. 33, the thinning out reading (thick line in area A3) and the pixel addition reading (thick line in area A4) are performed for (the electric charges of) the frame n held in the analog memories 322-1 to 322-4 by the time-division exposure.

### Application Example

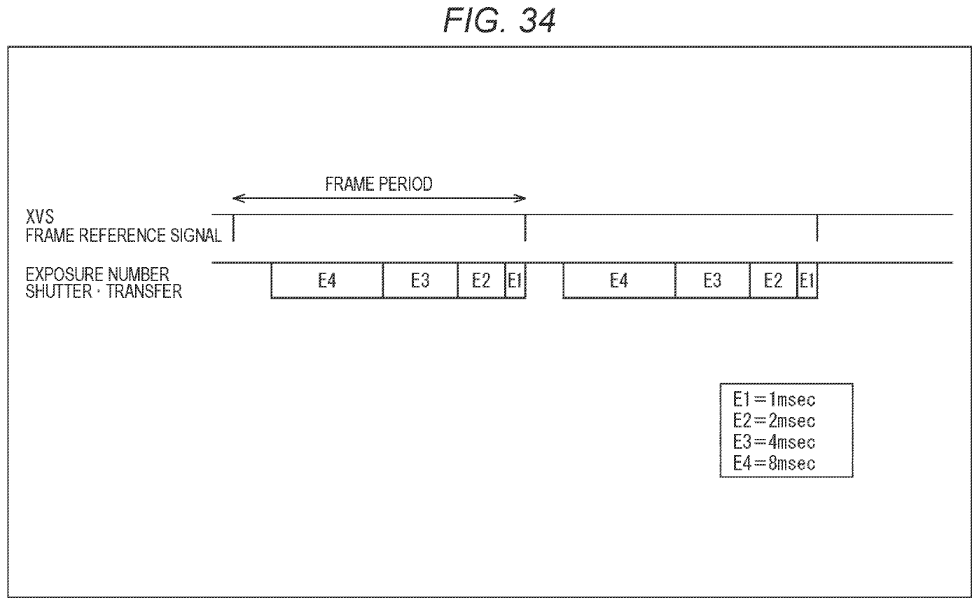

Here, in the solid-state imaging device 30A, in a case where one exposure is divided into four by time-division exposure, it is possible to perform control of making a combination to obtain a desired exposure time by combining the four-divided exposures. For example, as illustrated in FIG. 34, in a case where each exposure obtained by dividing one exposure into four is defined as exposure E1, exposure E2, exposure E3, and exposure E4, a case is assumed where each exposure time is set to the exposure E1=1 msec, the exposure E2=2 msec, the exposure E3=4 msec, and the exposure E4=8 msec.

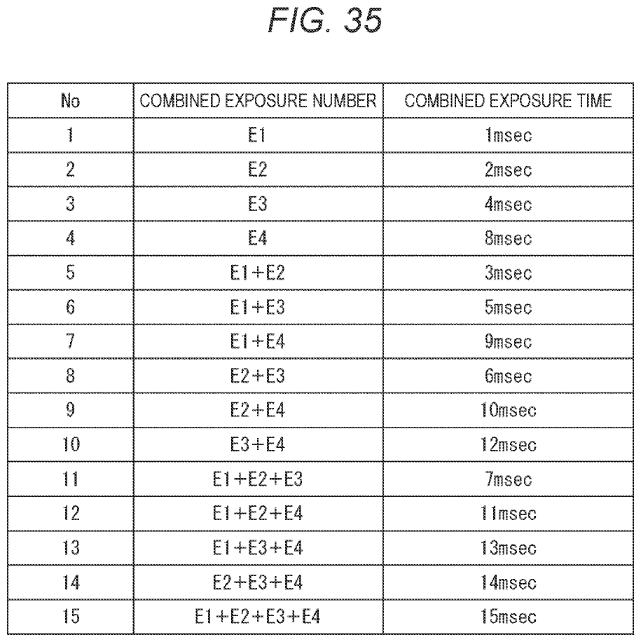

In this case, if a combination is made to obtain a desired exposure time by combining the exposures (E1, E2, E3, E4), it will be as illustrated in FIG. 35, for example. That is, in FIG. 35, in a case where a target to be combined is only the exposure E1, the combined exposure time is E1=1 msec. Furthermore, similarly, in a case where the target to be combined is only the exposure E2, the exposure E3, or the exposure E4, the combined exposure time is E2=2 msec, E3=4 msec, or E4=8 msec, respectively.

Furthermore, in FIG. 35, in a case where targets to be combined are the exposure E1 and the exposure E2, the combined exposure time is E1+E2=3 msec. Moreover, in a case where the targets to be combined are the exposure E1 and the exposure E3, the combined exposure time is E1+E3=5 msec. Furthermore, in a case where the targets to be combined are the exposure E1 and the exposure E4, the combined exposure time is E1+E4=9 msec. Similarly, in a case where the targets to be combined are the exposure E2 and exposure E3, the exposure E2 and exposure E4, and the exposure E3 and exposure E4, the combined exposure times are E2+E3=6 msec, E2+E4=10 msec, and E3+E4=12 msec, respectively.

Moreover, in FIG. 35, in a case where the targets to be combined are the exposure E1, the exposure E², and the exposure E3, the combined exposure time is E1+E2+E3=7 msec. Similarly, in a case where the targets to be combined are the exposure E1, exposure E2, and exposure E4, the exposure E1, exposure E3, and exposure E4, and the exposure E2, exposure E3, and exposure E4, the combined exposure times are E1+E2+E4=11 msec, E1+E3+E4=13 msec, and E2+E3+E4=14 msec. Moreover, in FIG. 34, in a case where the targets to be combined are the exposure E1, the exposure E2, the exposure E3, and the exposure E4, the combined exposure time is E1+E2+E3+E4=15 msec.

As described above, in FIG. 35, depending on the combination of the exposures (E1, E2, E3, E4), it is possible to make 15 steps of combined exposure time in steps of 1 msec in a range of from 1 to 15 msec. As a result, in the solid-state imaging device 30A, it is possible to perform re-exposure control depending on an appropriate exposure time by time-division exposure (for example, four-division exposure) and pixel addition (analog addition).

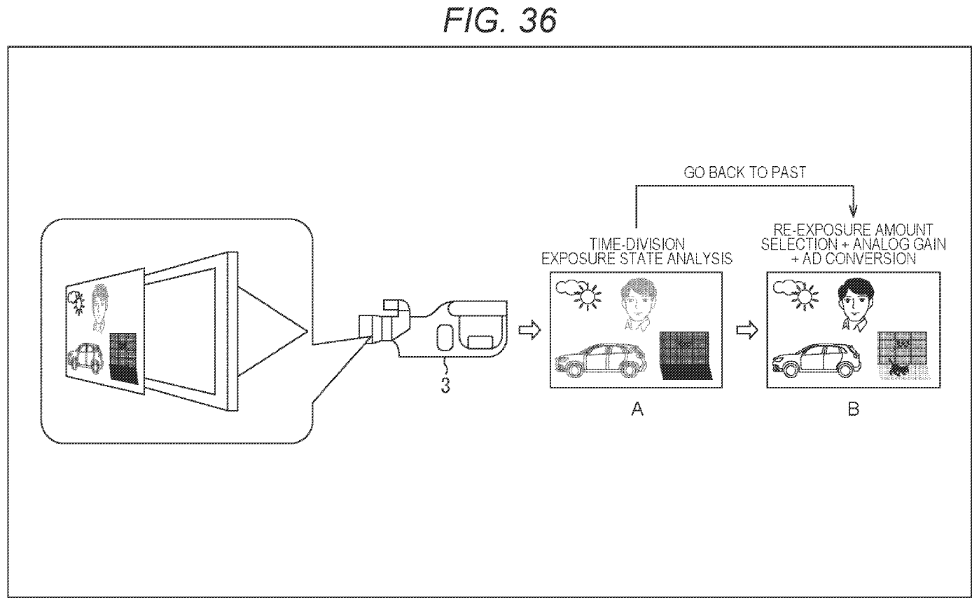

FIG. 36 illustrates an example of processing of a camera device equipped with the solid-state imaging device to which the technology according to the present disclosure is applied.

In FIG. 36, a camera device 3 equipped with the solid-state imaging device 30 (30A, 30B) can perform re-exposure control depending on the exposure time illustrated in FIGS. 34 and 35 by time-division exposure and pixel addition.

For example, in this re-exposure control, the electric charge obtained by time-division of one exposure (four divisions of exposures E1, E2, E3, and E4 in FIG. 34) is transferred to and held in the analog memories 322-1 to 322-4, so that by appropriately reading the electric charge from the memories, a change in the amount of electric charge, a timing of saturation, or the like in one exposure is detected, for example, and analysis of a time-division exposure state is performed (A of FIG. 36).

Then, in this re-exposure control, on the basis of an analysis result of the time-division exposure state, the most appropriate exposure time is selected (re-exposure amount selection) from, for example, the combined exposure time illustrated in FIG. 35, and electric charges corresponding to the appropriate exposure time is selectively (adaptively) read from the electric charges held in the analog memories 322-1 to 322-4 and added together appropriately, and then signal processing (for example, applying an analog gain, or the like) before and after the AD conversion can be performed (B of FIG. 36). As a result, so to speak, it is possible to go back to the past, and a processing unit in the subsequent stage can generate a captured image in which, for example, overexposure, motion blur, underexposure, and the like are excluded (A, B of FIG. 36).

Note that, in the description of FIGS. 23 to 36, for convenience of explanation, as the solid-state imaging device 30A (FIG. 23), a case has been mainly described where the pixel array unit 31 is provided, but the same applies to the solid-state imaging device 30B provided with the photodiode array unit 31A and the analog memory array unit 31B instead of the pixel array unit 31.

However, although the configuration of the solid-state imaging device 30B is not particularly illustrated, in a case where the pixels 300A (FIG. 21) are arranged in the photodiode array unit 31A and the analog memory array unit 31B that are laminated, the configuration corresponds to the solid-state imaging device 10B of FIG. 4, and in a case where the pixels 300B (FIG. 22) are arranged, the configuration corresponds to the solid-state imaging device 20B of FIG. 14.

In the above, the third embodiment has been described. In the solid-state imaging device 30 (30A, 30B) of the third embodiment, the pixel 300 is provided including the photodiode 311 and the plurality of analog memories 322, and the electric charge stored in the photodiode 311 is transferred and held in any of the plurality of analog memories 322, and in a case where the electric charge is read from the analog memories 322, one or a plurality of the analog memories 322 is selected, and added together as necessary and read. As a result, processing such as the above-described re-exposure control becomes possible, and phenomena is suppressed, for example, false color, motion blur, and the like that occur on the captured image, and visibility can be improved.

Furthermore, in the solid-state imaging device 30 (30A, 30B), time-division of one exposure is performed, and the electric charge from the photodiode 311 can be sequentially transferred to each analog memory 322 in the pixel 300. At this time, the number of time divisions in one exposure and the time intervals of them are arbitrary. For example, the time-division time intervals may be all the same time, or the times may be individually different.

Moreover, in the solid-state imaging device 30 (30A, 30B), during non-destructive reading of the electric charge held in one or the plurality of analog memories 222 for each of the plurality of pixels 300 arranged two-dimensionally, the electric charge can be adaptively read. For example, the electric charge held in one or the plurality of analog memories 222 for each of the plurality of pixels 300 can be read depending on an arbitrary area (for example, entire area or ROI area) in the image frame, or a drive mode (for example, all-pixel drive, thinning out drive, pixel addition reading drive, or the like).

Furthermore, for example, the exposure timing can be a predetermined timing such as a constant period depending on a frame rate, or notification of a trigger signal, and the electric charge held in one or the plurality of analog memories 122 for each pixel 300 may be non-destructively read depending on the predetermined timing. Furthermore, for example, the electric charge held in one or the plurality of analog memories 322 for each pixel 300 may be non-destructively read depending on the signal processing (for example, gain, clamp, or the like) before and after the AD conversion by the column ADC unit 33.

### 4. Fourth Embodiment

(Configuration of Electronic Device)

FIG. 37 is a diagram illustrating an example of a configuration of an electronic device equipped with the solid-state imaging device to which the technology according to the present disclosure is applied.

An electronic device 1000 of FIG. 37 is, for example, an imaging device such as a digital still camera or a video camera, or a device having an imaging function, such as a mobile terminal device such as a smartphone or a tablet terminal. Note that, it can also be said that the electronic device 1000 corresponds to the camera device 1 (FIG. 7), the camera device 2 (FIG. 17), and the camera device 3 (FIG. 36) described above.

In FIG. 37, the electronic device 1000 includes a Central Processing Unit (CPU) 1001, a lens drive unit 1002, a lens 1003, a solid-state imaging device 1004, a bus 1005, a non-volatile memory 1006, a built-in memory 1007, a detachable memory 1008, an object detection unit 1009, an object recognition unit 1010, an image processing unit 1011, a display drive control unit 1012, and a display unit 1013.

Furthermore, in the electronic device 1000, the CPU 1001, and components from the non-volatile memory 1006 to the display drive control unit 1012 are connected to each other via the bus 1005. Note that, the CPU 1001 performs serial communication with the solid-state imaging device 1004.

The CPU 1001 operates as a central processing device in the electronic device 1000, for various types of arithmetic processing, operation control of each part, and the like.

The lens drive unit 1002 includes, for example, a motor, an actuator, and the like, and drives the lens 1003 in accordance with the control from the CPU 1001. The lens 1003 includes, for example, a zoom lens, a focus lens, and the like, and focuses light from a subject. The light (image light) focused by the lens 1003 is incident on the solid-state imaging device 1004.

The solid-state imaging device 1004 is a solid-state imaging device (solid-state imaging element) to which the technology according to the present disclosure is applied, for example, the above-described solid-state imaging devices 10, 20, and 30, or the like. The solid-state imaging device 1004 performs processing such as AD conversion by photoelectrically converting the light (subject light) received through the lens 1003 into an electric signal in accordance with the control from the CPU 1001, and supplies imaging data obtained as a result of the processing to the CPU 1001.

The CPU 1001 controls the lens drive unit 1002 on the basis of the imaging data from the solid-state imaging device 1004. Furthermore, the CPU 1001 supplies the imaging data from the solid-state imaging device 1004 to each part connected to the bus 1005.

The non-volatile memory 1006 includes, for example, a Read Only Memory (ROM), a flash memory, or the like, and stores data from the CPU 1001 or the like. The built-in memory 1007 is a storage device mounted on a device such as a Random Access Memory (RAM), or a ROM, for example. The detachable memory 1008 is a storage device of a type that is inserted or connected to a device, such as a memory card, for example. The built-in memory 1007 and the detachable memory 1008 store data such as image data from the image processing unit 1011 in accordance with the control of the CPU 1001.

The object detection unit 1009 includes a signal processing circuit such as an image processing Large Scale Integration (LSI), for example. The object detection unit 1009 performs object detection processing (for example, detection of a person, face, car, or the like) on the basis of a result of image processing from the image processing unit 1011, and supplies a result of the object detection processing to the object recognition unit 1010.

The object recognition unit 1010 includes a signal processing circuit such as an image processing LSI, for example. Note that, the object recognition unit 1010 may include the same signal processing circuit as that of the object detection unit 1009. The object recognition unit 1010 performs object recognition processing (for example, individual identification of a person's face (individual), vehicle type, or the like) on the basis of the result of the object detection processing from the object detection unit 1009, and supplies a result of the object recognition processing to the CPU 1001 and the like.

The image processing unit 1011 includes a signal processing circuit such as a digital signal processor (DSP), for example. The image processing unit 1011 performs image processing such as camera signal processing and preprocessing on the imaging data from the solid-state imaging device 1004.

Here, the camera signal processing includes, for example, processing such as white balance processing, interpolation processing, and noise removal processing. Furthermore, the preprocessing includes, for example, processing such as image reduction and cutout. Note that, the image processing unit 1011 may include the same signal processing circuit as that of the object detection unit 1009 and the object recognition unit 1010.

The image processing unit 1011 supplies the result of the image processing to the object detection unit 1009. Furthermore, the image processing unit 1011 supplies image data of a still image or a moving image obtained as a result of the image processing to the built-in memory 1007, the detachable memory 1008, or the display drive control unit 1012.

The display drive control unit 1012 processes data such as the image data from the image processing unit 1011 in accordance with the control from the CPU 1001, and performs control to display information such as a still image, a moving image, and a predetermined screen on the display unit 1013. The display unit 1013 includes, for example, a display such as a Liquid Crystal Display (LCD) or an Organic Light Emitting Diode (OLED), and displays information such as a still image, a moving image, or a predetermined screen in accordance with the control from the display drive control unit 1012.

Note that, the display unit 1013 may be configured as a touch panel so that an operation signal corresponding to user's operation is supplied to the CPU 1001. Furthermore, not limited to the touch panel, an operation unit such as a physical button may be provided to accept the user's operation. Moreover, the electronic device 1000 may be provided with a communication unit such as a communication module compatible with a predetermined communication method, and data may be exchanged with an external device by wireless communication or wired communication.

The electronic device 1000 is configured as described above.

As described above, the technology according to the present disclosure is applied to the solid-state imaging device 1004. Specifically, the solid-state imaging devices 10, 20, and 30 can be applied to the solid-state imaging device 1004. By applying the technology according to the present disclosure to the solid-state imaging device 1004 of the solid-state imaging device 10 (20,30), the electric charge stored in the photodiode 111 (211) of the pixel 100 (200,300) is transferred and held in the analog memory 122 (222), and the electric charge is adaptively and non-destructively read during reading of the electric charge held in the analog memory 122 (222), so that the electric charge can be read and processed any number of times repeatedly.

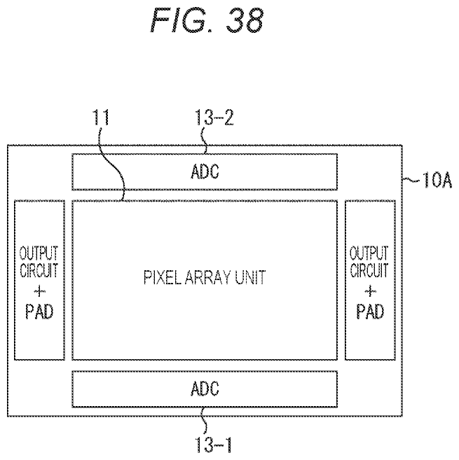

Here, as a structure of the solid-state imaging device 1004, for example, structures illustrated in FIGS. 38 to 40 can be adopted. Note that, here, as the solid-state imaging device 1004, a structure of the solid-state imaging device 10 will be described as an example.

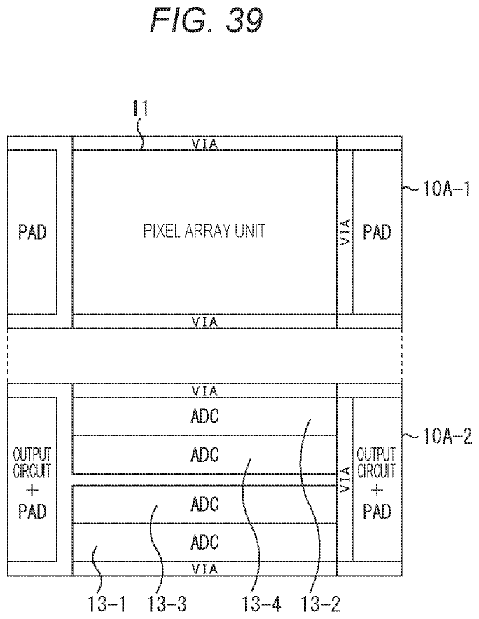

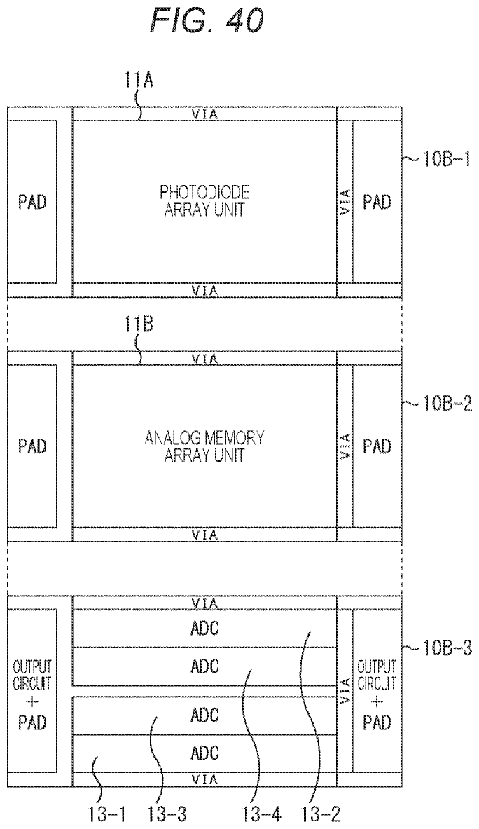

If a plurality of ADCs 151 is provided for the column ADC unit 13 in the solid-state imaging device 10, in the area illustrated in FIG. 38, for example, the chip size may increase and the cost may increase. Thus, as illustrated in FIGS. 39 and 40, the chips may be laminated.

For example, in FIG. 39, the solid-state imaging device 10A has a laminated structure (two-layer structure) in which a pixel layer 10A-1 and a peripheral circuit layer 10A-2 are laminated, the pixel layer 10A-1 including the pixel array unit 11 mainly, the peripheral circuit layer 10A-2 including an output circuit, a peripheral circuit, and the column ADC unit 13 mainly. In this laminated structure, an output line and a drive line of the pixel array unit 11 of the pixel layer 10A-1 are connected to the circuit of the peripheral circuit layer 10A-2 via a through-via (VIA).

Furthermore, for example, in FIG. 40, the solid-state imaging device 10B has a laminated structure (three-layer structure) in which a photodiode layer 10B-1, an analog memory layer 10B-2, and a peripheral circuit layer 10B-3 are laminated, the photodiode layer 10B-1 including the photodiode array unit 11A mainly, the analog memory layer 10B-2 including the analog memory array unit 11B mainly, the peripheral circuit layer 10B-3 including an output circuit, a peripheral circuit, and the column ADC unit 13 mainly. In this laminated structure, the photodiode array unit 11A of the photodiode layer 10B-1, the analog memory array unit 11B of the analog memory layer 10B-2, and the circuit of the peripheral circuit layer 10B-3 are connected to each other via through-vias (VIAs).

By adopting such a laminated structure, the chip size can be reduced and the cost can be reduced. Furthermore, since room is generated in a wiring layer, it becomes easy to route wiring. Moreover, each layer can be optimized by adopting the laminated structure.

Note that, although the structures of the solid-state imaging devices 10A and 10B are exemplified in FIGS. 39 and 40, a similar laminated structure (two-layer structure, three-layer structure) can be adopted also for the solid-state imaging devices 20A and 20B, and the solid-state imaging devices 30A and 30B. Furthermore, the laminated structures illustrated in FIGS. 39 and 40 are examples, and another structure may be adopted as the structure of the solid-state imaging device 1004.

(First Example of Configuration of Solid-State Imaging Device)

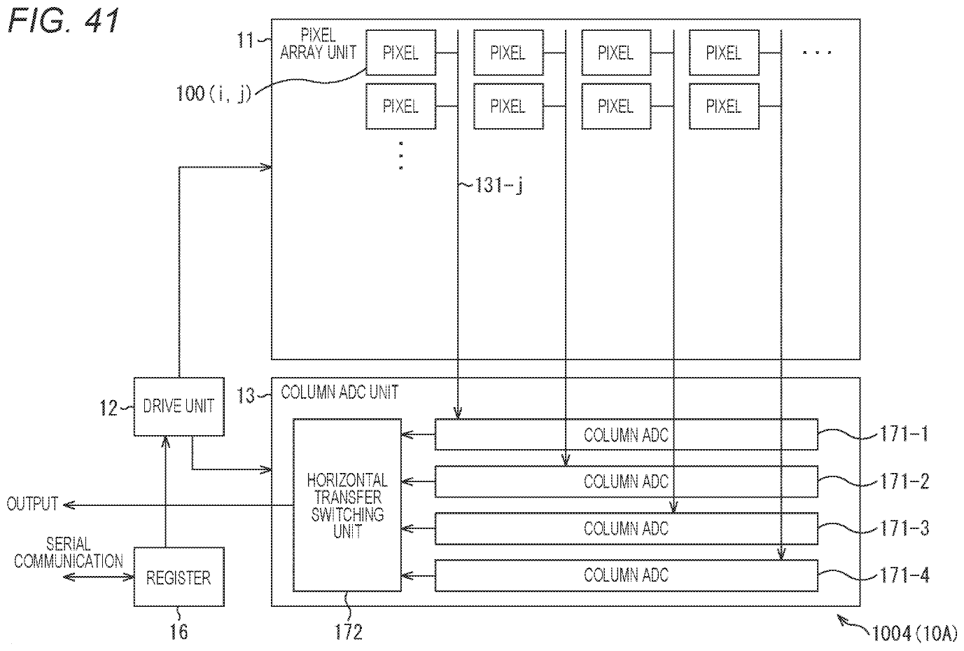

FIG. 41 illustrates an example of the configuration of the solid-state imaging device 10A (FIG. 1) as the solid-state imaging device 1004 mounted on the electronic device 1000 (FIG. 37).

In FIG. 41, the solid-state imaging device 10A includes the pixel array unit 11, the drive unit 12, the column ADC unit 13, and a register 16. The column ADC unit 13 includes column ADCs 171-1 to 171-4, and a horizontal transfer switching unit 172. That is, in the column ADC unit 13, connections of the columns ADCs 171-1 to 171-4 are respectively made for each of (the vertical signal lines 131 of) four columns in the horizontal direction.

To the column ADC 171-1, the vertical signal lines 131-j (j=1, 5, 9, . . . , 4m+1) are connected, and pixel signals (analog signals) read from the pixels 100(i, j) connected to the vertical signal lines 131-j are input. The column ADC 171-1 includes an AD conversion unit (Analog to Digital Converter (ADC)) for each of the vertical signal lines 131-j (j=1, 5, 9 . . . , 4m+1), and AD conversion is performed for each column, and a result of the AD conversion is output to the horizontal transfer switching unit 172.

Similarly, among the columns of the pixel array unit 11 in which the pixels 100(i, j) are arranged, AD conversion for each column j (j=2, 6, 10, . . . , 4m+2) is performed by the column ADC 171-2, AD conversion for each column j (j=3, 7, 11, . . . , 4m+3) is performed by the column ADC 171-3, and AD conversion for each column j (j=4, 8, 12, . . . , 4m+4) is performed by the column ADC 171-4. Results of the AD conversion of the column ADCs 171-2 to 171-4 are output to the horizontal transfer switching unit 172.

The horizontal transfer switching unit 172 switches the input depending on a reading mode, thereby selecting and outputting one of inputs among digital signals from the column ADCs 171-1 to 171-4 that are input to the horizontal transfer switching unit 172.

Note that, the register 16 performs serial communication with the CPU 1001 (FIG. 37), whereby the drive timing is set. Furthermore, although not illustrated, the column ADCs 171-1 to 171-4 are each provided with an analog signal amplification unit.

(Second Example of Configuration of Solid-State Imaging Device)

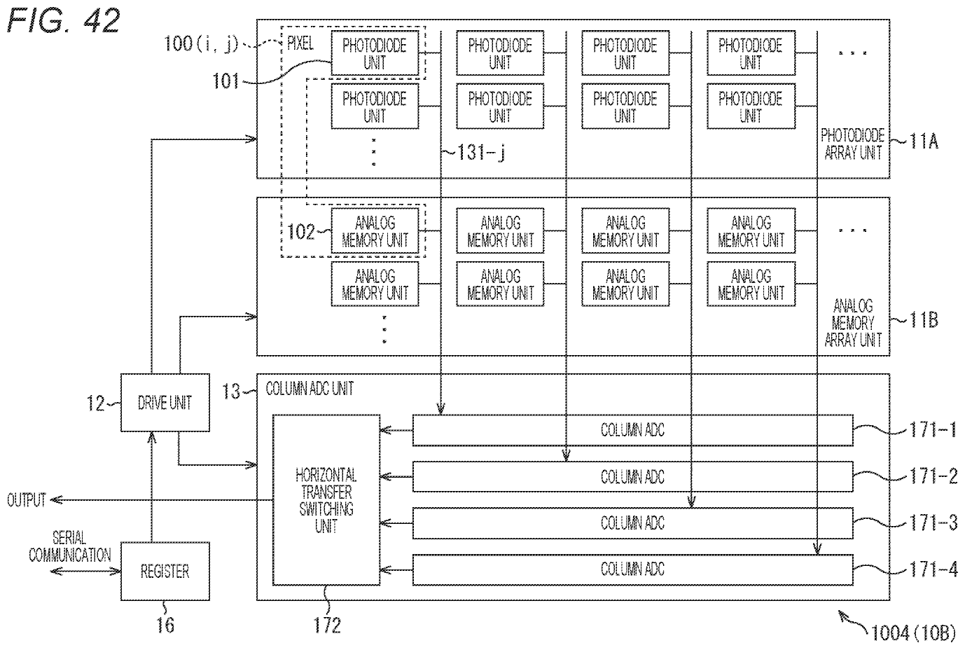

FIG. 42 illustrates an example of the configuration of the solid-state imaging device 10B (FIG. 4) as the solid-state imaging device 1004 mounted on the electronic device 1000 (FIG. 37).

In FIG. 42, the solid-state imaging device 10B includes the photodiode array unit 11A, the analog memory array unit 11B, the drive unit 12, the column ADC unit 13, and the register 16.

Similarly to FIG. 41, in the column ADC unit 13 of FIG. 42, connections of the columns ADC 171-1 to 171-4 are respectively made for each of (the vertical signal lines 131 of) four columns in the horizontal direction, and, to the column ADC 171-1, the vertical signal lines 131-j (j=1, 5, 9, . . . , 4m+1) are connected, and pixel signals (analog signals) read from the analog memory units 102 of the pixels 100(i, j) connected to the vertical signal lines 131-j are input, and AD conversion is performed for each column j (j=1, 5, 9, . . . , 4m+1).

Furthermore, also in the column ADCs 171-2 to 171-4, AD conversion is performed for each column j (4m+2, 4m+3, 4m+4) as in FIG. 41. Results of the AD conversion of the column ADCs 171-1 to 171-4 are output to the horizontal transfer switching unit 172. The horizontal transfer switching unit 172 selects and outputs one of inputs among digital signals input from the column ADCs 171-1 to 171-4 depending on a reading mode.

(Example of Pixel Arrangement)

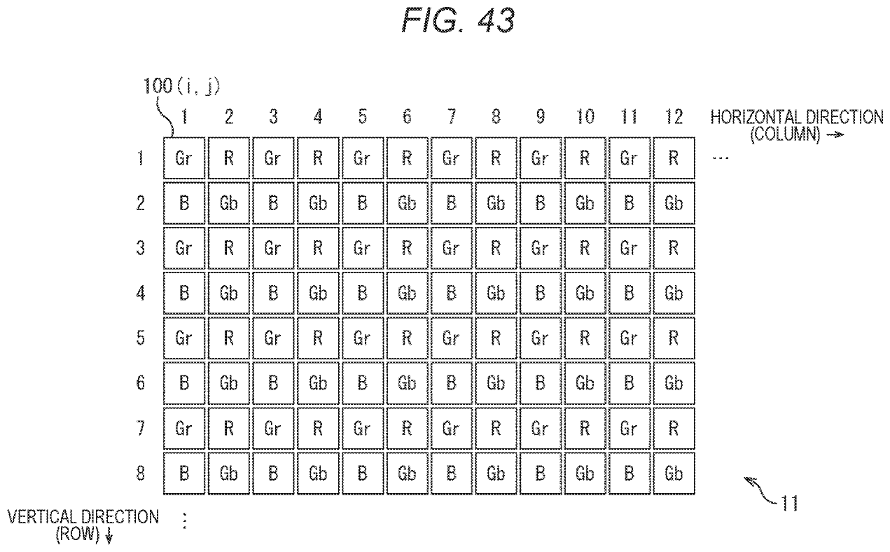

FIG. 43 illustrates a planar layout of the plurality of pixels 100 arranged two-dimensionally in the pixel array unit 11 of FIG. 41 or FIG. 42. Note that, in FIG. 43, to make the explanation easy to understand, the row numbers and column numbers corresponding to a row i and a column j of the pixels 100 are indicated in the left side and upper side areas.

Here, in the pixel array unit 11, paying attention to an area of four pixels (2×2 pixels) on the upper left, the Gr pixel 100(1, 1) and the Gb pixel 100(2, 2) of green (G), the R pixel 100(1, 2) of red (R), and the B pixel 100(2, 1) of blue (B) are arranged. Furthermore, in the pixel array unit 11, similar arrangement patterns are obtained also in the other areas of four pixels (2×2 pixels).

As described above, in the pixel array unit 11, an arrangement pattern is repeated in which G pixels 100 of green (G) are arranged in a checkered pattern, and in remaining portions, R pixels 100 of red (R) and B pixels 100 of blue (B) are alternately arranged in each row, and a Bayer arrangement is formed.

Note that, here, the pixel denoted as an R pixel is a pixel in which an electric charge corresponding to light of a red (R) component is obtained from light transmitted through an R color filter that transmits the wavelength of red (R). Furthermore, the pixel denoted as a G pixel is a pixel in which an electric charge corresponding to light of a green (G) component is obtained from light transmitted through a G color filter that transmits the wavelength of green (G), and the pixel denoted as a B pixel is a pixel in which an electric charge corresponding to light of a blue (B) component is obtained from light transmitted through a B color filter that transmits the wavelength of blue (B).

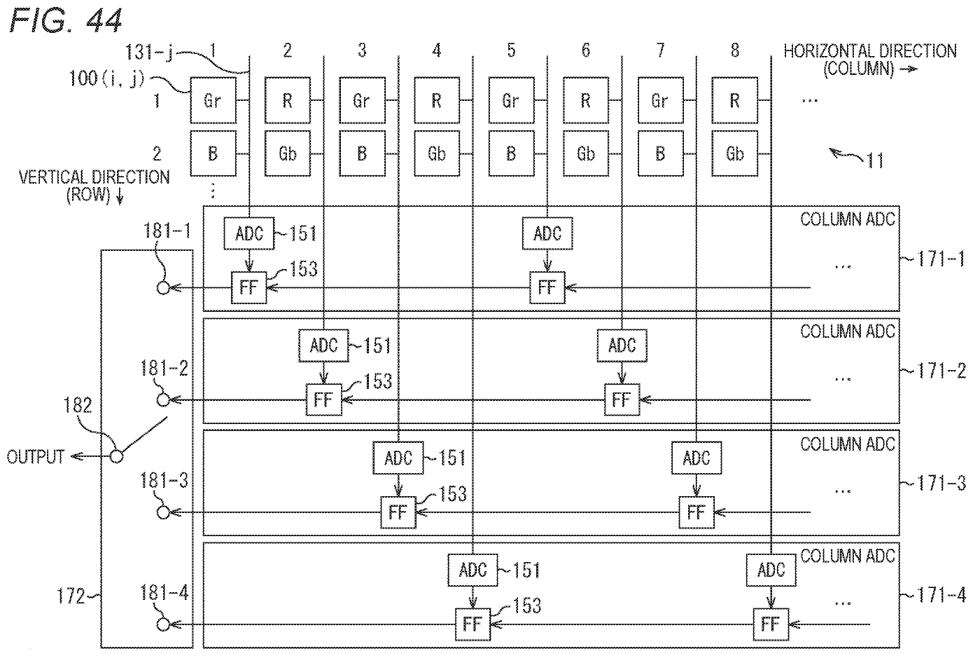

In the pixel array unit 11, the pixels 100 arranged in the Bayer arrangement are connected to any of the column ADCs 171-1 to 171-4 via the vertical signal lines 131 for each four columns in the horizontal direction (FIG. 44). For example, in FIG. 44, paying attention to the first row, the Gr pixel 100(1, 1) in the first column and the Gr pixel 100(1, 5) in the fifth column are connected to (the respective ADCs 151 of) the column ADC 171-1 via the vertical signal lines 131-1 and 131-5.

Furthermore, paying attention to the first row, the R pixel 100(1, 2) in the second column and the R pixel 100(1, 6) in the sixth column are connected to the column ADC 171-2 via the vertical signal lines 131-2 and 131-6. Similarly, the Gr pixel 100(1, 3) in the third column and the Gr pixel 100(1, 7) in the seventh column are connected to the column ADC 171-3 via the vertical signal lines 131-3 and 131-7, and the R pixel 100(1, 4) in the fourth column and the R pixel 100(1, 8) in the eighth column are connected to the column ADC 171-4 via the vertical signal lines 131-4 and 131-8.

At this time, in the column ADC 171-1, signal voltages from the vertical signal lines 131-1, 131-5, . . . , and 131-j are compared with the reference voltage by a plurality of ADCs 151 provided for each column j (j=1, 5, 9, . . . , 4m+1) in the horizontal direction, and count values depending on the comparison results are held in the FF circuits 153.

Similarly, the column ADC 171-2 is provided with a plurality of ADCs 151 for each column j (j=2, 6, 10, . . . , 4m+2) in the horizontal direction, the column ADC 171-3 is provided with a plurality of ADCs 151 for each column j (j=3, 7, 11, . . . , 4m+3) in the horizontal direction, the column ADC 171-4 is provided with a plurality of ADCs 151 for each column j (j=4, 8, 12, . . . , 4m+4) in the horizontal direction, and in the ADCs 151, comparisons are respectively performed between the signal voltage from the connected vertical signal line 131-j and the reference voltage, and count values depending on the comparison results are respectively held in the FF circuits 153.

In the horizontal transfer switching unit 172, input terminals 181-1 to 181-4 are connected to (the FF circuits 153 of) the column ADCs 171-1 to 171-4, respectively, and any of the input terminals 181-1 to 181-4 is selected depending on a reading mode, whereby a result (digital signal) of the AD conversion input from any of the column ADCs 171-1 to 171-4 is output via the output terminal 182.

(Example of all-Pixel Reading)

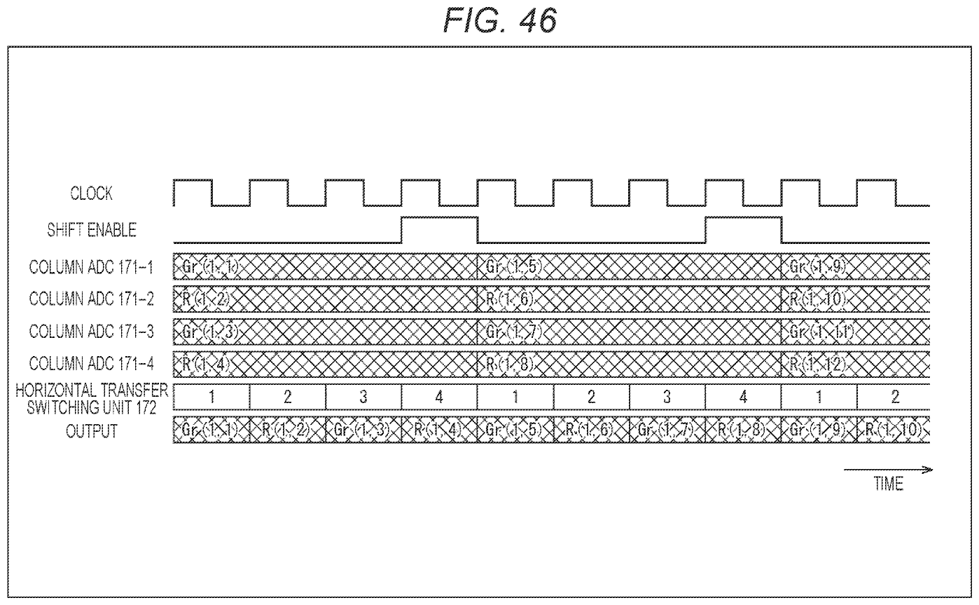

Next, a specific example of reading of the pixel 100 will be described, and here, first, a case will be described where the all-pixel reading is performed, as a drive mode of the plurality of pixels 100 arranged two-dimensionally in the pixel array unit 11, with reference to FIGS. 45 and 46.

In FIG. 45, among the pixels 100 arranged in the pixel array unit 11, pixels to be read are cross-hatched, and it is indicated that all the pixels 100 are the pixels to be read, and the all-pixel reading is performed. Furthermore, regarding the scan order during the all-pixel reading, the scan is performed line by line in order from the first row as illustrated by the arrows in the figure.

The timing chart of FIG. 46 illustrates a processing target of each part of the column ADC unit 13 in a case where the all-pixel reading illustrated in FIG. 45 is performed.

Since the column ADC unit 13 is provided with the column ADCs 171-1 to 171-4 for each four columns in the horizontal direction, when the scan of the first row is started, first, the processing target of the column ADC 171-1 is the Gr pixel 100(1, 1). Similarly, the processing target of the column ADC 171-2 is the R pixel 100(1, 2), the processing target of column ADC 171-3 is the Gr pixel 100(1, 3), and the processing target of column ADC 171-4 is the R pixel 100(1, 4).

At this time, in the horizontal transfer switching unit 172, in accordance with a clock signal, the input terminal 181 connected to the output terminal 182 is switched to the input terminal 181-1, the input terminal 181-2, the input terminal 181-3, and the input terminal 181-4 in that order. As a result, as the output of the column ADC unit 13, the result of the AD conversion is output in the order of the Gr pixel 100(1, 1), the R pixel 100(1, 2), the Gr pixel 100(1, 3), and the R pixel 100(1, 4).

Next, in the column ADC unit 13, in accordance with a shift enable signal, the processing target of the column ADC 171-1 is the Gr pixel 100(1, 5), the processing target of the column ADC 171-2 is the R pixel 100(1, 6), the processing target of the column ADC 171-3 is the Gr pixel 100(1, 7), and the processing target of the column ADC 171-4 is the R pixel 100(1, 8). At this time, in the horizontal transfer switching unit 172, the input is switched to the input terminals 181-1 to 181-4 in order, and the result of the AD conversion is output in the order of the Gr pixel 100(1, 5), the R pixel 100(1, 6), the Gr pixel 100(1, 7), and the R pixel 100(1, 8).

Note that, since it will be repeated, the following description will be omitted, but the result of the AD conversion of the pixel 100 in each column will be output similarly after that in response to the scan of the first row. Furthermore, when the scan of the first row is completed, then, similar processing is repeated for the second row and the third row, and eventually, the similar processing is repeated until the last row.

(Example of ⅓ Thinning Out Reading)

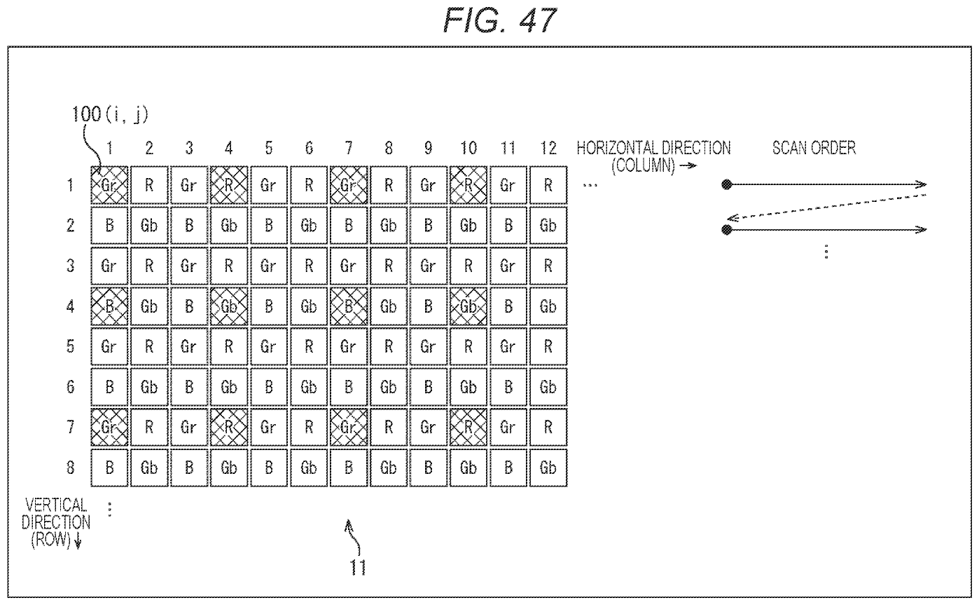

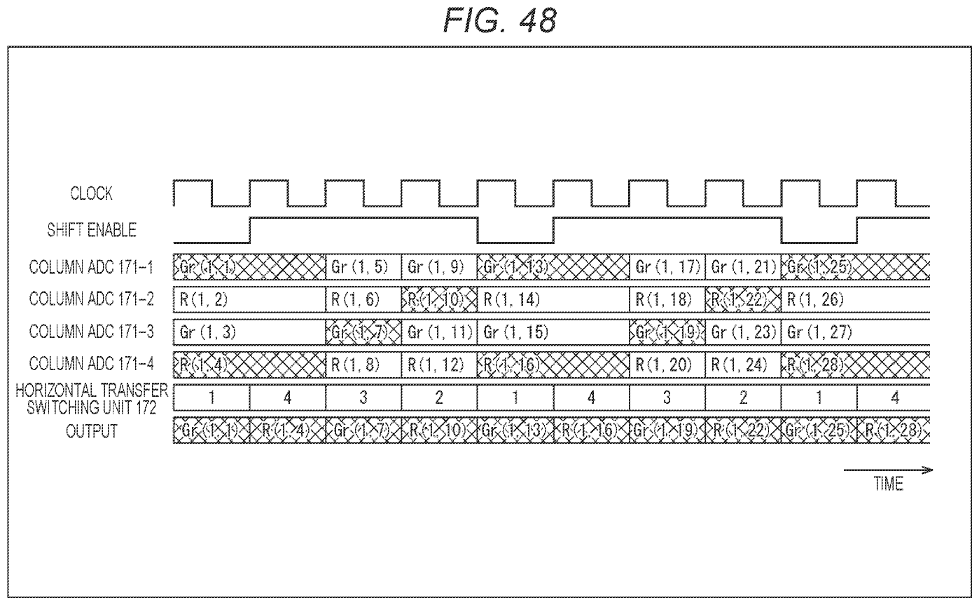

Next, with reference to FIGS. 47 and 48, a case will be described where ⅓ thinning out reading is performed as a drive mode of the plurality of pixels 100 arranged two-dimensionally in the pixel array unit 11.

In FIG. 47 as well, pixels to be read are cross-hatched, and it is indicated that since the pixels in each of the horizontal direction and the vertical direction become the pixel to be read every three pixels, only ⅓ of all the pixels 100 are the pixel to be read, and the ⅓ thinning out reading is performed. Furthermore, regarding the scan order during the ⅓ thinning out reading, the scan is performed line by line in order from the first row.

The timing chart of FIG. 48 illustrates a processing target of each part of the column ADC unit 13 in a case where the ⅓ thinning out reading illustrated in FIG. 47 is performed.

The column ADC unit 13 is provided with the column ADCs 171-1 to 171-4 for each four columns in the horizontal direction, but the pixels 100 in the horizontal direction are thinned out to ⅓, so that when the scan of the first row is started, the processing target of the column ADC 171-1 is Gr pixel 100(1, 1), and the processing target of the column ADC 171-4 is the R pixel 100(1, 4). At this time, in the horizontal transfer switching unit 172, the input is switched to the input terminals 181-1 and 181-4 in order, and the result of the AD conversion is output in the order of the Gr pixel 100(1, 1) and the R pixel 100(1, 4).

Next, in the column ADC unit 13, since the pixels 100 in the horizontal direction are thinned out to ⅓, the processing target of the column ADC 171-3 is the Gr pixel 100(1, 7). At this time, in the horizontal transfer switching unit 172, the input is switched to the input terminal 181-3, and the result of the AD conversion of the Gr pixel 100(1, 7) is output. Furthermore, in the column ADC unit 13, since the pixels 100 in the horizontal direction are thinned out to ⅓, the processing target of the column ADC 171-2 is the R pixel 100(1, 10), and the input of the horizontal transfer switching unit 172 is switched to the input terminal 181-2, and the result of the AD conversion of the R pixel 100(1, 10) is output.

Note that, since it will be repeated, the following description will be omitted, but the result of the AD conversion of pixel 100 is output every three columns similarly after that in response to the scan of the first row. Furthermore, when the scan of the first row is completed, similar processing is repeated every three rows, such as the fourth row and the seventh row, and eventually, the similar processing is repeated every three rows until the last row.

(Example of Pixel Addition Reading)

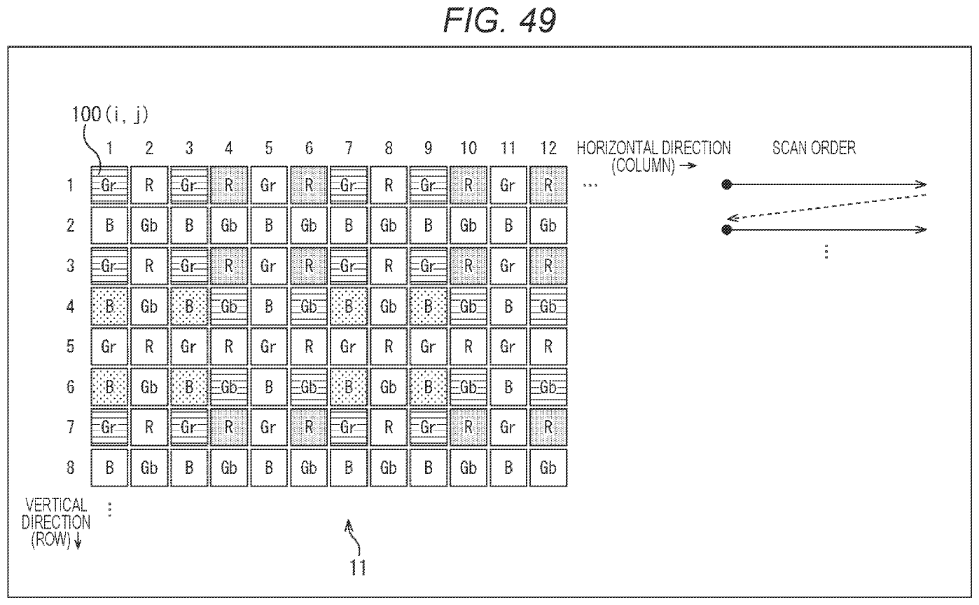

Finally, with reference to FIGS. 49 to 51, an example of the pixel addition reading will be described as a drive mode of the plurality of pixels 100 arranged two-dimensionally in the pixel array unit 11.

In FIG. 49, different hatching is applied to the pixel to be read for each RGB color, and it is indicated that every four pixels of the same color are the target pixel for the pixel addition reading and the pixel addition reading is performed. Furthermore, regarding the scan order during the pixel addition reading, the scan is performed line by line in order from the first row as illustrated by the arrows in the figure.

Here, since pixel addition is performed with four pixels of the same color, for example, four pixels of the Gr pixel 100(1, 1), the Gr pixel 100(1, 3), the Gr pixel 100(3, 1), and the Gr pixel 100(3, 3) are the pixels to be read for the same pixel addition reading. Furthermore, for example, four pixels of the R pixel 100(1, 4), the R pixel 100(1, 6), the R pixel 100(3, 4), and the R pixel 100(3, 6) are the pixels to be read for the same pixel addition reading.

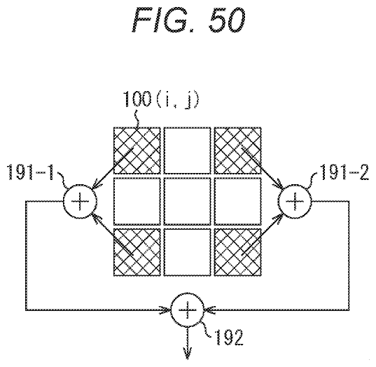

Furthermore, as illustrated in FIG. 50, in this pixel addition reading, signals from two pixels 100 in the vertical direction among the four pixels to be read for the same pixel addition reading target are subjected to analog addition by addition units 191-1 and 191-2, respectively, and two signals corresponding to those analog additions are subjected to digital addition by an addition unit 192.

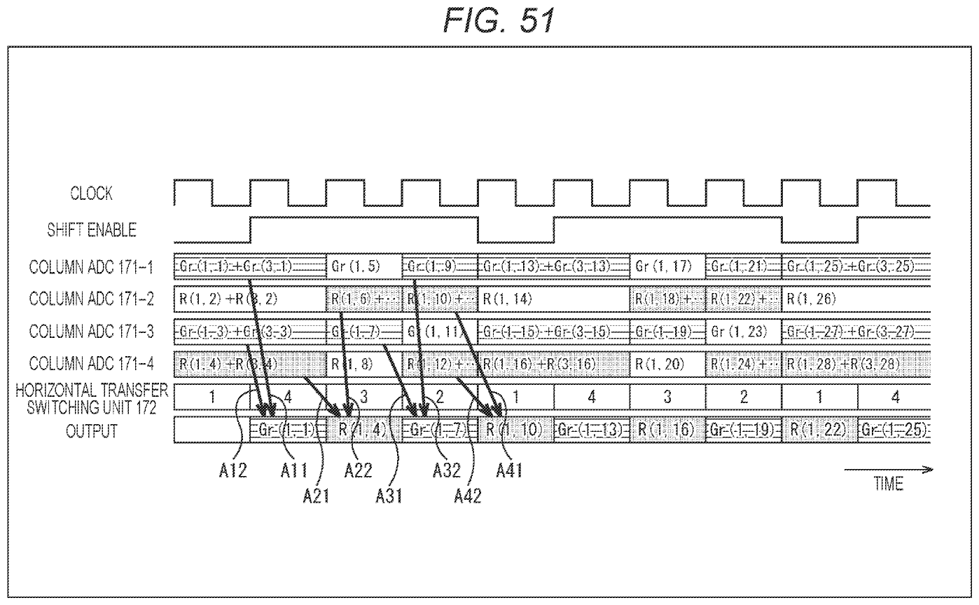

The timing chart of FIG. 51 illustrates a processing target of each part of the column ADC unit 13 in a case where the pixel addition reading illustrated in FIG. 49 is performed.

The column ADC unit 13 is provided with the column ADCs 171-1 to 171-4 for each four columns in the horizontal direction, but, since the addition reading is performed every four pixels of the same color, when the scan is performed, the processing target of the column ADC 171-1 is an addition signal A11 (Gr(1, 1)+Gr(3, 1)) obtained by analog addition of the Gr pixel 100(1, 1) and the Gr pixel 100(3, 1).

Similarly, the processing target of the column ADC 171-3 is an addition signal A12 (Gr(1, 3)+Gr(3, 3)) obtained by analog addition of the Gr pixel 100(1, 3) and the Gr pixel 100(3,3), and the processing target of the column ADC 171-4 is an addition signal A21 (R(1, 4)+R(3, 4)) obtained by analog addition of the R pixel 100(1, 4) and the R pixel 100(3, 4).

At this time, in the column ADC unit 13, the addition signal A11 (Gr(1, 1)+Gr(3, 1)) in the first column and the addition signal A12 (Gr(1, 3)+Gr(3, 3)) in the third column are subjected to digital addition, and the AD conversion result (A11+A12) is output.

Next, in the column ADC unit 13, since the addition reading is performed every four pixels of the same color, the processing target of the column ADC 171-2 is an addition signal A22 (R(1, 6)+R(3, 6)) obtained by analog addition of the R pixel 100(1, 6) and the R pixel 100(3, 6), and the processing target of the column ADC 171-3 is an addition signal A31 (Gr(1, 7)+Gr(3, 7)) obtained by analog addition of the Gr pixel 100(1, 7) and the Gr pixel 100(3, 7).

At this time, in the column ADC unit 13, the addition signal A21 (R(1, 4)+R(3, 4)) in the fourth row and the addition signal A22 (R(1, 6)+R(3, 6)) in the sixth row are subjected to digital addition, and the AD conversion addition result (A21+A22) is output.

Note that, since it will be repeated, the following description will be omitted, but the addition reading is repeated every four pixels of the same color similarly after that, and the addition result is output (for example, the addition result (A31+A32) or the addition result (A41+A42) of FIG. 51, or the like) that is obtained by analog addition in the vertical direction and digital addition in the horizontal direction every four pixels of the same color.

Furthermore, in the description of FIGS. 41 to 51, the solid-state imaging device 10A (FIG. 1) has been described as an example of the solid-state imaging device 1004 mounted on the electronic device 1000 (FIG. 37); however, similar processing (for example, processing of the all-pixel reading, thinning out reading, and pixel addition reading) can also be performed by the solid-state imaging device 10B, the solid-state imaging device 20 (20A, 20A), and the solid-state imaging device 30 (30A, 30A).

### 5. Modifications

In the above description, the configuration using the floating diffusion 126 (226, 326) has been described as the configuration for reading the electric charge held in the analog memory 122 (222, 322) in the pixel 100 (200, 300); however, the configuration of the pixel 100 (200, 300) is an example, and the electric charge held in the analog memory 122 (222, 322) may be read by, for example, a floating gate or a sample hold circuit. Furthermore, in the above description, in the first embodiment, the case has been described where the global shutter method is used as the shutter method; however, not limited to the global shutter method, the exposure with the rolling shutter method may be performed. Here, in the global shutter method, the shutter operation is performed on all the pixels simultaneously, whereas in the rolling shutter method, the shutter operation is performed on one or several rows basis.

Furthermore, in the above description, the solid-state imaging device 10 (20, 30) as a CMOS image sensor has been described as an example of the solid-state imaging device to which the technology according to the present disclosure is applied; however, the technology according to the present disclosure is not limited to application to CMOS image sensors. That is, the technology according to the present disclosure can be applied to all solid-state imaging devices in which pixels are arranged two-dimensionally (for example, an image sensor such as a Charge Coupled Device (CCD) image sensor). Moreover, the technology according to the present disclosure is applicable not only to a solid-state imaging device that detects a distribution of incident light amount of visible light and captures the distribution as an image, but also to all the solid state imaging devices that capture as an image a distribution of incident amount of infrared rays, X-rays, particles, or the like, for example.

### 6. Usage Examples of Solid-State Imaging Device

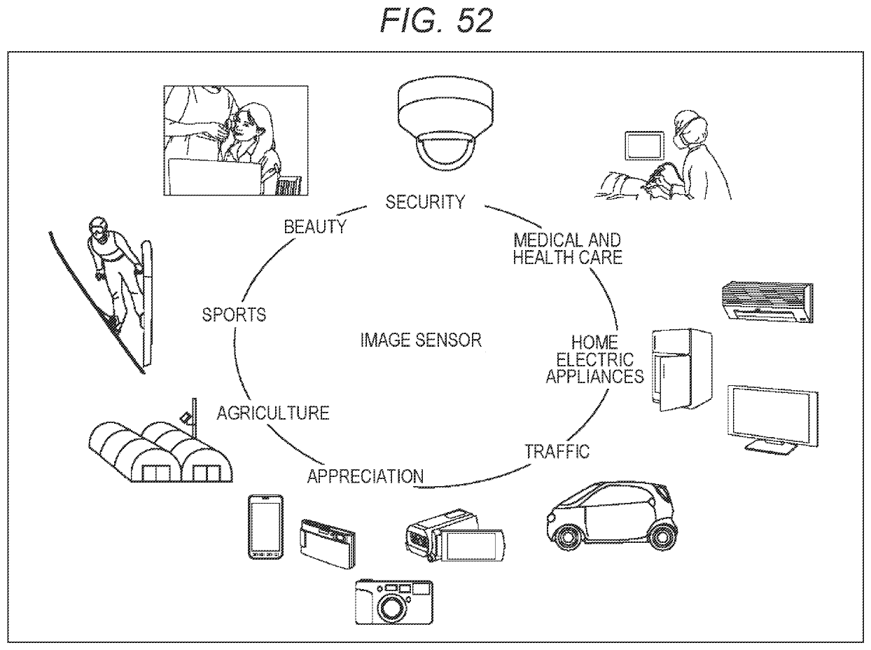

FIG. 52 is a diagram illustrating usage examples of the solid-state imaging device to which the technology according to the present disclosure is applied.

The solid-state imaging device 10 (20, 30) such as a CMOS image sensor can be used for various cases of sensing light such as visible light, infrared light, ultraviolet light, or X-rays, for example, as follows. That is, as illustrated in FIG. 52, not only in a field of appreciation in which an image to be used for appreciation is shot, also in a device used in a field such as a field of traffic, a field of home electric appliances, a field of medical and health care, a field of security, a field of beauty, a field of sports, or a field of agriculture, the solid-state imaging device 10 (20, 30) can be used.

Specifically, in the field of appreciation, the solid-state imaging device 10 (20, 30) can be used in a device (for example, the electronic device 1000 of FIG. 37) for imaging the image to be used for appreciation, such as a digital camera, a smartphone, a mobile phone with a camera function.

In the field of traffic, for example, the solid-state imaging device 10 (20, 30) can be used in devices to be used for traffic, such as an automotive sensor for imaging ahead of, behind, around, and inside the car, a monitoring camera for monitoring traveling vehicles and roads, and a distance sensor for measuring a distance between vehicles and the like, for safe driving such as automatic stop, and recognition of driver's condition.

In the field of home electric appliances, for example, the solid-state imaging device 10 (20,30) can be used in devices to be used for home electric appliances, such as a television receiver, a refrigerator, and an air conditioner, for imaging a user's gesture and performing device operation in accordance with the gesture. Furthermore, in the field of medical and health care, the solid-state imaging device 10 (20, 30) can be used in devices to be used for medical and health care, such as an endoscope, and a device for performing angiography by receiving infrared light.

In the field of security, for example, the solid-state imaging device 10 (20, 30) can be used in devices to be used for security, such as a monitoring camera for crime prevention, and a camera for person authentication. Furthermore, in the field of beauty, the solid-state imaging device 10 (20, 30) can be used in devices to be used for beauty, such as a skin measuring instrument for imaging skin, and a microscope for imaging a scalp.

In the field of sports, the solid-state imaging device 10 (20, 30) can be used in devices to be used for sports, such as an action camera for sports application, and a wearable camera. Furthermore, in the field of agriculture, the solid-state imaging device 10 (20, 30) can be used in devices to be used for agriculture, such as a camera for monitoring conditions of fields and crops, and the like.

### 7. Application Example to Mobile Body

The technology according to the present disclosure (the present technology) can be applied to various products. The technology according to the present disclosure may be implemented as a device mounted on any type of mobile body, for example, a car, an electric car, a hybrid electric car, a motorcycle, a bicycle, a personal mobility, an airplane, a drone, a ship, a robot, or the like.

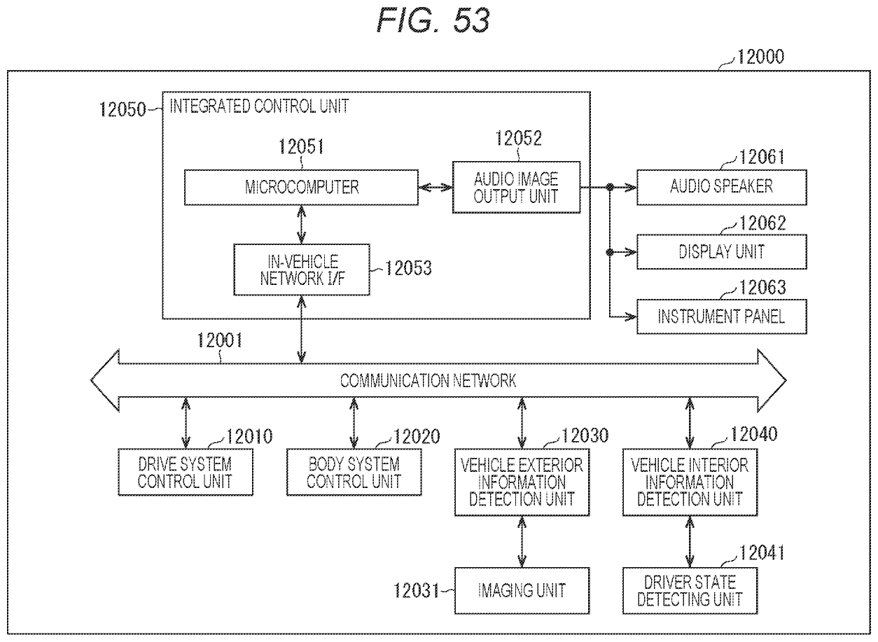

FIG. 53 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example illustrated in FIG. 53, the vehicle control system 12000 includes a drive system control unit 12010, a body system control unit 12020, a vehicle exterior information detection unit 12030, a vehicle interior information detection unit 12040, and an integrated control unit 12050. Furthermore, as functional configurations of the integrated control unit 12050, a microcomputer 12051, an audio image output unit 12052, and an in-vehicle network interface (I/F) 12053 are illustrated.

The drive system control unit 12010 controls operation of devices related to a drive system of a vehicle in accordance with various programs. For example, the drive system control unit 12010 functions as a control device of a driving force generating device for generating driving force of the vehicle, such as an internal combustion engine or a driving motor, a driving force transmitting mechanism for transmitting driving force to wheels, a steering mechanism for adjusting a steering angle of the vehicle, a braking device for generating braking force of the vehicle, and the like.

The body system control unit 12020 controls operation of various devices equipped on the vehicle body in accordance with various programs. For example, the body system control unit 12020 functions as a control device of a keyless entry system, a smart key system, a power window device, or various lamps such as a head lamp, a back lamp, a brake lamp, a turn signal lamp, and a fog lamp. In this case, to the body system control unit 12020, a radio wave transmitted from a portable device that substitutes for a key, or signals of various switches can be input. The body system control unit 12020 accepts input of these radio waves or signals and controls a door lock device, power window device, lamp, and the like of the vehicle.

The vehicle exterior information detection unit 12030 detects information on the outside of the vehicle equipped with the vehicle control system 12000. For example, an imaging unit 12031 is connected to the vehicle exterior information detection unit 12030. The vehicle exterior information detection unit 12030 causes the imaging unit 12031 to capture an image outside the vehicle and receives the image captured. The vehicle exterior information detection unit 12030 may perform object detection processing or distance detection processing on a person, a car, an obstacle, a sign, a character on a road surface, or the like, on the basis of the received image.

The imaging unit 12031 is an optical sensor that receives light and outputs an electric signal depending on an amount of light received. The imaging unit 12031 can output the electric signal as an image, or as distance measurement information. Furthermore, the light received by the imaging unit 12031 may be visible light, or invisible light such as infrared rays.

The vehicle interior information detection unit 12040 detects information on the inside of the vehicle. The vehicle interior information detection unit 12040 is connected to, for example, a driver state detecting unit 12041 that detects a state of a driver. The driver state detecting unit 12041 includes, for example, a camera that captures an image of the driver, and the vehicle interior information detection unit 12040 may calculate a degree of fatigue or a degree of concentration of the driver, or determine whether or not the driver is dozing, on the basis of the detection information input from the driver state detecting unit 12041.

The microcomputer 12051 can calculate a control target value of the driving force generating device, the steering mechanism, or the braking device on the basis of the information on the inside and outside of the vehicle acquired by the vehicle exterior information detection unit 12030 or the vehicle interior information detection unit 12040, and output a control command to the drive system control unit 12010. For example, the microcomputer 12051 can perform cooperative control aiming for implementing functions of advanced driver assistance system (ADAS) including collision avoidance or shock mitigation of the vehicle, follow-up traveling based on an inter-vehicle distance, vehicle speed maintaining traveling, vehicle collision warning, vehicle lane departure warning, or the like.

Furthermore, the microcomputer 12051 can perform cooperative control aiming for automatic driving that autonomously travels without depending on operation of the driver, or the like, by controlling the driving force generating device, the steering mechanism, the braking device, or the like on the basis of information on the periphery of the vehicle acquired by the vehicle exterior information detection unit 12030 or the vehicle interior information detection unit 12040.

Furthermore, the microcomputer 12051 can output a control command to the body system control unit 12020 on the basis of information on the outside of the vehicle acquired by the vehicle exterior information detection unit 12030. For example, the microcomputer 12051 can perform cooperative control aiming for preventing dazzling such as switching from the high beam to the low beam, by controlling the head lamp depending on a position of a preceding vehicle or an oncoming vehicle detected by the vehicle exterior information detection unit 12030.

The audio image output unit 12052 transmits at least one of audio or image output signal to an output device capable of visually or aurally notifying an occupant in the vehicle or the outside of the vehicle of information. In the example of FIG. 53, as the output device, an audio speaker 12061, a display unit 12062, and an instrument panel 12063 are exemplified. The display unit 12062 may include, for example, at least one of an on-board display or a head-up display.

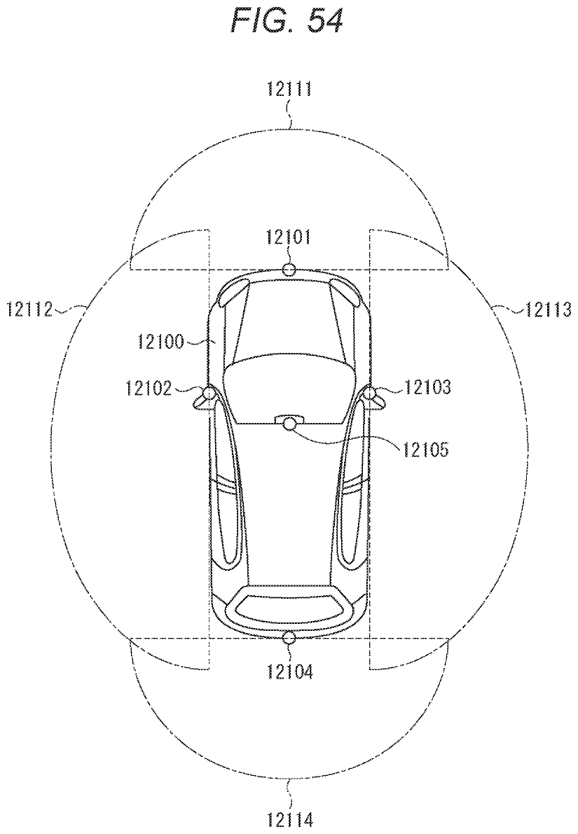

FIG. 54 is a diagram illustrating an example of installation positions of the imaging unit 12031.

In FIG. 54, as the imaging unit 12031, imaging units 12101, 12102, 12103, 12104, and 12105 are included.

Imaging units 12101, 12102, 12103, 12104, and 12105 are provided at, for example, at a position of the front nose, the side mirror, the rear bumper, the back door, the upper part of the windshield in the vehicle interior, or the like, of a vehicle 12100. The imaging unit 12101 provided at the front nose and the imaging unit 12105 provided at the upper part of the windshield in the vehicle interior mainly acquire images ahead of the vehicle 12100. The imaging units 12102 and 12103 provided at the side mirrors mainly acquire images on the sides of the vehicle 12100. The imaging unit 12104 provided at the rear bumper or the back door mainly acquires an image behind the vehicle 12100. The imaging unit 12105 provided on the upper part of the windshield in the vehicle interior is mainly used for detecting a preceding vehicle, a pedestrian, an obstacle, a traffic signal, a traffic sign, a lane, or the like.

Note that, FIG. 54 illustrates an example of imaging ranges of the imaging units 12101 to 12104. An imaging range 12111 indicates an imaging range of the imaging unit 12101 provided at the front nose, imaging ranges 12112 and 12113 respectively indicate imaging ranges of the imaging units 12102 and 12103 provided at the side mirrors, an imaging range 12114 indicates an imaging range of the imaging unit 12104 provided at the rear bumper or the back door. For example, image data captured by the imaging units 12101 to 12104 are superimposed on each other, whereby an overhead image is obtained of the vehicle 12100 viewed from above.

At least one of the imaging units 12101 to 12104 may have a function of acquiring distance information. For example, at least one of the imaging units 12101 to 12104 may be a stereo camera including a plurality of imaging elements, or may be an imaging element including pixels for phase difference detection.

For example, on the basis of the distance information obtained from the imaging units 12101 to 12104, the microcomputer 12051 obtains a distance to each three-dimensional object within the imaging ranges 12111 to 12114, and a temporal change of the distance (relative speed to the vehicle 12100), thereby being able to extract, as a preceding vehicle, a three-dimensional object that is in particular a closest three-dimensional object on a traveling path of the vehicle 12100 and traveling at a predetermined speed (for example, greater than or equal to 0 km/h) in substantially the same direction as that of the vehicle 12100. Moreover, the microcomputer 12051 can set an inter-vehicle distance to be secured in advance in front of the preceding vehicle, and can perform automatic brake control (including follow-up stop control), automatic acceleration control (including follow-up start control), and the like. As described above, it is possible to perform cooperative control aiming for automatic driving that autonomously travels without depending on operation of the driver, or the like.

For example, on the basis of the distance information obtained from the imaging units 12101 to 12104, the microcomputer 12051 can extract three-dimensional object data regarding the three-dimensional object by classifying the objects into a two-wheeled vehicle, a regular vehicle, a large vehicle, a pedestrian, and other three-dimensional objects such as a utility pole, and use the data for automatic avoidance of obstacles. For example, the microcomputer 12051 identifies obstacles in the periphery of the vehicle 12100 into an obstacle visually recognizable to the driver of the vehicle 12100 and an obstacle difficult to visually recognize. Then, the microcomputer 12051 determines a collision risk indicating a risk of collision with each obstacle, and when the collision risk is greater than or equal to a set value and there is a possibility of collision, the microcomputer 12051 outputs an alarm to the driver via the audio speaker 12061 and the display unit 12062, or performs forced deceleration or avoidance steering via the drive system control unit 12010, thereby being able to perform driving assistance for collision avoidance.

At least one of the imaging units 12101 to 12104 may be an infrared camera that detects infrared rays. For example, the microcomputer 12051 can recognize a pedestrian by determining whether or not a pedestrian exists in the captured images of the imaging units 12101 to 12104. Such pedestrian recognition is performed by, for example, a procedure of extracting feature points in the captured images of the imaging units 12101 to 12104 as infrared cameras, and a procedure of performing pattern matching processing on a series of feature points indicating a contour of an object to determine whether or not the object is a pedestrian. When the microcomputer 12051 determines that a pedestrian exists in the captured images of the imaging units 12101 to 12104 and recognizes the pedestrian, the audio image output unit 12052 controls the display unit 12062 so that a rectangular contour line for emphasis is superimposed and displayed on the recognized pedestrian. Furthermore, the audio image output unit 12052 may control the display unit 12062 so that an icon or the like indicating the pedestrian is displayed at a desired position.

In the above, an example has been described of the vehicle control system to which the technology according to the present disclosure can be applied. The technology according to the present disclosure can be applied to the imaging unit 12101 among the configurations described above. Specifically, the solid-state imaging device 10 (20, 30) can be applied to the imaging unit 12031. By applying the technology according to the present disclosure to the imaging unit 12031, for example, processing becomes possible such as detecting an object (for example, a person, a car, an obstacle, a sign, a character on a road surface, or the like) from a reduced image output prior to the main processing, and extracting an ROI image of an arbitrary area including the detected object (for example, the application example illustrated in FIG. 7), so that it becomes possible to improve the visibility, and more accurately recognize the object such as the person, car, obstacle, sign, or character on the road surface.

Note that, the embodiment of the present technology is not limited to the embodiments described above, and various modifications are possible without departing from the scope of the present technology.

Furthermore, the technology according to the present disclosure can have a configuration as follows.

(1)

A solid-state imaging device including

an array unit in which a plurality of pixels each including a photoelectric conversion unit and an analog memory unit is arranged, in which

the analog memory unit holds an electric charge photoelectrically converted by the photoelectric conversion unit by first exposure, and

the electric charge held in the analog memory unit by the first exposure is adaptively and non-destructively read.

(2)

The solid-state imaging device according to (1), in which

the electric charge held in the analog memory unit is read a plurality of times non-destructively.

(3)

The solid-state imaging device according to (1) or (2), in which

an electric charge photoelectrically converted by the photoelectric conversion unit by second exposure is read.

(4)

The solid-state imaging device according to (1) or (2), in which

the analog memory unit includes a plurality of analog memories,

at least one or more of the analog memories of the plurality of analog memories holds the electric charge photoelectrically converted by the photoelectric conversion unit by the first exposure, and

the electric charge held in the analog memory by the first exposure is selectively read.

(5)

The solid-state imaging device according to (1) or (2), in which

the first exposure is performed with a global shutter method.

(6)

The solid-state imaging device according to (5), in which

the electric charge held in the analog memory unit for each of the plurality of pixels is read depending on an arbitrary area in an image frame, a drive mode of the pixels, predetermined signal processing, or a predetermined timing.

(7)

The solid-state imaging device according to (5) or (6), in which

among electric charges held in the analog memory unit for the respective plurality of pixels, electric charges to generate a first image are read, and then electric charges to generate a second image captured simultaneously with the first image are read.

(8)

The solid-state imaging device according to (3), in which

the first exposure is performed with a global shutter method or a rolling shutter method, and the second exposure is performed with the rolling shutter method.

(9)

The solid-state imaging device according to (8), in which

the second exposure is performed after the first exposure temporally.

(10)

The solid-state imaging device according to (8) or (9), in which

the electric charge held in the analog memory unit for each of the plurality of pixels is read depending on an arbitrary area in an image frame, a drive mode of the pixels, predetermined signal processing, or a predetermined timing.

(11)

The solid-state imaging device according to (4), in which

the plurality of analog memories sequentially holds electric charges obtained by time-division of the first exposure as the electric charge photoelectrically converted by the photoelectric conversion unit.

(12)

The solid-state imaging device according to (11), in which

the electric charges held in the plurality of analog memories are added together and read.

(13)

The solid-state imaging device according to (11) or (12), in which

the electric charges held in the plurality of analog memories of the analog memory unit for each of the plurality of pixels are read depending on an arbitrary area in an image frame, a drive mode of the pixels, predetermined signal processing, or a predetermined timing.

(14)

The solid-state imaging device according to (11) or (12), in which

the electric charges held in the plurality of analog memories of the analog memory unit for each of the plurality of pixels are selectively read depending on a state of time-division exposure of the first exposure.

(15)

The solid-state imaging device according to any of (11) to (14), in which

an electric charge photoelectrically converted by the photoelectric conversion unit by second exposure is read.

(16)

The solid-state imaging device according to any of (1) to (15), in which

in the array unit, the plurality of pixels is arranged two-dimensionally,

an AD conversion unit is further provided, the AD conversion unit converting, into a digital signal, an analog signal input via a vertical signal line provided corresponding to a pixel arrangement in a horizontal direction in the array unit, and

the AD conversion unit is provided with a column Analog to Digital Converter (ADC) for each of a plurality of the vertical signal lines.

(17)

The solid-state imaging device according to (16), in which

the array unit includes a pixel array unit in which the plurality of pixels is arranged two-dimensionally, and

a first layer including the pixel array unit and a second layer including the AD conversion unit are laminated.

(18)

The solid-state imaging device according to (16), in which

the array unit includes a first array unit in which a plurality of the photoelectric conversion units of the pixels is arranged two-dimensionally, and a second array unit in which a plurality of the analog memory units of the pixels is arranged two-dimensionally, and

a first layer including the first array unit, a second layer including the second array unit, and a third layer including the AD conversion unit are laminated.

(19)

The solid-state imaging device according to any of (1) to (18), further including a drive unit that drives the plurality of pixels.

(20)

An electronic device equipped with a solid-state imaging device including

an array unit in which a plurality of pixels each including a photoelectric conversion unit and an analog memory unit is arranged, in which

the analog memory unit holds an electric charge photoelectrically converted by the photoelectric conversion unit by first exposure, and

the electric charge held in the analog memory unit by the first exposure is adaptively and non-destructively read.

### REFERENCE SIGNS LIST

10, 10A, 10B Solid-state imaging device
11 Pixel array unit
11A Photodiode array unit
12A Analog memory array unit
12 Drive unit
13 Column ADC unit
20, 20A, 20B Solid-state imaging device
21 Pixel array unit
21A Photodiode array unit
22A Analog memory array unit
22 Drive unit
23 Column ADC unit
30, 30A, 30B Solid-state imaging device
31 Pixel array unit
31A Photodiode array unit
32A Analog memory array unit
32 Drive unit
33 Column ADC unit
100 Pixel
Photodiode unit
102 Analog memory unit
Photodiode
122 Analog memory
Vertical signal line
ADC
200 Pixel
201 Photodiode unit
202 Analog memory unit
211 Photodiode
222 Analog memory
231 Vertical signal line
251 ADC
300 Pixel
301 Photodiode unit
302 Analog memory unit
303, 303-1 to 303-4 Tap
311 Photodiode
322, 322-1 to 322-4 Analog memory
331 Vertical signal line
351 ADC
1000 Electronic device
1001 CPU
1004 Solid-state imaging device
1009 Object detection unit
1010 Object recognition unit
1011 Image processing unit

1. A solid-state imaging device comprising
an array unit in which a plurality of pixels each including a photoelectric conversion unit and an analog memory unit is arranged, wherein
the analog memory unit holds an electric charge photoelectrically converted by the photoelectric conversion unit by first exposure, and
the electric charge held in the analog memory unit by the first exposure is adaptively and non-destructively read.

2. The solid-state imaging device according to claim 1, wherein
the electric charge held in the analog memory unit is read a plurality of times non-destructively.

3. The solid-state imaging device according to claim 1, wherein
an electric charge photoelectrically converted by the photoelectric conversion unit by second exposure is read.

4. The solid-state imaging device according to claim 1, wherein
the analog memory unit includes a plurality of analog memories,
at least one or more of the analog memories of the plurality of analog memories holds the electric charge photoelectrically converted by the photoelectric conversion unit by the first exposure, and
the electric charge held in the analog memory by the first exposure is selectively read.

5. The solid-state imaging device according to claim 2, wherein
the first exposure is performed with a global shutter method.

6. The solid-state imaging device according to claim 5, wherein
the electric charge held in the analog memory unit for each of the plurality of pixels is read depending on an arbitrary area in an image frame, a drive mode of the pixels, predetermined signal processing, or a predetermined timing.

7. The solid-state imaging device according to claim 5, wherein
among electric charges held in the analog memory unit for the respective plurality of pixels, electric charges to generate a first image are read, and then electric charges to generate a second image captured simultaneously with the first image are read.

8. The solid-state imaging device according to claim 3, wherein
the first exposure is performed with a global shutter method or a rolling shutter method, and
the second exposure is performed with the rolling shutter method.

9. The solid-state imaging device according to claim 8, wherein
the second exposure is performed after the first exposure temporally.

10. The solid-state imaging device according to claim 8, wherein
the electric charge held in the analog memory unit for each of the plurality of pixels is read depending on an arbitrary area in an image frame, a drive mode of the pixels, predetermined signal processing, or a predetermined timing.

11. The solid-state imaging device according to claim 4, wherein
the plurality of analog memories sequentially holds electric charges obtained by time-division of the first exposure as the electric charge photoelectrically converted by the photoelectric conversion unit.

12. The solid-state imaging device according to claim 11, wherein
the electric charges held in the plurality of analog memories are added together and read.

13. The solid-state imaging device according to claim 11, wherein
the electric charges held in the plurality of analog memories of the analog memory unit for each of the plurality of pixels are read depending on an arbitrary area in an image frame, a drive mode of the pixels, predetermined signal processing, or a predetermined timing.

14. The solid-state imaging device according to claim 12, wherein
the electric charges held in the plurality of analog memories of the analog memory unit for each of the plurality of pixels are selectively read depending on a state of time-division exposure of the first exposure.

15. The solid-state imaging device according to claim 11, wherein
an electric charge photoelectrically converted by the photoelectric conversion unit by second exposure is read.

16. The solid-state imaging device according to claim 1, wherein
in the array unit, the plurality of pixels is arranged two-dimensionally,
an AD conversion unit is further provided, the AD conversion unit converting, into a digital signal, an analog signal input via a vertical signal line provided corresponding to a pixel arrangement in a horizontal direction in the array unit, and
the AD conversion unit is provided with a column Analog to Digital Converter (ADC) for each of a plurality of the vertical signal lines.

17. The solid-state imaging device according to claim 16, wherein
the array unit includes a pixel array unit in which the plurality of pixels is arranged two-dimensionally, and
a first layer including the pixel array unit and a second layer including the AD conversion unit are laminated.

18. The solid-state imaging device according to claim 16, wherein
the array unit includes a first array unit in which a plurality of the photoelectric conversion units of the pixels is arranged two-dimensionally, and a second array unit in which a plurality of the analog memory units of the pixels is arranged two-dimensionally, and
a first layer including the first array unit, a second layer including the second array unit, and a third layer including the AD conversion unit are laminated.

19. The solid-state imaging device according to claim 1, further comprising
a drive unit that drives the plurality of pixels.

20. An electronic device equipped with a solid-state imaging device including
an array unit in which a plurality of pixels each including a photoelectric conversion unit and an analog memory unit is arranged, wherein
the analog memory unit holds an electric charge photoelectrically converted by the photoelectric conversion unit by first exposure, and
the electric charge held in the analog memory unit by the first exposure is adaptively and non-destructively read.
